(19) United States
(12) Patent Application Publication
(10) Pub. No.: US 2009/0130849 A1
(43) Pub. Date: May 21, 2009

(54) CHEMICAL MECHANICAL POLISHING AND WAFER CLEANING COMPOSITION COMPRISING AMIDOXIME COMPOUNDS AND ASSOCIATED METHOD FOR USE

(76) Inventor: Wai Mun Lee, Fremont, CA (US)

Correspondence Address: MORGAN LEWIS & BOCKIUS LLP, 1111 PENNSYLVANIA AVENUE NW, WASHINGTON, DC, 20004, US

(21) Appl. No.: 12/260,575

(22) Filed: Oct. 29, 2008

Related U.S. Application Data
(60) Provisional application No. 61/000,727, filed on Oct. 29, 2007.
(60) Provisional application No. 61/006,226, filed on Dec. 31, 2007.

(51) Int. Cl. H01L 21/304; C09G 1/02

(52) U.S. Cl. 438/693; 252/79.1; 257/E21.239

(57) ABSTRACT

A composition and associated method for chemical mechanical planarization (or other polishing) is described. The composition contains an amidoxime compound and water. The composition may also contain an abrasive and a compound with oxidation and reduction potential. The composition is useful for attaining improved removal rates for metal, including copper, barrier material, and dielectric layer materials in metal CMP. The composition is particularly useful in conjunction with the associated method for metal CMP applications.

### CROSS-REFERENCE TO RELATED APPLICATIONS

This application claims the benefit of U.S. Provisional Application No. 61/000,727, filed Oct. 29, 2007, and U.S. Provisional Application No. 61/006,226, filed Dec. 31, 2007, both of which are incorporated herein by reference in their entirety.

### BACKGROUND

1. Field of the Invention

The present invention relates to an improved composition for chemical mechanical planarization (CMP) and processes for chemical mechanical polishing or planarization of semiconductor wafers. More particularly, the present invention relates to such a composition and process tailored to meet more stringent requirements of advanced integrated circuit fabrication. Moreover, the invention relates to chemical mechanical polishing of substrates using an abrasive and a fluid composition comprising amidoxime compounds, and particularly relates to a method of polishing substrates comprising copper, at least one barrier material, and at least one dielectric material using a chemical-mechanical polishing system comprising amidoxime compounds, or comprising amidoxime compounds and a compound with oxidation and reduction potential.

2. Description of Related Art

Modern integrated circuits typically comprise millions of active devices on a single substrate, electrically interconnected through the use of single and multilevel interconnections including conductive lines and plugs (“vias”). Conventionally, integrated circuit includes a semiconductor substrate and a plurality of sequentially formed dielectric layers and conductive patterns, including conductive lines, vias and interconnects. Typically, the conductive patterns on different layers, i.e. upper and lower layers, are electrically connected by a conductive interconnect or plug filling a via opening through the interlayer dielectric (“lLD”), while a conductive plug filling a contact opening establishes electrical contact with an active region on a semiconductor substrate, such as a source/drain region. As is known in the art, a damascene technique can be employed to form interconnects by forming an opening or channel in the ILD and filling the opening with a conductive material, typically a metal. The metal typically fills the channel in the ILD and covers the field region atop the IDL between channels. Planarization typically is the next step, removing the metal in the field region, removing barrier/adhesion layers (if any), and providing a substantially planar surface for further coating and patterning.

A dual damascene technique is also known in the art and can be employed to form conductive plugs and lines simultaneously. Basically, dual damascene involves forming an opening comprising a lower contact or via opening section in communication with an upper channel section, and filling the opening and channel section with a conductive material, typically a metal, to simultaneously form an electrically connected conductive plug and channel combination. Planarization follows to remove metal and other materials as in the damascene technique.

Elemental aluminum and its alloys have been traditionally employed for filling metallic channels and vias in the fabrication of integrated circuits having relatively low integration density. The advantages of aluminum include its low resistivity, superior adhesion to typical dielectric layers (e.g. SiO₂), ease of patterning, and high purity.

However, aluminum and aluminum alloys are susceptible to detrimental increases in contact resistances during high temperature processing. Another problem associated with the use of aluminum and aluminum alloys in integrated circuits is electromigration, which becomes a more serious concern as the level of integration and the density of components increase. The higher number of circuit components in very large-scale integration (“VLSI”), ultra large-scale integration (“ULSI”), and even higher densities, requires the use of conductive interconnects with smaller cross sections. This causes higher electrical resistance in the interconnect and increased heat generation. Accordingly, as integrated circuit patterning schemes continue to miniaturize to submicron dimensions, aluminum based metallurgies have become increasingly marginal for handling the increased circuit speed and current density requirements. Materials having higher conductivity than aluminum or its alloys would be advantageous for use as interconnects. Hence, the escalating requirements for high density and performance associated with VLSI, ULSI and beyond require responsive changes in multilevel interconnection technology.

Currently, copper and copper alloys are receiving considerable attention as replacement materials for, inter alia, aluminum and aluminum alloys in VLSI and LLSI multilevel metallization systems. Copper has a lower resistivity than aluminum, and also significantly higher resistance to electornigration. However, problems with integrating copper metal into multilevel metallization systems include the difficulty of etching copper and its relatively high diffusivity. Since copper is difficult to pattern precisely and economically, damascene or dual damascene processing is typically preferred over subtractive patterning processes for creating copper interconnections. To hinder copper diffusion and to enhance its adhesion, barrier/adhesion layers (typically Ta/TaN) are used to separate the copper interconnections from the surrounding dielectric and to enhance the adhesion of the copper. However, these multicomponent layered structures of Cu/Ta/TaN/ILD exacerbate the problems of providing smooth surfaces for accurate patterning, while accurate patterning is increasingly necessary for providing reliable electrical contact to submicron features.

This invention relates generally to the chemical-mechanical polishing (CMP) of metal substrates on semiconductor wafers and slurry compositions therefor. In particular, the present invention relates to a CMP slurry composition which is characterized to enhance removal of barrier layer materials, copper, and low-k dielectric materials in relation to PETEOS dielectric layer materials, and to provide tenability for the selective removal of barrier layer materials, copper, low-k dielectric materials, and PETEOS dielectric layer materials, during CMP processing of substrates comprised of metal, barer layer materials, and dielectric layer materials. This invention is especially useful for metal CMP and most especially for step 2 copper CMP processes.

Chemical mechanical planarization (chemical mechanical polishing, CMP) for planarization of semiconductor substrates is now widely known to those skilled in the art and has been described in numerous patents and open literature publications Some introductory references on CMP are as follows: “Polishing Surfaces for Integrated Circuits”, by B. L. Mueller and J. S. Stcckenrider, Chemtech, February, 1998, pages 38-46; H. Landis et al., Thin Solids Films, 220 (1992), page I; and “Chemical-Mechanical Polish” by G. B. Shinn et al., Chapter IS, pages 415-460, in Handbook of 55 Semiconductor Manufacturing Technology, editors: Y. Nishi and It. Doering, Marcel Dekker, New York City (2000).

Chemical Mechanical Planarization (also referred to as Chemical Mechanical Polishing), or CMP, is the process of removing material and forming a substantially planar layer before additional layers are deposited and/or additional patterning occurs. CMP of copper and copper alloys deposited on a tantalum (Ta) and/or tantalum nitride (TaN) barrier/adhesion layer has become the subject of considerable interest. For economy of language, we refer to copper and/or copper alloys as “copper” and barrier/adhesion layer(s) as “barrier layer,” understanding thereby that the copper conductor may include copper alloys (among other materials) and the barrier layer may have adhesive as well as barrier functions.

In a typical CMP process, a substrate (e.g., a wafer) is placed in contact with a rotating polishing pad attached to a platen. A CMP slurry, typically an abrasive and chemically reactive mixture, is supplied to the pad during CMP processing of the substrate. During the CMP process, the pad (fixed to the platen) and substrate are rotated while a wafer carrier system or polishing head applies pressure (downward force) against the substrate. The slurry accomplishes the planarization (polishing) process by chemically and mechanically interacting with the substrate film being planarized due to the effect of the downward force and the rotational movement of the pad relative to the substrate. Polishing is continued in this manner until the desired film on the substrate is removed with the usual objective being to effectively planarize the substrate. Typically metal CMP slurries contain an abrasive material, such as silica or alumina, suspended in an oxidizing, aqueous medium.

Silicon based semiconductor devices, such as integrated circuits (ICs), typically include a dielectric layer. Multilevel circuit traces, typically formed from aluminum or an aluminum alloy or copper, are patterned onto the dielectric layer substrate. These are numerous types of layers that can be polished by CMP, for example, silicon nitride, interlayer dielectrics (ILD) such as silicon oxide and low-k films including carbon-doped oxides; metal layers such as tungsten, copper, aluminum, etc., which are used to connect the active devices; barrier layer materials such as titanium, titanium nitride, tantalum, tantalum nitride, noble metals, etc.

CMP processing is often employed to remove and planarize excess metal at different stages of semiconductor manufacturing. Various metals and metal alloys have been used at different stages of semiconductor manufacturing, including tungsten, aluminum, copper, tantalum, tantalum nitride, titanium, titanium nitride, ruthenium, platinum, iridium, and combinations thereof. For example, one way to fabricate a multilevel copper interconnect or planar copper circuit traces on a dielectric substrate is referred to as the damascene process. In a semiconductor manufacturing process typically used to form a multilevel copper interconnect, metallized copper lines or copper vias are formed by electrochemical metal deposition followed by copper CMLP processing. In a typical process, the interievel dielectric (ILD) surface is patterned by a conventional dry etch process to form vias and trenches for vertical and horizontal interconnects and make connection to the sublayer interconnect structures. The patterned ILD surface typically is coated with an adhesion-promoting layer such as titanium or tantalum and/or a diffusion barrier layer such as titanium nitride or tantalum nitride over the ILD surface and into the etched trenches and vias. The adhesion-promoting layer and/or the diffusion barrier layer is then overcoated with copper, for example, by a seed copper layer and followed by an electrochemically deposited copper layer. Electro-deposition is continued until the structures are filled with the deposited metal. Finally, CMP processing is used to remove the copper overlayer, adhesion-promoting layer, and/or diffusion barrier layer, until a planarized surface with exposed elevated portions of the dielectric (silicon dioxide and/or low-k) surface is obtained. The vias and trenches remain filled with electrically conductive copper forming the circuit interconnects. The adhesion-promoting layer plus diffusion barrier layer is typically collectively referred to as the “barrier layer.”

A multi-step copper CMP process may be employed to achieve local and global planarization in the production of IC chips, referred to as a step 1 copper CMLP process, followed by a barrier layer CMP process. In relation to copper CLMP, the current state of this technology involves use of a two-step process. During step 1 of a copper CMP process, the overburden copper is removed and planarized. Then step 2 of the copper CMP process follows to remove the barrier layer materials and achieve both local and global planarization. The barrier layer CMP process is frequently referred to as a barrier or step 2 copper CMP process. The ratio of the removal rate of copper to the removal rate of dielectric material is called the “selectivity” for removal of copper in relation to dielectric material during CMP processing of substrates comprised of copper, barrier layer materials, and dielectric material. The ratio of the removal rate of barrier layer materials to the removal rate of copper is called the “selectivity” for removal of barrier layer materials in relation to copper during CMP processing of substrates comprised of copper, barrier layer materials, and dielectric materials. Barrier layer materials include tantalum, tantalum nitride, tungsten, noble metals such as ruthenium and ruthenium oxide, and combinations thereof.

When CMP slurries over-polish copper layers they may create a depression or “dishing” effect in the copper vias and trenches. This feature distortion is unacceptable due to lithographic and other constraints in semiconductor manufacturing. Another feature distortion that is unsuitable for semiconductor manufacturing is called “erosion.” Erosion is the topography difference between a field of dielectric and a dense array of copper vias or trenches. In CMP, the materials in the dense array may be removed or eroded at a faster rate than the surrounding field of dielectric. This causes a topography difference between the field of dielectric and the dense copper array.

A number of systems for CMP of copper have been disclosed. A few illustrative examples are listed next. Kumar et al. in an article entitled “Chemical-Mechanical Polishing of Copper in Glycerol Based Slurries” (Materials Research Society Symposium Proceedings, 1996) disclose a slurry that contains glycerol and abrasive alumina particles. An article by Gutmann et al. entitled “Chemical-Mechanical Polishing of Copper with Oxide and Polymer Interlevel Dielectrics” (Thin Solid Films, 1995) discloses slurries based on either ammonium hydroxide or nitric acid that may contain benzotriazole (BTA) as an inhibitor of copper dissolution. Luo et al. in an article entitled “Stabilization of Alumina Slurry for Chemical-Mechanical Polishing of Copper” (Langmuir, 1996) discloses alumina-ferric nitrate slurries that contain polymeric surfactants and BTA. Carpio et al. in an article entitled “Initial Study on Copper CMP Slurry Chemistries” (Thin Solid Films, 1995) disclose slurries that contain either alumina or silicon particles, nitric acid or ammonium hydroxide, with hydrogen peroxide or potassium permanganate as an oxidizer.

Generally, after removal of overburden copper in step 1, polished wafer surfaces have non-uniform local and global planarity due to differences in the step heights at various locations of the wafer surfaces. Low density features tend to have higher copper step heights whereas high density features tend to have low step heights. Due to differences in the step heights after step 1, selective slurries are highly desirable for step 2 copper CMP for the selective removal of barrier layer materials in relation to copper and for the selective removal of dielectric materials in relation to copper.

A typically used CMP slurry has two actions, a chemical component, and a mechanical component. There are a number of theories as to the mechanism for chemical mechanical polishing of copper. An article by Zeidler et al. (Microelectronic Engineering, 1997) proposes that the chemical component forms a passivation layer on the copper changing the copper to a copper oxide. The copper oxide has different mechanical properties, such as density and hardness, than metallic copper and passivation changes the polishing rate of the abrasive portion. The above article by Gutmann et al. discloses that the mechanical component abrades elevated portions of copper and the chemical component then dissolves the abraded material. The chemical component also passivates recessed copper areas minimizing dissolution of those portions.

In the case of CMP of metals, the chemical action is generally considered to take one of two forms. In the first mechanism, the chemicals in the solution react with the metal layer to continuously form an oxide layer on the surface of the metal. This generally requires the addition of an oxidizer to the solution such as hydrogen peroxide, ferric nitrate, etc. Then the mechanical abrasive action of the particles continuously and simultaneously removes this oxide layer. A judicious balance of these two processes obtains optimum results in terms of removal rate and polished surface quality.

In the second mechanism, no protective oxide layer is formed. Instead, the constituents in the solution chemically attack and dissolve the metal, while the mechanical action is largely one of mechanically enhancing the dissolution rate by such processes as continuously exposing more surface area to chemical attack, raising the local temperature (which increases the dissolution rate) by the friction between the particles and the metal, and enhancing the diffusion of reactants and products to and away from the surface by mixing and by reducing the thickness of the boundary layer.

Slures previously employed in the CMP processes of copper and/or barrier layers have suffered from several disadvantages, including an inadequate selectivity between removal rates of copper and barrer material. The selectivity in the removal of copper and barrier materials should be neither too high nor too low. Uncontrollable removal rates can be the undesirable result. Over-polishing of some materials in order to remove other materials may also occur when selectivity is too high. Over-polishing can lead to significant degradation, dishing or erosion of the surface being over-polished and consequently poor planarization. U.S. Pat. Nos. 7,229,570, 6,866,792, and 6,635,186 describe Cow compositions but none offer the selectivity of the amidoxime compositions of the present invention.

The present invention is directed to polishing slurry that is able to selectively polish the copper portion of a copper wafer having a tantalum and/or tantalum nitride layer. Embodiments of the present invention include CMI) compositions that polish both copper and barrier layers (under different polishing conditions) as well as compositions that polish only copper.

The present invention relates to compositions and methods for removal of chemical mechanical polishing of a copper or aluminum surface including an aqueous solution comprising an amidoxime complex applied to a “semiconductor work-piece”, which is a microelectronic device, which has not completed the fabrication process, typically a silicon wafer with active regions formed in or on the surface of the silicon wafer.

In all such manufacture, connections to the active regions are made using multiple layers of metal, typically copper and tungsten, which has been deposited on the silicon substrate. When copper is used as the interconnect material, a damascene process is used whereby the copper is deposited into lines etched into the inter-layer dielectric and then the excess copper is removed and the surface planarized using a CLMP process, followed by a cleaning step. An effective CMP solution will also help prevent the deposition of residues, which aids the post-CMP cleaning process.

A cleaning solution may contain various chemicals that perform different functions during the cleaning process. A cleaning solution must contain a “cleaning agent,” A “cleaning agent” is the component of solution that removes residual CMP slurry particles, typically particles of metal, from the surface of the semiconductor work-piece. A cleaning solution may also contain “chelating agents,” “corrosion-inhibiting compounds,” and/or “surface-active agents.” A “chelating agent” helps prevent re-deposition of removed metal onto the semiconductor work-piece by complexing the metal in the cleaning solution. A “corrosion-inhibiting compound” is the component of the cleaning solution that protects the metal surface from attack by mechanisms such as the aggressive nature of the cleaning solution, oxidation, post cleaning corrosion, galvanic attack, or photo-induced attack. A “surface-active agent” is a component of the cleaning solution that modifies the wetting characteristics and prevents watermark formation.

It is highly advantageous to use a cleaning solution protect the metal surfaces of the semiconductor device from having a high static etch rate and from oxidation of the metal surfaces by forming a protective film on the surface. The metal surfaces of the semiconductor work-piece are typically copper, and form the conducting paths of the semiconductor wafer. Due to the very small size of features on semiconductor wafers, the metal lines are as thin as possible while still carrying the desired electric current. Any oxidation or corrosion on the surface or recess of the metal causes thinning of the lines (dissolution) and results in poor performance or failure of the semiconductor device. Therefore, it is important to protect the metal surfaces from corrosion by forming a suitable corrosion resistant film on the surface of the metal. Many cleaning solutions available in the art do not provide a film forming agent, and thus suffer from a high static etch rate and/or high RMS value.

The cleaning solution's corrosion preventing abilities are quantified by measuring the static etch rate or the surface roughness (quantified by RMS, root mean square, value) of a metal surface that has been cleaned with the subject solution. A high static etch rate indicates dissolution of the metal surface is occurring. A high RMS value indicates a rough surface caused by attack of the metal. An effective protective film reduces the corrosion of the metal as indicated by static etch rate and RMS values after cleaning. The corrosion resistance of a cleaning solution can also be directly measured using electrochemical means known to those skilled in the art.

One preferred method of protecting the metal surface from oxidation corrosion is by passivating the metal surface after or during cleaning. Some existing acidic cleaning chemistries do not passivate the metal, resulting in corrosion during and after the cleaning step by oxidation of the metal surface. Some chemistry for planarizing a wafer surface includes a cleaning step followed by an additional step of rinsing with water or an inhibitor solution. Some rinsing agents can leave deposits on the surface of the work-piece, thus contaminating the wafer Adding a second step is also a drawback due to the fact that it lengthens the manufacturing process, complicates the process by having to handle more chemicals and more steps, and provides one more possible source of contamination or other quality control problems. Clearly, a CMP process that protects the surface of the semiconductor work-piece in the same step is desirable. The CMP chemistries of the present invention overcome this problem by passivating in a single step.

The ability of the cleaning chemistry to remove residual metals and retain them in the cleaning solution is also an important characteristic to prevent redeposition. Chemicals that can complex the residual metals in the cleaning solution are effective cleaning solutions because the residual metals are not re-deposited on the semiconductor work-piece after they are removed. These complexing chemicals are referred to as “chelating agents.” Cleaning solutions using chemistry that cannot complex the residual metals typically perform poorly at the desired CMP task. Thus, it is desirable to have a cleaning solution capable of removing and complexing the dissolved metal in the cleaning solution.

Another common problem with cleaning semiconductor surfaces is the deposition of contaminants on the surface of the semiconductor device. Any cleaning solutions that deposit even a few molecules of undesirable composition, such as carbon, will adversely affect the performance of the semiconductor device. Cleaning solutions that require a rinsing step can also result in depositing contaminants on the surface, Thus, it is desirable to use a cleaning chemistry that is will leave little to no residue on the semiconductor surface.

It may also be desirable to have a surface wetting agent in the cleaning solution. Surface wetting agents prevent contamination of the semiconductor work-piece by helping to stop spotting of the surface caused by droplets clinging to the surface. Spotting (also called watermarks) on the surface can saturate metrology tools that measure light point defects, thus masking defects in the semiconductor work-piece.

The chemistry of the current invention makes use of multiple additives to provide a solution that is not sensitive to oxygen, removes particles efficiently, removes metal from the dielectric surface, is in the neutral to low pH range, protects the metal from corrosion and dissolution, and does not contaminate the semiconductor surface.

In some cases, the biodegradability is also unsatisfactory. Thus, EDTA proves to have inadequate biodegradability in conventional tests, as does PDTA or HPDTA and corresponding aminomethylenephosphonates which, moreover, are often undesirable because of their phosphorus content. Phosphorus is also a dopant in semiconductor devices, therefore it is desirable to have CMP and post-CMP cleaning solutions with non-phosphor containing compounds.

Further, most formulations being used in the CMP process contains complexing agents, sometimes called chelating agents. Much metal-chelating functionality are known which causes a central metal ion to be attached by coordination links to two or more nonmetal atoms (ligands) in the same molecule. Heterocyclic rings are formed with the central (metal) atom as part of each ring. When the complex becomes more soluble in the solution, it functions as a cleaning process. If the complexed product is not soluble in the solution, it becomes a passivating agent by forming an insoluble film on top of the metal surface. The current complexing agents in use, such as, glycolic acid, glyoxylic acid, lactic acid, phosphonic acid, are acidic in nature and have a tendency to attack the residue and remove both metals and metal oxides, such as copper and copper oxide. This presents a problem for formulators where a chelating function is sought but only selectively to metal oxide and not the metal itself, e.g. in an application involving metal, such as copper. Accordingly, there is a need for complexing agents that are not aggressive toward metal substrates, while effectively providing for the chelation of metal ions residue created during the manufacturing processes.

The present invention addresses these problems.

### SUMMARY OF PREFERRED EMBODIMENTS

The present invention provides for solutions one or more of the following problems common with prior art compositions and methods: reducing or eliminating corrosion problems; eliminating substantial use of flammable solvents; eliminating SARA Title III chemistries; and lowering mobile and transition metal ions. The present invention further provides excellent selectivity and the ability to planarize metals, such as copper and aluminum alloys, as well as dielectric, with a selected pH.

Specifically, the present invention provides for a chemical mechanical planarization composition comprising at least one amidoxime compound, water and an abrasive. The present invention also provides for uses of such chemical mechanical planarization (CMP) compositions. In one embodiment, the method of chemical-mechanical planarization of a substrate, having a metal surface, at least one dielectric material and at least one barrier material, comprising the steps of (a) contacting the substrate with a polishing pad and with the chemical-mechanical planarization composition of containing least one amidoxime compound, water and an abrasive and (b) polishing the substrate.

The present invention also applies to a method for the chemical mechanical planarization of a semiconductor work-piece; the method comprising the steps of: (a) providing a semiconductor work-piece, wherein said semiconductor workpiece comprises: (i) a metal line, wherein said metal line comprises copper or aluminum; (ii) a barrier material, wherein said barrier material comprises materials selected from the group consisting of: a. Ta, b. TaN, c. Ti, d. TiN, e. W, and f. WN; and (iii) a dielectric (b) contacting said semiconductor work-piece with a CMP composition comprising a cleaning agent, wherein said cleaning agent comprises: (i) water; (ii) one or more compounds containing at least one amidoxime functional group.

One embodiment of the invention is a chemical-mechanical planarization composition comprising an abrasive, water, and an amidoxime compound having the structure:

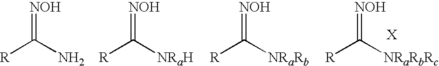

or tautomers thereof, wherein X is a counterion and R, Rₐ, R_{b} and R_{c} are independently selected from alkyl, heteroalkyl, aryl and heteroaryl.

The abrasive may be a colloidal abrasive, silicia, or a surface-modified silica. In one embodiment of the invention, the amidoximide compound is present from about 0.1 weight % to 25% weight.

In some embodiments, the chemical mechanical planarization composition comprises one or more additional components such as e.g. a compound with an oxidation and reduction potential (e.g. hydrogen peroxide), a surfactant (e.g. a non-ionic surfactant), a chelating agent, and/or corrosion inhibitor. In one embodiment of the invention, the composition contains hydrogen peroxide, preferably between about 0.05 weight % to about 7.5 weight % of the total composition, as the compound with oxidation and reduction potential. In one embodiment, the pH of the composition ranges from 5 to 11.

In another embodiment the amidoxime has the following structure:

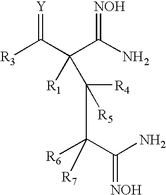

wherein R4, R5, R6 and R7 are independently selected from hydrogen, heteteroatoms, heterogroups, alkyl, heteroalkyl, aryl and heteroaryl.

In another embodiment, the amidoxime is selected from the group consisting of 1,2,3,4,5,6-hexakis-O-[3-(hydroxyamino)-3-iminopropyl Hexitol, 3,3′,3″,3′″-(ethane-1,2-diylbis(azanetriyl))tetrakis(N′-hydroxypropanimidamide), 3,3′-(ethane-1,2-diylbis(oxy))bis(N′-hydroxypropanimidamide), 3-(diethylamino)-N′-hydroxypropanimidamide, 3,3′-(piperazine-1,4-diyl)bis(N′-hydroxypropanimidamide), 3-(2-ethoxyethoxy-N′-hydroxypropanimidaide, 3-(2-(2-(dimethylamino)ethoxy)ethoxy) N′-hydroxypropanimidamide, N′-hydroxy-3-(phenylamino)propanimidamide, 3,3′,3″-nitrilotris(N′-hydroxypropanimidamide), 3,3′-(2,2-bis((3-(hydroxyamino)-3-iminopropoxy)methyl)propane-1,3-diyl)bis(oxy)bis(N-hydroxypropanimidamide), 3,3′-(2,2′-(methylazanediyl)bis(ethane-2,1-diyl)bis(oxy))bis(N′-hydroxypropanimidamide), N,N-bis(3-amino-3-(hydroxyimino)propyl)acetamide, 3,3′-(2-(N′-hydroxycarbamimidoyl)phenylazanediyl)bis(N′-hydroxypropanimidamide), 3,3′-(2,2′-(3-amino-3-(hydroxyimino)propylazanediyl)bis(ethane-2,1-diyl))bis(oxy)bis(N′-hydroxypropanimidamide), N′,3-dihydroxypropanimidamide, NN′-hydroxyacetimidamide, N′-hydroxy-3-(methylamino)propanimidamide, N′-hydroxybenzimidamide, 3,3′-azanediylbis(N′-hydroxypropanimidamide), N′-hydroxyoctanimidamide, N′1-hydroxy-3-phenylpropanimidamide, 3-amino-N-hydroxy-3-(hydroxyimino)propanamide, 3-amino-3-(hydroxyimino)propanoic acid, 3-amino-3-(hydroxyimino)propanamide, N′1,N′6-dihydroxyadipimidamide, N′1,N′10-dihydroxydecanebis(imidamide), N′-hydroxyisonicotinimidamide, N′-hydroxy-3-methylbenzimidamide, isoindoline-1,3-dione dioxime, N′,2-dihydroxyacetimidamide, 2-chloro-N′-hydroxyacetimidamide, product N′-hydroxy-2-phenylacetimidamide, 2-amino-N′-hydroxybenzimidamide, 2,2′-azanediylbis(N′-hydroxyacetimidamide), N′-hydroxy-1-oxo-1,3-dihydroisobenzofuran-5-carboximidamide, 3-aminoisoquinolin-1(4H)-one oxime or 3-(hydroxyamino)-3,4-dihydroisoquinolin-1-amine, N′-hydroxycinnamimidamide, 4-cyano-N′-hydroxybutanimidamide, 4-chloro-N′-hydroxybenzimidamide and salts thereof.

In another embodiment, the amidoxime has the following structure:

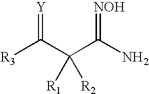

wherein R₁, R₂ and R₃ are independently selected from hydrogen, heteteroatoms, heterogroups, alkyl, heteroalkyl, aryl and heteroaryl, and Y is O, NH or NOH.

Another embodiment of the invention is a method of metal chemical-mechanical planarization comprising the following steps:

(a) placing a substrate comprising metal, at least one dielectric material and at least one barrier material in contact with a polishing pad;

(b) delivering a chemical-mechanical planarization composition comprising at least one abrasive, water and an amidoxime compound having the structure:

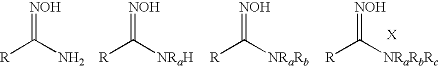

or tautomers thereof, wherein X is a counterion and R, Rₐ, R_{b} and R_{c} are independently selected from alkyl, heteroalkyl, aryl and heteroaryl; and

(c) polishing the substrate with the chemical mechanical planarization composition.

The abrasive may be a colloidal abrasive, silica, or a surface-modified silica. In one embodiment of the invention, the amidoximide compound is present from about 0.1 weight % to 25% weight. In some embodiments, the chemical mechanical planarization composition used for CMP comprises one or more additional components such as e.g. a compound with an oxidation and reduction potential (e.g. hydrogen peroxide and hydroxylamine and its salts), a surfactant (e.g., a non-ionic surfactant), a chelating agent, and/or corrosion inhibitor. In one embodiment of the invention, the composition contains hydrogen peroxide, preferably between about 0.05 weight % to about 7.5 weight % of the total composition, as the compound with oxidation and reduction potential. In one embodiment of the invention, the pH ranges from 5 to 11.

Yet another embodiment of the invention is a method of metal chemical-mechanical planarization comprising the following steps:

(a) placing a substrate comprising metal, at least one dielectric material and at least one barrier material in contact with a polishing pad,

(b) delivering a chemical-mechanical planarization composition comprising an abrasive, water, a compound with oxidation and reduction potential and an amidoxime compound having the structure:

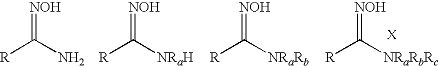

or tautomers thereof, wherein X is a counterion and R, Rₐ, R_{b} and R_{c}, are independently selected from alkyl, heteroalkyl, aryl and heteroaryl, and

(c) polishing the substrate with the chemical mechanical planarization composition.

In one embodiment of the invention, amidoxime compound in the composition use for the method of metal chemical-mechanical planarization contains an R group with ten or more carbon atoms. In another embodiment, R is an alkyl group. In yet another embodiment of the invention, R is a heteroalkyl.

The method may be used to polish a variety of substrates and metals. In one embodiment of the invention, metal is copper, aluminum, or tungsten. In another embodiment of the invention, the substrate further comprises at least one dielectric material and at least one barrier material. In some embodiments, dielectric material is silicon oxide, carbon doped silicon oxide or an organic low k dielectric material. The compositions used for the method of metal chemical-mechanical planarization may further comprise e.g. one or more acid compounds, one or more basic compounds or a corrosion inhibitor.

Yet another embodiment of the invention is a method for the chemical mechanical planarization of a semiconductor work-piece, the method comprising the steps of:

(a) providing a semiconductor work-piece, wherein said semiconductor workpiece comprises at least (i) metal line, wherein said metal line comprises copper or aluminum, (ii) a barrier material, wherein said barrier material comprises materials selected from the group consisting of: a) Tantalum (Ta), b) Tantalum nitride (TaN), c) Titanium (Ti), d) Titanium nitride (TiN), e) Tungsten (W), and f) Tungsten nitride (WN); and (iii) a dielectric, and

(b) contacting said semiconductor work-piece with a polishing composition comprising a cleaning agent, wherein said cleaning agent comprises water; and one or more amidoxime compounds.

The one or more amidoxime compounds present in the polishing composition may be present in an amount of from about 0.001 percent by weight to about 25 percent by weight.

In one embodiment, the polishing composition is a slurry comprising from about 0.1 to about 10 percent by weight of one or more abrasive particles selected from the group consisting of silica, alumina, titanium oxide, zirconium oxide, cerium oxide, and combinations thereof as well as one or more amidoxime compounds present in the polishing composition may be present in an amount of from about 0.001 percent by weight to about 25 percent by weight.

In another embodiment, the polishing composition further comprises one or more compounds with oxidation and reduction potential selected form the group consisting of ammonium peroxydisulfate, peracetic acid, urea hydroperoxide, sodium percarbonate, sodium perborate, hydrogen peroxide; hydroxylamine, hydroxylamine salts, peracetic acid, perchloric acid, periodic acid, ammonium persulfate, sodium persulfate, potassium persulfate, Na₂O₂, Ba₂O₂ and (C₆H₅C)₂O₂; hypochlorous acid, ketoneperoxides, diacylperoxides, hydroperoxides, alkylperoxides, peroxyketals, alkylperesters, peroxycarbonates, hydroxylammonium salts and mixtures thereof. In one embodiment, the one or more compounds with oxidation and reduction potential are present in an amount of about 0.01 percent by weight to about 10 percent by weight.

In another embodiment, the polishing composition further comprises a corrosion inhibitor selected from the group consisting of dithiocarbamate, thiosulfate, benzotriazole, 1-hydroxybenzotriazole, 4-hydroxybenzotriazole, 2,3-dicarboxybenzotriazole, 2,3-dicarboxypropylbenzotriazole, 4-carboxyl-1H-benzotriazole, 4-methoxycarbonyl-1H-benzotriazole, 4-butoxycarbonyl-1H-benzotriazole and methyl-1H-benzotriazole in an amount from about 0.001 percent by weight to about 1.0 percent by weight.

Preferably, the semiconductor workpiece has at least one feature thereon comprising copper, and the polishing composition further comprises a hydroxylamine compound in an amount sufficient for chemical etching of the at least one feature comprising copper, an abrasive, and a pH in a range of from approximately 2.0 to approximately 12.0. The hydroxylamine may be freebase, hydroxylamine sulfate, hydroxylamine nitrate or hydroxylamine phosphate and may be present in amounts from about approximately 0.3 to approximately 10 percent by weight.

Amidoxime Containing Compounds

In one embodiment of the invention, the content of the amidoxime in the polishing slurry of the present invention is set preferably not less than 0.001 wt %, more preferably not less than 0.005 wt % and still more preferably not less than 0.01 wt %, but preferably not greater than 5 wt %, more preferably not greater than 1 wt % and still more preferably not greater than 0.5 wt %.

A preferred source of the amidoxime group is from a nitrite compound that is derived from the cyanoethylation of a compound selected from the group consisting of sugar alcohols, hydroxy acids, sugar acids, monomeric polyols, polyhydric alcohols, glycol ethers, polymeric polyols, polyethylene glycols, polypropylene glycols, amines, amides, imides, amino alcohols, and synthetic polymers.

The reaction of nitrite-containing compounds with hydroxylamine are as follows, for example:

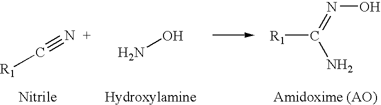

The amidoxime structure can be represented in their resonance form as illustrated below

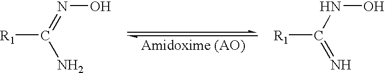

Amidoximes are made by the reaction of hydroxylamine with nitrite compounds. The most preferred compounds which undergo cyanoethylation include the following:

Compounds containing one or more —OH or —SH groups, such as water alcohols, phenols, oximes, hydrogen sulphide and thiols.

Compounds containing one or more —NH— groups, e.g., ammonia, primary and secondary amines, hydrazines, and amides.

Ketones or aldehydes possessing a —CH—, —CH₂—, or CH₃ group adjacent to the carbonyl group.

Compounds such as malonic esters, malonamide and cyanoacetamide, in which a —CH— or —CH₂— group is situated between, —CO₂R, —CN, or —CONH— groups.

A list of the above compounds can be found in the CRC Handbook—Table for Organic Compound Identification, 3^{rd} Ed. Published by The Chemical Rubber Company, such Table is incorporated herein by reference.

In one embodiment of the invention, the amidoxime compound is selected from the group consisting of 1,2,3,4,5,6-hexakis-O-[3-(hydroxyamino)-3-iminopropyl Hexitol, 3,3′,3″,3′″-(ethane-1,2-diylbis(azanetriyl))tetrakis(N′-hydroxypropanimidamide), 3,3′-(ethane-1,2-diylbis(oxy))bis(N′-hydroxypropanimidamide), 3-(diethylamino)-N′-hydroxypropanimidamide, 3,3′-(piperazine-1,4-diyl)bis(N′-hydroxypropanimidamide), 3-(2-ethoxyethoxy)-N′-hydroxypropanimidamide, 3-(2-(2-(dimethylamino)ethoxy)ethoxy)-N′-hydroxypropanimidamide, N′-hydroxy-3-(phenylamino)propanimidamide, 3,3′,3″-nitrilotris(N′-hydroxypropanimidamide), 3,3′-(2,2-bis((3-(hydroxyamino)-3-iminopropoxy)methyl)propane-1,3-diyl)bis(oxy)bis(N-hydroxypropanimidamide), 3,3′-(2,2′-(methylazanediyl)bis(ethane-2,1-diyl)bis(oxy))bis(N′-hydroxypropanimidamide), N,N-bis(3-amino-3-(hydroxyimino)propyl)acetamide, 3,3′-(2-(N′-hydroxycarbamimidoyl)phenylazanediyl)bis(N′-hydroxypropanimidamide), 3,3′-(2,2′-(3-amino-3-(hydroxyimino)propylazanediyl)bis(ethane-2,1-diyl))bis(oxy)bis(N′-hydroxypropanimidamide), N′,3-dihydroxypropanimidamide, NN′-hydroxyacetimidamide, N′-hydroxy-3-(methylamino)propanimidamide, N′-hydroxybenzimidamide, 3,3′-azanediylbis(N′-hydroxypropanimidamide), N′-hydroxyoctanimidamide, N′-hydroxy-3-phenylpropanimidamide, 3-amino-N-hydroxy-3-(hydroxyimino)propanamide, 3-amino-3-(hydroxyimino)propanoic acid, 3-amino-3-(hydroxyimino)propanamide, N′1,N′6-dihydroxyadipimidamide, N′1,N′10-dihydroxydecanebis(imidamide), N′-hydroxyisonicotinimidamide, N′-hydroxy-3-methylbenzimidamide, isoindoline-1,3-dione dioxime, N′2-dihydroxyacetimidamide, 2-chloro-N′-hydroxyacetimidamide, product N′-hydroxy-2-phenylacetimidamide, 2-amino-N′-hydroxybenzimidamide, 2,2′-azanediylbis(N′-hydroxyacetimidamide), N′-hydroxy-1-oxo-1,3-dihydroisobenzofuran-5-carboximidamide, 3-aminoisoquinolin-1(4H)-one oxime or 3-(hydroxyamino)-3,4-dihydroisoquinolin-1-amine, N′-hydroxycinnamimidamide, 4-cyano-N′-hydroxybutanimidamide, 4-chloro-N′-hydroxybenzimidamide and salts thereof.

Formulations containing amidoximes may optionally include other complexing agents and the amidoxime compound could have other functional groups that have a chelate functionality within the molecule itself.

The compositions of the present application include semiconductor processing compositions comprising water and at least one compound containing at least one amidoxime functional group. It a preferred embodiment the at least one amidoxime functional groups are derived from a nitrile compound.

In some embodiments the nitrile compound is derived from the cyanoethylation of a compound selected from the group consisting of sugar alcohols, hydroxy acids, sugar acids, monomeric polyols, polyhydric alcohols, glycol ethers, polymeric polyols, polyethylene glycols, polypropylene glycols, amines, amides, imides, amino alcohols, and synthetic polymers.

In use in CMP applications, the cleaning agent may further include one or more oxidizers and one or more surface-active agents, such as a surfactant in the classes disclosed herein (anionic surfactants, Zwitter-ionic surfactants, multi-ionic surfactants, or combinations thereof). Examples of such surfactants are: sodium salts of polyacrylic acid, potassium oleate, sulfosuccinates, sulfosuccinate derivatives, sulfonated amines, sulfonated amides, sulfates of alcohols, alkylanyl sulfonates, carboxylated alcohols, alkylamino propionic acids, alkyliminodipropionic acids, and combinations thereof and wherein the surfactant comprises between about 0.001 to about 10 percent by weight of the composition.

In CMP applications the pH may be adjusted to between about 2 and about 11. In one embodiment of the invention, the pH ranges from about 5 to about 11. Preferable additives for pH adjustment are acetic acid, phosphoric acid, oxalic acid, and combinations thereof and wherein the composition has a pH between about 2 and about 11.

Such chemistries in CMP applications may be slurries including abrasive particles comprising about 0.1 to about 50% of the cleaning slurry, more preferably about 35 wt. % or less of the composition, such as less than 10% or 5% of the composition, and wherein the abrasive particles comprise materials selected from the group of silica, alumina, titanium oxide, zirconium oxide, cerium oxide, and combinations thereof. The chemistries may also comprise one or more corrosion inhibitors, water, and combinations thereof.

In some embodiments the one or more compounds containing at least one amidoxime group in situ with a first CMP composition between about 30 seconds and about 300 seconds after the first CMP composition is delivered to the polishing pad.

In another embodiment, the compositions herein are diluted prior to use in an amount of up to about 1000 parts water by weight to about 1 part of the composition by weight, more preferably up to about 500 parts water by weight to about 1 part of the composition, or up to about 100 parts water by weight to about 1 part of the composition or up to about 10 parts water by weight to about 1 part of the composition, or 1 part water to about 1 part of the composition, including ratios in between. The dilution is done prior to use in some embodiments and after use in another embodiment. When done prior to use, the water is added, for example, within about one week, or about one day, or about one hour. It has been found that the fresh dilution is more effective than if said dilution occurred greater than about one week from use. By use, for example, the mixture is contacted with a substrate.

Organic Acid and/or Basic Component

In embodiments of the present invention, the aqueous composition may include: a) a monofunctional, difunctional or trifunctional organic acid; and/or b) a buffering amount of one or more basic compounds selected from quaternary amines, hydroxylamine, hydroxylamine derivatives (including salts), hydrazine or hydrazine salt base, ammonium compounds, and one or more alkanolamines.

In another embodiment, the composition contains at least one alkaline (basic) compound that is an alkanolamine. Preferred alkanolamines are monoethanolamine, 2-(2-hydroxyethylamino)ethanol, 2-(2-aminoethoxy)ethanol, N,N,N-tris(2-hydroxyethyl)-ammonia, isopropanolamine, 3-amino-1-propanol, 2-amino-1-propanol, 2-(N-methylamino)ethanol, 2-(2-aminoethylamino)ethanol, and mixtures thereof.

Suitable organic acids include methanesulfonic acid, oxalic acid, acetic acid, lactic acid, citric acid, xylenesulfonic acid, toluenesulfonic acid, formic acid, tartaric acid, propionic acid, benzoic acid, ascorbic acid, gluconic acid, malic acid, malonic acid, succinic acid, gallic acid, butyric acid, trifluoracetic acid, glycolic, and mixtures thereof.

Chelating Agents. In another alternative or additional embodiment, the aqueous composition can include a chelation agent that will complex with transition metal ions and mobile ions. In a preferred embodiment, the chelation agent includes ethylene diamine tetraacetic acid (EDTA), an oxime, 8-hydroxy quinoline, a polyalkylenepolyamine or a crown ether. In one embodiment of the invention, the composition comprises a chelating agent and/or corrosion inhibitor.

Oxidizing Agents. In another alternative or additional embodiment, the aqueous composition can include an oxidizing agent that will maintain metal film oxide layers. In a preferred embodiment, the oxidizing agent includes ammonium peroxydisulfate, peracetic acid, urea hydroperoxide, sodium percarbonate or sodium perborate. Other oxidizing agents include hydrogen peroxide; hydroxylamine and its salts; nitrate, sulfate, chloride and mixtures, a peracetic acid, perchloric acid, periodic acid and mixtures thereof; persulfates such as ammonium persulfate, sodium persulfate and potassium persulfate, Na₂O₂, Ba₂O₂ and (C₆H₅C)₂O₂; hypochlorous acid (HClO); organic peroxides (ketoneperoxides, diacylperoxides, hydroperoxides, alkylperoxides, peroxyketals, alkylperesters, peroxycarbonates, water-soluble peroxides and such). Among these, hydrogen peroxide (H₂O₂) and hydroxylamine, hydroxylamine sulfate, hydroxylammonium salts and mixtures thereof are preferable because they do not contain a metal component or do not generate a harmful byproduct.

A content of the oxidizing agent to the total amount of the polishing slurry in the polishing slurry of the present invention is appropriately set within a range of 0.01 to 10 wt %, taking the polishing efficiency, the polishing accuracy and the like into consideration. The content thereof is set preferably not less than 0.05 wt % and more preferably not less than 0.1 wt % to achieve a better polishing rate; but preferably not greater than 5 wt % and more preferably not greater than 3 wt % to suppress the dishing and regulate the polishing rate.

The cleaning agents of the current invention include chelation. The cleaning action of the current invention efficiently removes residual particles from the surface of the semiconductor work-piece and also complexes the metal that is removed in solution. Thus the cleaning efficiency is improved by presenting metal from re-depositing on the semiconductor work-piece surface.

The corrosion inhibitors in the present invention can prevent the copper-based metal from eluting out by forming a coating film on the surface of the copper film, and thereby contribute to the suppression of excessive polishing of the copper-based metal. Moreover, if this compound is utilized together with an amidoxime compound, described herein, the excessive polishing of the copper-based metal can be reduced even more and, thus, the dishing is suppressed still further than that when the copper corrosion inhibitor based compound is singly utilized.

Examples of copper corrosion inhibitors are dithiocarbamate, benzotriazole, thiosulfate, etc.

Examples of such a benzotriazole-based compound, that is, benzotriazole or its derivative, include benzotriazole without substitution and substituted benzotriazoles such as 1-hydroxybenzotriazole, 4-hydroxybenzotriazole, 2,3-dicarboxybenzotriazole, 2,3-dicarboxypropylbenzotriazole, 4-carboxyl-1H-benzotriazole, 4-methoxycarbonyl-1H-benzotriazole, 4-butoxycarbonyl-1H-benzotriazole and methyl-1H-benzotriazole.

A content of the corrosion inhibiting compound in the polishing slurry of the present invention is set preferably not less than 0.001 wt %, more preferably not less than 0.005 wt % and still more preferably not less than 0.01 wt %, but preferably not greater than 0.5 wt %, more preferably not greater than 0.2 wt % and still more preferably not greater than 0.1 wt %. When the content of the compound is too low, its effect of reducing the excessive polishing of the copper-based metal becomes small. On the other hand, even if the content of the compound is set higher than necessary, the reducing effect matching with that content cannot be obtained.

Surprisingly, and beneficially, compositions of the current invention are not highly sensitive to oxygen because it does not contain any oxygen sensitive compounds. Because the cleaning solution is not highly sensitive to oxygen, the performance of the cleaning solution is not affected by the presence of air in the cleaning equipment. Thus, the cleaning solution of the current invention can be used without extra precautions to purge the storage, transfer and cleaning equipment of essentially all air.

The cleaning solution of the current invention cleans the semiconductor work-piece and forms a corrosion-inhibiting film on the metal surfaces in the same step. Because the cleaning and corrosion inhibiting is accomplished in a single step, there is less likelihood of accidental contamination by handling a completely separate solution. Furthermore, valuable processing time is saved by not having to add an additional inhibiting step. Some preferred embodiments of the cleaning solution include a surface-active agent, also referred to as a surface-wetting agent. The surface-active agent helps prevent spotting (watermarks) on the surface that can be a source of contamination or hide defects in the semiconductor work-piece.

In some embodiments of the present invention can be used synergistically with an Post CMP Cleaner containing a compound containing one or more amidoxime functional group in a semiconductor application wherein the amidoxime compound complexes with metal (or metal oxide) on a surface, in a residue, or both. Optionally, the compositions of the present invention contain one or more organic solvents. Optionally, the compositions contain one or more surfactants. Optionally, the composition contains one or more additional compounds that contain functional groups which complex or chelate with metals or metal oxides. Optionally, the compositions contain a compound which has oxidation and reduction potentials, such as a hydroxylamine or hydroxylamine derivative, such as a salt, and hydrogen peroxide.

The methods of the present invention may also use compositions that are substantially free from fluoride-containing compounds, acid compounds, organic solvents, alkanolamines, quaternary ammonium compounds, hydroxylamine and hydroxylamine derivatives, non-hydroxyl-containing amines, alkanolamines, non-amidoxime group chelating agents, and surfactants.

The compositions herein may contain substantially no additional components.

In some embodiments the organic solvent, which is miscible with water, is in an amount from about 5% to about 15% by weight. Other preferred embodiments contain a surface active agent, such as: (a) non-ionic; (b) anionic; (c) cationic; (d) zwitterionic; (e) amphoteric surfactants; (f) and mixtures thereof.

In some embodiments, the cleaning agent further comprises a surface-active agent is selected from the group consisting of: (a) non-ionic; (b) anionic; (c) cationic; (d) zwitterionic; (e) amphoteric surfactants; (f) and mixtures thereof and/or at least one basic compound which includes one or more alkanolamines selected from the group consisting of monoethanolamine, 2-(2-hydroxyethylamino)ethanol, 2-(2-aminoethoxy)ethanol, N,N,N-tris(2-hydroxyethyl)-ammonia, isopropanolamine 3-amino-1-propanol, 2-amino-1-propanol, 2-(N-methylamino)ethanol, 2-(2-aminoethylamino)ethanol, and mixtures thereof in an amount from about 0.5% to about 5% by weight.

It is preferred that the amidoxime group is derived from a nitrile compound that is derived from the cyanoethylation of a compound selected from the group consisting of sugar alcohols, hydroxy acids, sugar acids, monomeric polyols, polyhydric alcohols, glycol ethers, polymeric polyols, polyethylene glycols, polypropylene glycols, amines, amides, imides, amino alcohols, and synthetic polymers.

In other embodiments the cleaning agent or compositions are diluted before use or replenished during or after use where up to 500 pas water is added to said composition within about one day prior to contacting the resulting mixture to a substrate. At some times the up to 500 parts water is added to said composition within about one hour prior to contacting the resulting mixture to a substrate.

The embodiments herein may have another chelating agent which does not contain an amidoxime functional group, such as ethylene diamine tetraacetic acid, an oxime, 8-hydroxy quinoline, a polyalkylenepolyamine, and a crown ether and/or an oxidizing agent to maintain metal film oxide layers, such as ammonium peroxydisulfate, peracetic acid, urea hydroperoxide, sodium percarbonate or sodium perborate.

### BRIEF DESCRIPTION OF THE FIGURES

In order to facilitate a fuller understanding of the present disclosure, reference is now made to the accompanying figures. These figures should not be construed as limiting the present disclosure, but are only intended to be exemplary. It will be obvious to the skill in the art that the cleaning performance can be adjusted by varying time, temperature, pH, composition, and dilution of the present invention.

FIG. 1 is a plot showing the amount of copper thickness loss over time using three different compositions—one including hydrogen peroxide, one including amidoxime and one including hydrogen peroxide and amidoxime. This therefore illustrates the unexpected result of the amidoxime compound inhibiting copper oxidation in the presence of strong oxidizer, such as hydrogen peroxide.

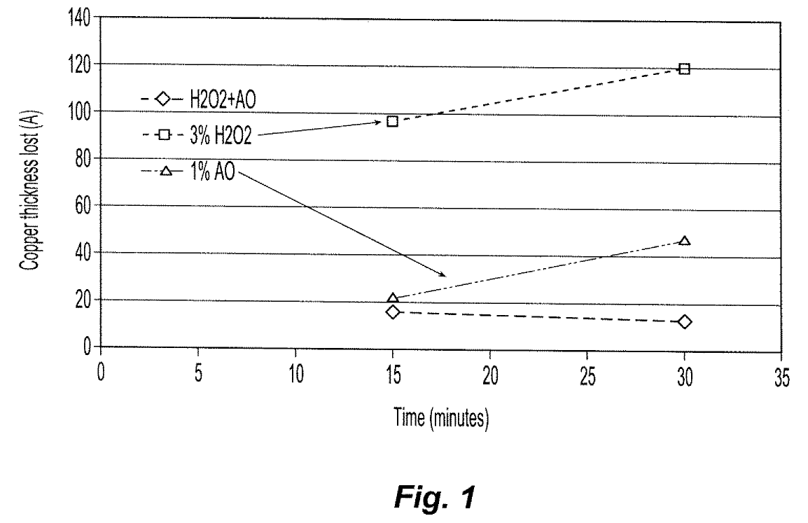

FIG. 2 shows SEM images of amidoxime solution (DS6-10) of the invention effectively removing particle and copper oxide from the substrate surface without damaging the copper surface. Comparative SEM images are shown for exposure of the surface to EKC5510 from EKC Technology. The surface was exposed to the solution at 60° C. up to 4 hours.

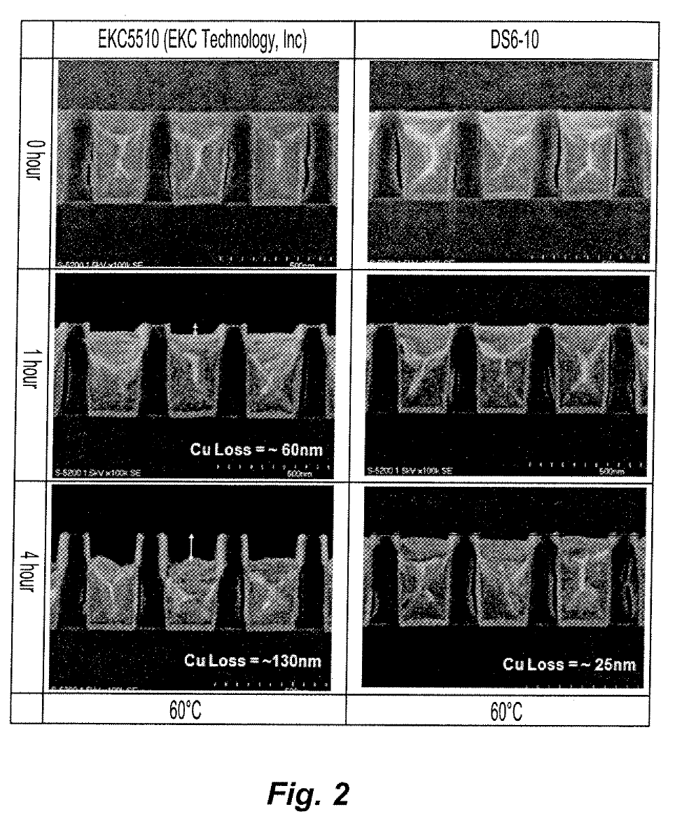

### DESCRIPTION OF PREFERRED EMBODIMENTS

The present invention relates to a slurry for chemical mechanical polishing, which comprises an amidoxime chelating agent and an abrasive material—polishing material and optionally a sufficient amount of a selectively oxidizing compound, an acid or base to adjust the pH of the composition to the proper ranges that makes polishing composition to provide the differential removal of the metal film, barrier metal film and the dielectric material. Some embodiments include corrosion inhibitors.

The present invention can polish and remove a barrier metal film at a satisfactory polishing rate and, at the same time, can keep a polishing rate for a copper-based metal film for filling low and, consequently, can effectively reduce the occurrence of dishing.

Compound with at Least One Amidoxime Functional Group

Examples of such amidoxime can be prepared from reacting hydroxylamine with a nitrile compound illustrated in the equation below, for example. Herein a number of amidoxime compounds are disclosed in addition to the example below. Any such compound is for use with the present invention.

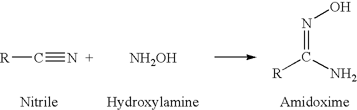

A content of the amidoxime in the polishing slurry of the present invention is set preferably not less than 0.001 wt %, more preferably not less than 0.005 wt % and still more preferably not less than 0.01 wt %, but preferably not greater than 5 wt %, more preferably not greater than 1 wt % and still more preferably not greater than 0.5 wt %.

Oxidizing Compound

The oxidizer includes, in some embodiments of the present invention, hydrogen peroxide; hydroxylamine and its salts; nitrate, sulfate, chloride and mixtures; a peracetic acid, perchloric acid, periodic acid and mixtures thereof, persulfates such as ammonium persulfate, sodium persulfate and potassium persulfate, Na₂O₂, Ba₂O₂ and (C₆H₅C)₂O₂; hypochlorous acid (HClO); organic peroxides (ketoneperoxides, diacylperoxides, hydroperoxides, alkylperoxides, peroxyketals, alkylperesters, peroxycabonates, water-soluble peroxides and such). Among these, hydrogen peroxide (H₂O₂) and hydroxylamine, hydroxylamine sulfate, hydroxylammonium salts and mixtures thereof are preferable because they do not contain a metal component or do not generate a harmful byproduct.

A content of the oxidizing agent to the total amount of the polishing slurry in the polishing slurry of the present invention is appropriately set within a range of 0.01 to 10 wt %, taking the polishing efficiency, the polishing accuracy and the like into consideration. The content thereof is set preferably not less than 0.05 wt % and more preferably not less than 0.1 wt % to achieve a better polishing rate; but preferably not greater than 5 wt % and more preferably not greater than 3 wt % to suppress the dishing and regulate the polishing rate. When the content of the oxidizing agent is too low, the chemical effects of the polishing slurry become small so that the polishing rate obtained may become insufficient or the damage may become liable to appear on the polished face. On the other hand, when the content of the oxidizing agent is too high, its etching capability (chemical effect) against the copper-based metal increases and the dishing may become liable to occur.

In the case that hydrogen peroxide is utilized as an oxidizing agent, an excellent polishing slurry can be obtained by adding, for example, an aqueous solution of hydrogen peroxide with a concentration of 30 wt % to a concentration of 1 to 5 wt % in the slurry (H₂O₂ concentration: 0.3 to 1.5 wt %). When such an oxidizing agent relatively susceptible to deterioration with age as hydrogen peroxide is used, it is possible to make separate preparations of a solution containing, along with a stabilizer and the like, an oxidizing agent at a given concentration and a composition which is to produce a prescribed polishing slurry on addition of the above solution containing the oxidizing agent, and mix them together just before use.

Additional Complexing Agent

Additionally, pursuant to some embodiments of the present invention, the polishing slurry may further include other complexing agent for copper, such as such as carboxylic acids and amino acids.

As carboxylic acids, there can be given, for instance, oxalic acid, malonic acid, tartaric acid, malic acid, glutaric acid, citric acid, maleic acid, formic acid, acetic acid, propionic acid, butyric acid, valeric acid, acrylic acid, lactic acid, succinic acid, nicotinic acid and their salts.

As amino acids, there can be given, for instance, arginine, arginine hydrochloride, arginine picrate, arginine flavianate, lysine, lysine hydrochloride, lysine dihydrochloride, lysine picrate, histidine, histidine hydrochloride, histidine dihydrochloride, glutamic acid, sodium glutaminate monohydrate, glutamine, glutathione, glycylglycine, alanine, β-alanine, γ-aminobutyric acid, .epsilon.-aminocarproic acid, aspartic acid, aspartic acid monohydrate, potassium aspartate, calcium aspartate trihydrate, tryptophan, threonine, glycine, cysteine, cysteine hydrochloride monohydrate, oxyproline, isoleucine, leucine, methionine, ornithine hydrochloride, phenylalanine, phenylglycine, proline, serine, tyrosine and valine.

As inorganic acids, there can be given, for instance, nitric acid, nitrous acid, sulfuric acid, sulfurous acid, persulfuric acid, boric acid, perboric acid, phosphoric acid, phosphorous acid, hypophosphorous acid and silicic acid.

An added feature for this invention is to add small quantities of metal ion chelators which could include di-, tri-, tetra-functional groups, i.e., EDTA, citric acid, oximes, lactic acid, 8-hydroxy quinoline and other well known agents that will chelate with metal ions under acid conditions. Other possible agents are polyethylene oxide, polyethyleneimine and crown ethers. These latter two compounds have varying affinity for mobile ions (Li, Na, K, and certain alkaline earth ions). Concentrations preferably vary from 0.01 to 10 wt %.

Corrosion Inhibitors

The corrosion-inhibiting compound of the current invention protects the metal of the semiconductor work-piece from oxidation, and corrosion. The corrosion-inhibiting compounds are effective at forming a film on the metal of the semiconductor work-piece that protects metal surfaces from chemical, galvanic and photo-induced attack during and after the cleaning step. One preferred embodiment forms a protective film by reducing the surface of the metal. By protecting the metal surface from attack, the metal retains its desired thickness and electrical carrying capacity.

Some embodiments of the present invention include corrosion inhibitors such as benzotriazole, 2,4-pentadione dioxime (which may also be referred to as 2,4-pentanedione dioxime), and/or 1,6-dioxaspiro[4,4]nonane 2,7-dione.

The corrosion inhibitors in the present invention can prevent the copper-based metal from eluting out by forming a coating film on the surface of the copper film, and thereby contribute to the suppression of excessive polishing of the copper-based metal. Moreover, if this compound is utilized together with an amidoxime compound, described herein, the excessive polishing of the copper-based metal can be reduced even more and, thus, the dishing is suppressed still further than that when the copper corrosion inhibitor based compound is singly utilized.

Examples of copper corrosion inhibitors are dithiocarbamate, benzotriazole, thiosulfate, etc.

Examples of such a benzotriazole-based compound, that is, benzotriazole or its derivative, include benzotriazole without substitution and substituted benzotriazoles such as 1-hydroxybenzotriazole, 4-hydroxybenzotriazole, 2,3-dicarboxybenzotriazole, 2,3-dicarboxypropylbenzotriazole, 4-carboxyl-1H-benzotriazole, 4-methoxycarbonyl-1H-benzotriazole, 4-butoxycarbonyl-1H-benzotriazole and methyl-1H-benzotriazole.

A content of the corrosion inhibiting compound in the polishing slurry of the present invention is set preferably not less than 0.001 wt %, more preferably not less than 0.005 wt % and still more preferably not less than 0.01 wt %, but preferably not greater than 0.5 wt %, more preferably not greater than 0.2 wt % and still more preferably not greater than 0.1 wt %. When the content of the compound is too low, its effect of reducing the excessive polishing of the copper-based metal becomes small. On the other hand, even if the content of the compound is set higher than necessary, the reducing effect matching with that content cannot be obtained.

Surfactants

One preferred cleaning solution of the present invention includes a surface-active agent to promote even wetting of the semiconductor surface. Preferred embodiments include, but are not limited to, non-ionic, anionic, cationic, zwitterionic or amphoteric surfactants or mixtures thereof. Surfactants (nonionics, anionics and cationics) can be included in these formulations. Though the surface tensions for the CMIP solutions preferably may be about 70 dynes/cm, there may be special situations were the surface tension needs to be reduced.

Other Additives

The CMP slurry of the present invention may contain a variety of additives such as a dispersing agent, a buffer agent and a viscosity modifier, which are in wide use as common additives to the polishing slurry, provided that they do not affect adversely the properties of the slurry.

Abrasive Component

Colloidal silica and milled alumina are typically used as abrasive components pursuant to some embodiments of the present invention. For a polishing material in the present invention, a silica polishing material such as colloidal silica or fumed silica is utilized, viewed from the points of the control over the polishing of the copper-based metal film, the reduction of scratches on the polished face and the dispersion stability of the slurry, and, among them, colloidal silica is particularly preferable.

In respects of the polishing rate, the polishing accuracy, the dispersion stability, the surface roughness of the polished face and the like, the average particle size of the silica polishing material, measured by the light scattering diffraction method, is preferably not less than 5 nm, more preferably not less than 10 nm and still more preferably not less than 20 nm, but preferably not greater than 300 nm, more preferably not greater than 100 nm and still more preferably not greater than 80 nm.

A content of the silica polishing material to the total amount of the polishing slurry in the polishing slurry is appropriately set within a range of 0.1 to 50 wt % taking the polishing efficiency, the polishing accuracy and the like into consideration. In particular, from the viewpoints of the polishing rate, the dispersion stability, the surface roughness of the polished face and the like, it is set preferably not less than 0.5 wt % and more preferably not less than 1 wt %, but preferably not greater than 35 wt %, more preferably not greater than 10% or not greater than 5 wt %.

pH

A pH value of the CMP slurry of the present invention is set to be preferably in a range of pH 1 to 7, more preferably in a range of pH 2 to 5 and still more preferably in a range of pH 2 to 4. By employing a CMP slurry whose pH is in such a range, it is possible to carry out the polishing wherein the excessive polishing of the copper-based metal film is well suppressed, while the polishing rate for the barrier metal is kept high. The CMP slurry of the present invention may contain an acidic compound when needed. The acidic compound can enhance the oxidation effect brought about by the oxidizing agent, and besides, through the control of its content, it can facilitate the adjustment of the polishing rate for the copper-based metal as well as the pH regulation and the pH stabilization.

A content of the acidic compound in the CMP slurry is set appropriately within a range of 0 to 5 wt %, preferably in a range of 0.005 to 2 wt % and more preferably in a range of 0.01 to 1 wt %. When the content of the acidic compound is too low, its addition does not produce sufficient effects. On the other hand, when its content is too high, the polishing rate for the copper-based metal film may become, in some cases, unnecessarily high.

For the acidic compound described above, any one of organic acids such as carboxylic acids and amino acids as well as various inorganic acids can be employed.

As carboxylic acids, there can be given, for instance, oxalic acid, malonic acid, tartaric acid, malic acid, glutaric acid, citric acid, maleic acid, formic acid, acetic acid, propionic acid, butyric acid, valeric acid, acrylic acid, lactic acid, succinic acid, nicotinic acid and their salts. As amino acids, there can be given, for instance, arginine, arginine hydrochloride, arginine picrate, arginine flavianate, lysine, lysine hydrochloride, lysine dihydrochloride, lysine picrate, histidine, histidine hydrochloride, histidine dihydrochloride, glutamic acid, sodium glutaminate monohydrate, glutamine, glutathione, glycylglycine, alanine, β-alanine, γ-aminobutyric acid, ε-aminocarproic acid, aspartic acid, aspartic acid monohydrate, potassium aspartate, calcium aspartate trihydrate, tryptophan, threonine, glycine, cysteine, cysteine hydrochloride monohydrate, oxyproline, isoleucine, leucine, methionine, ornithine hydrochloride, phenylalanine, phenylglycine, praline, serine, tyrosine and valine.

As inorganic acids, there can be given, for instance, nitric acid, nitrous acid, sulfuric acid, sulfurous acid, persulfuric acid, boric acid, perboric acid, phosphoric acid, phosphorous acid, hypophosphorous acid and silicic acid.

The type of organic acid is very important. Some possible acids and their pKₐ's are as follows:

| | | pKₐ₁ | pKₐ₂ | pKₐ₃ |
|---|---|---|---|---|
| Monobasic | Formic | 3.8 | | |
| | Acetic | 4.8 | | |
| | Propionic | 4.9 | | |
| | n-Butyric | 4.9 | | |
| | Isobutyric | 4.8 | | |
| | Benzoic | 4.2 | | |
| Dibasic | Ascorbic | 4.2 | 11.6 | |
| | Gluconic | 3.5 | 4.7 | |
| | Malic | 3.4 | 5.1 | |
| | Malonic | 2.8 | 5.7 | |
| | Oxalic | 1.3 | 4.3 | |
| | Succinic | 4.1 | 5.6 | |
| | Tartaric | 2.9 | 4.2 | |
| Tribasic | Citric | 3.1 | 4.8 | 6.9 |
| | Gallic | 4.2 | 8.9 | |

General Structure for the Acid

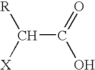

X=—OH, —NHR, —H, -Halogen, —CO₂H and —CH₂COOH, —CH(OH)—COOH R generally aliphatic, H or aromatic

The important factor is the solubility of the acid and base products with any additional agents in the aqueous solutions.

A caustic component can be used to adjust the pH. Although the pH adjustment can be achieved with any common base, i.e. sodium, potassium, magnesium etc. hydroxides, such bases introduce mobile ions into the final formulation. Mobile ions can easily destroy computer chips being produced today in the semiconductor industry. Accordingly, embodiments of the present invention are free of bases that introduce mobile ions, In such embodiments, other bases are used, including organic amines, carbonates, hydroxylamine, quaternary amines such as tetramethylammonium hydroxide (TMAH) or choline or THEMAH or ammonium hydroxide.

The present invention can polish and remove a barrier metal film at a satisfactory polishing rate and, at the same time, can keep a polishing rate for a copper-based metal film for filling low and, consequently, can reduce the occurrence of dishing.

The present invention overcomes one or more of the shortcomings of the prior art by providing CMP slurry compositions that have one or more of the following characteristics: 1) an improved copper/barrier selectivity; 2) an ability to planarize the copper portion of a copper and tantalum and/or a tantalum nitride layer at desired high planarization rates while reducing copper dishing and erosion; and 3) good within-wafer-non uniformity values.

An amidoxime in the present invention can reduce the excessive polishing of the copper-based metal even more when used together with the afore-mentioned benzotriazole compound than when used singly.

For a method of preparing the CMP polishing slurry of the present invention, an ordinary method of preparing an aqueous polishing slurry composition with free grains can be applied. Specifically, an appropriate amount of a polishing material is added to an aqueous solvent and then, if necessary, with an appropriate amount of a dispersing agent being added, a treatment of dispersion is carried out. In the step of the dispersion, for example, an ultrasonic disperser, a bead mill disperser, a kneader disperser, a ball mill disperser or the like may be used, according to the circumstances.

The CMP using a CMP slurry of the present invention may be, for example, conducted in the following way. Firstly, there is provided a substrate, wherein an insulating film is formed and a sunken section in prescribed pattern shape is formed in the insulating film and, thereon, a copper-based metal film is grown. This substrate is placed on a wafer carrier such as a spindle. With a prescribed pressure applied, the surface of this copper-based metal film in this substrate is made to contact with a polishing pad which is adhered onto a surface plate such as a rotary plate, and while supplying a polishing slurry between the substrate and the polishing pad, the wafer and the polishing pad are moved relative to each other (for instance, both of them are rotated) and thereby the wafer is polished. The polishing slurry may be supplied onto the polishing pad from a supply tube set separately or it may be supplied onto the surface of the polishing pad from the side of the surface plate. If necessary, a pad conditioner may be brought into contact with the surface of the polishing pad to condition the surface of the polishing pad.

The CMP slurry of the present invention described above can be applied with effect to a polishing treatment wherein a sunken section such as a trench or a connection hole is formed in an insulating film laid on a substrate, and by polishing, by the CMP method, a copper-based metal film which is formed over the entire surface thereof so as to fill up this sunken section with a barrier metal film lying therebetween, an electrical connection section such as a buried interconnection, a via plug, a contact is formed. As an insulating film, there can be given a silicon oxide film, a BPSG (Boro-Phospho-Silicate Glass) film, a SOG (Spin-on-Glass) film, a SiOF film, a HSQ (Hydrogen Silses-Quioxane) film, a SiOC film, a MSQ (MethylSilses-Quioxane) film, a polyimide film, a Parylene® film (polyparaxylylene film), a Teflon® film and an amorphous carbon film. As a barrier metal film well suited to the copper-based metal film, that is, the copper film or the copper alloy film whose main component is copper, there can be given a tantalum-based metal film made of tantalum (Ta), tantalum nitride, tantalum silicon nitride or the like.

In the afore-mentioned polishing treatment, a CMP slurry of the present invention can be applied with best effect to the step which starts with polishing of the barrier metal and, with the barrier metal other than the sunken section being polished and removed, ends in formation of an electrical connection section. For example, in the two-steps polishing method described above, the step of the second polishing is well suited for its application.

Silicon Oxide Chemistry

The mechanism for dielectric polishing is still being developed, but the polishing process appears to involve two concurrent processes; a mechanical process involving plastic deformation of the surface and, chemical attack by hydroxide (OH) to form silanol bonds.

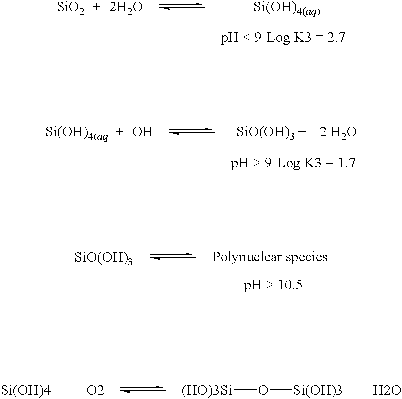

In a slurry (colloidal suspension), the pH is important and for the silicon oxide system it needs to be in the 10 to 11.5 range. Currently CMP users are using silicon oxide-based slurries which were “buffered” with sodium hydroxide but now are being formulated with potassium or ammonium hydroxide solutions. Etch rates can be in the range of 1700 A/min.

If the pH is too high the polynuclear species may start to precipitate in an unpredictable manner. There is also the possibility of an oxidation process to form Si—O—Si bonds.

There are other important features of the silicon surface that will influence the etch rates and final surface conditions (metal contamination and possibly micro scratches). As mentioned above, the typical silicon surface is terminated (covered) with —OH groups under neutral or basic conditions. The silicon surface is hydrophilic, meaning the surface is “wettable”. These groups activate the surface to a number of possible chemical or physioabsorption phenomena. The Si—OH groups impair a weak acid effect which allows for the formation of salts and to exchange the proton (H⁺) for various metals (similar to the ion exchange resins). These SiO— and Si—OH groups can also act as ligands for complexing Al, Fe, Cu, Sn and Ca. Of course the surface is very dipolar and so electrostatic charges can accumulate or be dissipated depending on the bulk solution's pH, ion concentration or charge. This accumulated surface charge can be measured as the Zeta potential.

If the silicon (Si) surface underneath the oxide layer is exposed because of an over aggressive polishing process, this could cause electrochemical problems because silicon has a modest redox potential which will allow Cu, Au, Pt, Pb, Hg and Ag to “plate on” the silica surface. Exposure to light will also effect the redox reaction for Cu. The light will “generate” electrons in the semiconductor Si material which then reduces the copper ion to Cu⁰.

Metal CMP

In CMP planarization of copper or aluminum metal films polishing relies on the oxidation of the metal surface and the subsequent abrasion of the oxide surface with an emulsion slurry. In this mechanism, the chemistry's pH is important. The general equations are (M=metal atom):

M⁰→Mⁿ⁺+ne⁻

Mⁿ⁺+[O_{x]}_{y}→MOₓ or [M(OH)ₓ]

Under ideal conditions the rate of metal oxide (MOₓ) formation (V_{f}) will equal the rate of oxide polishing (Vₚ), (V_{f}=Vₚ). If the pH is too low (acidic) then the chemistry can rapidly penetrate the oxide and attack the metal (V_{f}<Vₚ), thus exposing the metal without any further oxide formation. This means that all metal surfaces, at high points and in valleys, are removed at the same rate, Planarization of the surface is not achieved. This could cause metal plug connectors to be recessed below (“dishing”) the planarization surface which will lead eventually to poor step coverage and possible poor contact resistance.

When the pH is too high (caustic), then the oxide layer may become impenetrable to the chemistry and the metal becomes passive, (V_{f}>Vₚ) and the metal polishing rate becomes slow. Metal polishing selectively to oxide generally ranges from 20 to 100:1, depending on the metal type. Tungsten metal should have selectivities >50:1 for the metal to oxide, and copper could have >140:1 metal to oxide selectivity. Etch rates can be up to 7000 A/min. The chemical diffusion rate and the type of metal oxide surface are important to the successful planarization process. A detailed mechanism has been proposed by Kaufman, F.; J. Electrochem. Soc; 138 (11), p. 3460, 1991.

Copper films present a difficult problem because copper is a soft metal and is easily damaged by slurry particles. Aluminum is also a soft metal and is easily damaged by slurry particles. However, Aluminum differs from copper in its ability to self-passivate. Copper in its natural state does not easily form an oxide film on its surface. It is believed that the Post Clean Treatment solution can successfully polish copper in part because copper does not easily form a protective oxide layer. In contrast, Aluminum does self-passivate relatively easily. In spite of this tendency to form a protective oxide layer, surprisingly, the amidoxime CMP compositions herein are able to passivate copper to provide more controlled planarization of copper metals.

A key component of the formulations of the present invention is the presence of one or more compounds with at least one amidoxime functional group. Without being bound to any particular theory, it is understood that the multidentate complexing agents disclosed above complex with substrate surfaces to remove contaminants on such surfaces. Amidoxime molecule can be designed to function as passivation on metal surface by rendering insoluble metal complex or as cleaning agent by rendering the metal containing residue more soluble.

Amidoxime copper complexes have shown to be readily soluble in water under basic condition while less soluble under acidic condition. Accordingly, the passivating/cleaning effect of the amidoxime chemistry can be affected by altering the pH.

U.S. Pat. No. 6,166,254, for example, discusses the formation of amidoximes from aqueous hydroxylamine freebase and nitriles, such as the reaction of acetonitrile with aqueous hydroxylamine at ambient temperature to yield high purity acetamidoxime.

It will be obvious to those skills of the art that other nitriles will react with hydroxylamine freebase in similar manners.

Amidoximes have been shown to complex with metals, such as copper Amidoximes of cyanoethylated cellulose have also been shown to complex with copper and other metal ions. (See, Altas H. Basta, International Journal of Polymeric Materials, 42, 1-26 (1998)).

One preferred embodiment of the present invention is to compositions, and method of use thereof, containing a group of higher pH range chelating compounds comprising at least two functional groups where at least one such group is an amidoxime. The other groups or complexing compounds may be selected as may be beneficial for the application, the chemistry, and/or the conditions. Examples of other complexing groups include hydroxamic acid, thiohydroxamic acid, N-hydroxyurea, N-hydroxycarbamate, and N-nitroso-alkyl-hydroxylamine. These groups offer synergistic advantages when used with amidoximes of removing metal oxide, such as copper oxide, residue by rendering such oxides soluble in aqueous solutions. As with amidoximes, these functional groups can be formed by reaction with hydroxylamine or hydroxylamine derivatives.

Regarding other complexing agents that may optionally be used with amidoximes in the compositions of the present application, complexing agents may be purchased commercially or prepared by known methods. A non-exhaustive list has been previously presented.

One example of a synergistic functional group is a hydroxamic acid group. Such groups are well known (H. L. Yale, “The Hydroxamic Acids”, Chem. Rev., 209-256 (1943)). Polymers containing hydroxamic acid groups are known and can be prepared by addition of hydroxylamine to anhydride groups of anhydride-containing copolymers, such as styrene-maleic anhydride copolymer or poly(vinylmethylether/maleic anhydride) copolymers, or by reaction of hydroxylamine with ester groups. Hydroxamic acid-containing polymers can also be prepared by acid-catalyzed hydrolysis of polymers that contain amidoxime groups (U.S. Pat. No. 3,345,344).

U.S. Pat. No. 6,235,935, for example, discusses the formation of high purity oximes from aqueous hydroxylamine and ketones reacted at ambient temperature without addition of impurities such as salts or acids.

Thiohydroxamic acids are another synergistic type of functional groups with amidoximes and can be prepared by addition of hydroxylamine to dithiocarboxylic acids (H. L. Yale, Chem. Rev., 33, 209-256 (1943)).

N-hydroxyureas are another synergistic type of functional groups with amidoximes and can be prepared by reaction of hydroxylamine with an isocyanate (A. O. Ilvespaa et al., Chime (Switz.) 18, 1-16 (1964)).

N-Hydroxycarbamates are another synergistic type of functional groups with amidoximes and can be prepared by reaction of hydroxylamine with either a linear or cyclic carbonate (A. O. Ilvespaa et al., Chimia (Switz.) 18, 1-16 (1964)).

N-Nitroso-alkyl-hydroxylamines are another synergistic type of functional groups with amidoximes and can be prepared by nitrosation of alkyl hydroxylamines (M. Shiino et al., Bioorganic and Medicinal Chemistry 95, 1233-1240 (2001)).

One embodiment of the present invention involves methods of precleaning substrates or removing stripping or ashing residues using aqueous cleaning solutions which comprise at least one chelating compound with one or more amidoxime functional group. R₁ is independently selected from alkyl, heteroalkyl, aryl, heteroaryl, alkyl-heteroaryl, or alkyl-aryl group.

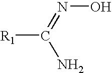

The amidoximes can be prepared by the reaction of nitrile-containing compounds with hydroxylamine.

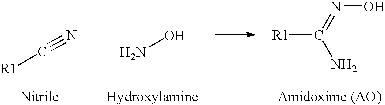

A convenient route to the formation of amidoxime chelating compounds is by adding hydroxylamine to the corresponding nitrile compound, There are several methods known for preparing nitrile-containing compounds, including cyanide addition reactions such as hydrocyanation, polymerization of nitrile-containing monomers to form polyacrylonitrile or copolymers of acrylonitrile with vinyl monomers, and dehydration of amides. Typical procedures for the syntheses of nitriles may be found in J. March, Advanced Organic Chemistry, 4th ed., John Wiley and Sons, NY, (1992).

Nitriles compounds listed in the CRC Handbook (pages 344-368) can be used in this invention include but not limited to the followings: Cyanoacetylene, Cyanoacetaldehyde, Acrylonitrile, Fluoroacetonitrile, Acetonitrile (or Cyanomethane), Trichloroacetonitrile, Methacrylonitrile (or α-Methylacrylonitrile), Proionitrile (or Cyanoethane), Isobutyronitrile, Trimethylacetonitrile (or tert-Butylcyanide), 2-Ethyacrylonitrile, Dichloroacetonitrile, α Chloroisobutyronitrile, n-Butyronitrile (or 1-Cyanopropane), trans-Crotononitrile, Allycyanide, Methoxyacetonitrile, 2 Hydroxyisobutyronitrile (or Acetone cyanohydrins), 3-Hydroxy-4-methoxybenzonitrile, 2-Methylbutyronitrile, Chloroacetonitrile, Isovaleronitrile, 2,4-Pentadienonitrile, 2-Chlorocrotononitrile, Ethoxyacetonitrile, 2-Methycrotononitrile, 2-Bromoisobutyronitrile, 4-Pentenonitrile, Thiophene-2,3-dicarbonitrile (or 2,3-Dicyanothiophene), 3,3-Dimethylacrylonitrile, Valeronitrile (or 1 Cyanobutane), 2-Chlorobutyronitrile, Diethylacetonitrile, 2-Furanecarbonitrile (or α-Furonitrile; 2 Cyanofuran), 2-Methylacetoacetonitrile, Cyclobutanecarbonitrile (or Cyanocyclobutane), 2-Chloro-3-methylbutyronitrile, Isocapronitrile (or 4-Methylpentanonitrile), 2,2-Dimethylacetoacetonitrile, 2-Methylhexanonitrile, 3-Methoxypropionitrile, n-Capronitrile (n-Hexanonitrile), (Ethylamino) acetonitrile (or N-Ethylglycinonitrile), d,l-3-Methylhexanonitrile, Chlorofumaronitrile, 2-Acetoxyropionitrile (or O-Acetyllactonitrile), 3-Ethoxyropionitrile, 3-Chlorobutyronitrilet, 3-Chloropropionitrile, Indole-3-carbonitrile (or 3-Cyanoindole), 5-Methylhexanonitrile, Thiophene-3-carbonitrile (or 3-Cyanothiophene), d,l-4-Methylhexanonitrile, d,l-Lactonitrile (or Acetaldehydecyanohydrin), Glycolnitrile (or Formaldehydecyanohydrin), Heptanonitrile, 4-Cyanoheptane, Benzonitrile, Thiophene-2-carbonitrile (or 2-Cyanothiophene), 2-Octynonitrile, 4-Chlorobutyronitrile, Methyl cyanoacetate, Dibenzylacetonitrile, 2-Tolunitrile (or 2-Methoxybenzonitrile), 2,3,3-Trimethyl-1-cyclopentene-1-carbonitrile (or □-Campholytonitrile), Caprylonitrile (or Octanonitrile), 1,1-Dicyanopropane (or Ethylmalononitrile), Ethyl cyanoacetate, 1,1-Dicyanobutane (or Propylmalononitrile), 3-Tolunitrile (or 3-Methylbenzonitrile), Cyclohexylacetonitrile, 4,4-Dicyano-1-butene (or Allylmalononitrile), 3-Isopropylidene-1-methyl-cyclopentane-1-carbonitrile (or βFencholenonitrile), 3-Hydroxypropionitrile, 1,1-Dicyano-3-methylbutane (or Isobutylmalononitrile), Nonanonitrile, 2-Phenylcrotononitrile, Ethylenecyanohydrin, 2-Phenylpropionitrile, Phenylacetonitrile (or Benzylcyanide), Phenoxyacetonitrile, 4-Hydroxy-butyronitrile, (3-Tolyl)acetonitrile (or m-Xylycyanide), (4-Tolyl)acetonitrile (or p-Xylycyanide), 4-Isopropylbenzonitrile, (2-Tolyl)acetonitrile (or o-Xylycyanide), Decanonitrile, 3-Methyl-2-phenylbutyronitrile, 1,2-Dicyanopropane, 1-Undecanonitrile (or 1-Hendecanonitrile), 2-Phenylvaleronitrile, 10-Undecenonitrile (or 10 Hendecenonitrile), 3-Phenylpropionitrile, 2-Cyanobenzalchloride (or α,α-Dichloro-m-tolunitrile), N-Methylanilinonitrile (or N-Cyano-N-methylaniline), 3-(2-Chlorophenyl)propionitrile, 1,3-Dicyano-2-methypropane (or 2-Methylglutaronitrile), O-Benzoyl lactonitrile (or Lactonitrile benzoate), 3-Cyanobenzalchloride (or α,α-Dichloro-m-tolunitrile), 4-Cyanobenzalchloride (or α,α-Dichloro-p-tolunitrile), Dodecanonitrile (or Lauronitrile), 1,3-Dicyanopropane (or Glutaronitrile), 4-Methoxyhydrocinnamonitrile (or 3-(4-Methoxyphenyl)-propionitrile), 1,4-Dicyanobutane (Adiponitrile), 1,2,2,3-Tetramethyl-3-cyclopentene-1-acetonitrile (or 5-Methyl-α-campholenonitrile), 1-Cyanocyclohexene, 2-Hydroxybutyronitrile (or Propanalcyanohydrin), Hydnocarponitrile, α-Chloro-α-phenylacetonitrile, Butyl cyanoacetate, 3-Bromopropionitrile, 2,4-Diphenylbutyronitrile, Thiophene-2-acetonitrile, Trans-4-Chirocrotononitrile, 2-Cyanopentanoic acid, Azelaonitrile (or 1,7-Dicyanoheptane), 3-Chloro-2-hydroxy-2-methylpropionitrile (or Chloroacetone cyanohydrins), 1,11-Dicyanoundecane (or 1,11-Dicyanohendecane), 2-Cyanobutyric acid, 2-Cyanobiphenyl, 1,12-Dicyanodedecane (or α,ω-Dodecane dicyanide), 1-Cyano-4-isopropenylcyclohexene, Sebaconitrile (or 1,8-Dicyanooctane), Suberonitrite (or 1,6-Dicyanohexane), 3-Cyanoindene (or Indene-3-carbonitrile), Aminoacetonitrile (or Glycinonitrile), 2-Cyanodiphenylmethane, N-Piperidinoacetonitrile, 3-Chloro-2-tolunitrile, Tetradecanonitrile, Cinnamonitrile, Trichloroacrylonitrile, DL-Mandelonitrile (or Benzaldehyde cyanohydrins), Pentadecanonitrile, 2-Methoxybenzonitrile, (2-Chlorophenyl)acetonitrile (or 2-Chlorobenzylcyanide), 1,1-Dicyanoethane (or Methylmalononitrile), 2-Cyanopyridine (or 2-Pyridinecarbonitrile; Picolinonitrile), 4-tolunitrile (or 4-Methylbenzonitrile), D-Mandelonitrile, d,l-(2-Bromophenyl)acetonitrile (or 2-Bromobenzyl cyanide), (4-Chlorophenyl)acetonitrile (or 4-Chlorobenzyl cyanide), Malononitrile (or Methylene cyanide), Hexadecanonitrile, Maleonitrile (or cis-1,2-Dicyanoethylene), 2,2-Dicyanopropane (or Dimethylmalononitrile), tert-Butylacetonitrile (or Neopentyl cyanide), 1-Naphthylacetonitrile, 4,4-Dicyanoheptane (or Dipropylmalononitrile), Heptadecanonitrile, 1-Naphthonitrile (or 1-Cyanonapthalene), 2-Cyanopropionic acid, 4-Ftuorobenzonitrile, Coumarilonitrile (or Coumarin-2-carbonitrile), Indole-3-acetonitrile, 3-Bromobenzonitrile, 2-(N-Anilino)-butyronitrile, Trans-o-Chlorocinnamonitrile, Octadecanonitrie, 3-Chlorobenzonitrile, 2-Chlorobenzonitrile, 4-Chloromandelonitrile, Nonadecanonitrile, 2-Bromo-4-tolunitrile, 3,3-Dicyanopentane (or Diethylmalononitrile), 4-Cyanobutyric acid, 5-Chloro-2-tolunitrile, (4-Aminophenyl)acetonitrile (or 4-Aminobenzyl cyanide), meso-2,3-Dimethyl-succinonitrile, 3-Bromo-4-tolunitrile, (4-Bromophenyl)acetonitrile (or 4-Bromobenzyl cyanide), N-Anilinoacetonitrile, 3-Cyanopropionic acid, 3-Chloro-4-tolunitrile, 3,3-Diphenylacrylonitrile (O-Phenylcinnamonitrile), 3-Bromo-2-hydroxy benzonitrile, 4,4-Dicyanoheptane (or Dipropylmalononitrile), trans-2,3-Diphenyl acrylonitrile, Eicosanonitrile, 3-Cyanopyridine (or Nicotinonitrile), (4-Iodophenyl)acetonitrile (or 4-Iodobenzyl cyanide), 4-Cyanodiphenyl methane, 2-(N-Anilino) valeronitrile, 2-Aminobenzonitrile (or Anthranilonitrile), 2-Bromobenzonitrile, 5-Cyanothiazole, 3-Aminobenzonitrile, 2-Quinolinoacetonitrile, 2-Iodobenzonitrile, 2,4,6-Trimethylbenzonitrile, α-Aminobenzyl cyanide, Cyanoform (or Tricyanomethane), Succinonitrile, 2-Iodo-4-tolunitrile (2-Iodo-4-methylbenzonitrile), 2,6-Dinitrobenzonitril, d,l-2,3-Dimethylsuccinonitrile, 2-Chloro-4-tolunitrile, 4-Methoxybenzonitrile, 2,4-Dichlorobenzonitrile, 4-Methoxycinnamonitrile, 3,5-Dichlorobenzonitrile, cis-1,4-Dicyanocyclohexane, Bromomalononitrile, 2-Naphthonitrile (or 2-Cyanonaphthalene), Cyanoacetic acid, 2-Cyano-2-ethylbutyric acid (or Diethylcyanoacetic acid), 2,4-Diphenylglutaronitrile, α-Chloro-3-tolunitrile, 4-Chloro-2-tolunitrile, 1-Cyanoacenaphthene (or Acenaphthene-1-carbonitrile), Phenylmalononitrile (α-Cyanobenzyl cyanide), 6-Nitro-2-tolunitrile, (4-Hydroxyphenyl)acetonitrile (or 4-Hydroxybenzyl cyanide), 5-Bromo-2-tolunitrile, α-Bromo-2-tolunitrile, 2,2-Diphenylglutaronitrile, (2-Aminophenyl)acetonitrile (or 2-Aminobenzyl cyanide), 3,4-Dichlorobenzonitrile, 1,2,2,3-Tetramethylcyclopentene-1-carbonitrile (or Campholic nitrile), Dicyanodimethylamine (or Bis(cyanomethyl) amine), Diphenylacetonitrile (α-Phenylbenzyl cyanide), 4-Cyano-N,N-dimethylaniline, 1-Cyanoisoquinoline, 4-Cyanopyridine, α-Chloro-4-tolunitrile (or 4-Cyanobenzyl chloride), 2,5-Diphenylvaleronitrile, 3-Cyanobenzaldehyde (or 3-Formyltenzonitrile), 6-Nitro-3-tolunitrile, Blenzoylacetonitrile, 6-Chloro-2-tolunitrile, 8-Cyanoquinoline, 2-Nitro-3-tolunitrile, 2,3,4,5-Tetrachforobenzonitrile, 4-Cyanobiphenyl, 2-Naphthylacetonitrile, cis-2,3-Diphenylacrylonitrile, 4-Aminobenzonitrile (or 4-Cyanoaniline), 1-Cyano-2-phenylacrylonitrile (or Benzalmalononitrile), 5-Bromo-2,4-dimethyl-benzonitrile, 2-Cyanotriphenylmethane, 5-Cyanoquinoline, 2,6-Dimethylbenzonitrile, Phenylcyanoacetic acid, 2-(N-Anilino)-propionitrile, 2,4-Dibromobenzonitrile, β-(2-Nitrophenyl)-acrylonitrile, 5-Chloro-2-nitro-4-tolunitrile, α-Bromo-3-tolunitrile (or 3-Cyanobenzyl bromide), 4-Nitro-3-tolunitrile, 2-(N-Anilino)-isobutyronitrile, 2-Cyanoquinoline, 4-Cyanovaleric acid (or 2-Methylglutaromononitrile), Fumaronitrile, 4-Chlorobeuzonitrile, 9-Phenanthrylacetonitrile, 3,5-Dibromobenzonitrile, 2-Chloro-3-nitrobenzonitrile, 2-Hydroxybenzonitrile (or 2-Cyanophenol), 4-Chloro-2-nitrobenzonitrile, 4-Cyanotriphenylmethane, 4-Chloro-3-nitrobenzonitrile, 3-Nitro-4-tolunitrile, 2-Cyano-3-phenylpropionic acid, 3-Cyanophenanthrene, 2,3,3-Triphenylpropionitrile, 4-Cyanoquinoline, 4-Bromo-1-naphthonitrile (or 1-Bromo-4-cyanonaphthalene), 4-Bromo-2,5-dimethylbenzonitrile, 5-Nitro-3-tolunitrile, 2,4-Dinitrobenzonitrile, 4-Nitro-2-tolunitrile, 6-Chloro-3-nitrobenzonitrile, 5-Bromo-3-nitro-2-tolunitrile, 2-Nitro-4-tolunitrile, 9-Cyanophenanthrene, 3-Cyanoquinoline, 2-Cyanophenanthrene, 3-Nitro-2-tolunitrile, 2-Nitrobenzonitrile, 4-Chloro-1-naphthonitrile (or 1-Chloro-4-cyanonaphthalene), 5-Cyanoacenaphthene (or Acenaphthene-5-carbonitrile), 4-Bromobenzonitrile, 2,4,5-Trimethoxybenzonitric, 4-Hydroxyhenzonitrile (or 4-Cyanophenol), 2,3-Diphenylvaleronitrile, □-Bromo-4-tolunitrile (or 4-Cyanobenzylbromide), (4-Nitrophenyl)aceto nitrile (or 4-Nitrobenzylcyanide), 6-Bromo-3-nitrobenzonitrile, (2-Hydroxyphenyl)acetonitrile (or 2-Hydroxybenzyl cyanide), 3-Nitrobenzonitrile, 4-Bromo-3-nitrobenzonitrile, 4-Cyanoazobenzene, Dipicolinonitrile (or 2,6-Dicyanopyridine), 2-Cyanohexanoic acid, Dibromomalononitrile (or Bromodicyanomethane), 1-Cyanoanthracene, 2,2,3-Triphenylpropionitrile, 1-Cyanophenanthrene, 2,3-Diphenylbutyronitrile, 5-Bromo-3-nitro-4-tolunitrile, 2,5-Dichlorobenzonitrile, 2,5-Dibromrobenzonitrile, 5-Bromo-2-nitro-4-tolunitrile, 2-Hydroxy-3-nitrobenzonitrile (or 2-Cyano-6-nitrophenol), 4-Nitro-1-naphthonitrile (or 1-Cyano-4-nitronaphthalene), 4-Acetamidobenzonitrile, 6-Cyanoquinoline, Apiolonitrile (or 2,5-Dimethoxy-3,4-methylenedioxybenzonitrile), 1-Nitro-2-naphthonitrile (or 2-Cyano-1-nitronaphthalene), 3,5-Dichloro-2-hydroxybenzonitrile, trans-1,4-Dicyanocyclohexane, 3,3,3-Triphenylpropionitrile, 4-Cyano-2-phenylquinoline (or 2-Phenyl-4-quinolinonitrile), Phthalonitrile (or o-Dicyanobenzene), 8-Nitro-2-naphthonitrile (or 2-Cyano-8-nitronaphthalene), 5-Chloro-2-naphthonitrile (or 5-Chloro-2cyanonaphthalene), 5-Chloro-1-naphthonitrile (or 5-Chloro-1-cyanonaphthalene), 3,5-Dichloro-4-hydroxybenzonitrile, 4-Nitrobenzonitrile, 5-Bromo-1-naphthonitrile (or 1-Bromo-5cyanonaphthalene), 5-Iodo-2-naphthonitrile (or 2-Cyano-5-iodonaphthalene), 3-Cyano-3-phenylpropionic Acid, 2-Cyano-2-propylvaleramide (or Dipropylcyanoacetamide), 2,6-Dibromobenzonitrile, 3-Chloro-4-hydroxybenzonitrile, 5-Chloro-2,4-dinitrobenzonitrile, 4-Benzamidobenzonitrile (or N-Benzoylanthranilonitrile), 5-Bromo-2-hydroxybenzonitrile, d,l-2,3-Diphenylsuccinonitrile, Isophthalonitrile (or m-Dicyanobenzene), 2-Hydroxy-4-nitrohenzonitrile (or 2-Cyano-5-nitrophenol), d,l-4-Cyano-3,4-diphenylbutyric acid (or d,l-2,3-Diphenylglutarornononitrile), d-3-Carboxy-2,2,3-trimethylcyclopentylacetonitrile, 5-Chloro-2-hydroxyhenzonitrile (or 4-Chloro-2-cyanophenol), 2,3-Diphenylcinnamonitrile (or Cyanotdiphenylethylene), 1,7-Dicyanonaphthalene, 4,4′-Dicyanodiphenylmethane, 2,2′-Diphenic acid mononitrile (or 2-Carboxy-2′-cyanobiphenyl), 5-Nitro-2-naphthonitrile (or 2-Cyano-5-nitronaphthalene), 9-Cyanoanthracene (or 9-Anthracenecarbonitrile), 2,3-Dicyanopyridine, 1,3-Dicyanonaphthalene, 3-Cyanocoumarin, 2-Cyanocinnamic acid, 2-Cyanobenzoic acid, 1,2-Dicyanonaphthalene, 2-Hydroxy-5-nitrobenzonitrile (or 2-Cyano-4-nitrophenol) Tetracyanoethylene, 5-Nitro-1-naphthonitrile (or 1-Cyano-5-nitronaphthalene), 1,4-Dicyanonaphthalene, 1,6-Dicyanonaphthalene, 1,5-Dicyanonaphthalene, 3-Cyanobenzoic acid, 4-Cyanobenzoic acid, Terephthalonitrile (or p-Dicyanobenzene), 1,8-Dicyanonaphthalene, 4,4′-Dicyanobiphenyl, 1-2,3-Diphenylsuccinonitrile, 1-Cyano-9,10-anthraquinone, 2,3-Dicyanonaphthalene, 2,7-Dicyanonaphthalene, 2,6-Dicyanonaphthalene.

The present invention further include the “nitrile quaternaries”, cationic nitrites of the formula

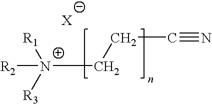

in which R1 is —H, H₃, a C₂—-alkyl or -alkenyl radical, a substituted C₂₋₂₄-alkyl or -alkenyl radical with at least one substituent from the group —Cl, —Br, —OH, —NH₂, —CN, an alkyl- or alkenylaryl radical with a C₁₋₂₄-alkyl group, or is a substituted alkyl- or alkenylaryl radical with a C₁₋₂₄-alkyl group and at least one further substituent on the aromatic ring, R.2 and R3, independently of one another, are chosen from CH₂CN, —CH₃, —CH₂CH₃, CH₂CH₂—CH₃, —CH(CH₃)—CH₃, —CH₂#H, —CH₂—CH₂—OH, —CH(OH)—CH₃, —CH₂—H₂—CH₂—OH, —CH₂H(OH)—CH₃, —CH(OH)—CH₂—CH₃, —CH₂CH₂—O)ₙH where n=1, 2, 3, 4, 5 or 6 and X is an anion.

The general formula covers a large number of cationic nitrites which can be used within the scope of the present invention. With particular advantage, the detergent and cleaner according to the invention comprise cationic nitrites in which R1 is methyl, ethyl, propyl, isopropyl or an n-butyl, n-hexyl, n-octyl, n-decyl, n-dodecyl, n-tetradecyl, nhexadecyl or n-octadecyl radical. R2 and R3 are preferably chosen from methyl, ethyl, propyl, isopropyl and hydroxyethyl, where one or both of the radicals may advantageously also be a cyanomethylene radical.

For reasons of easier synthesis, preference is given to compounds in which the radicals R₁ to R₃ are identical, for example (CH₃)₃N⁽⁺⁾CH₂CN(X⁻), (CH₃CH₂)₃N⁺CH₂—CN X⁻, (CH₃CH₂CH₂)₃N⁽⁺⁾CH₂—CN X⁻, (CH₃CH(CH₃))₃N⁽⁺⁾CH₂—CN X⁻ or (HO—CH₂—CH₂)₃N⁽⁺⁾CH₂N X⁻, where X⁻ is preferably an anion which is chosen from the group consisting of hydroxide, chloride, bromide, iodide, hydrogensulfate, methosulfate, p-toluenesulfonate (tosylate) or xylenesulfonate.

Examples of typical acrylonitrile polymeric materials, which serve as precursors for preparing our polyamidoximes, are listed below. The figures are the percents by weight of each monomer in the polymer.

| | | |
|---|---|---|
| 90% acrylonitriIe | 10% vinylacetonitrile | |
| 50%′ acrylonitrile | 50% methacrylonitrile | |
| 97% acrylonitrile | 3% vinyl acetate | |
| 50% acrylonitrile | 50% vinyl acetate | |
| 95% acrylonitrile | 5% methyl methacrylate | |
| 65% acrylonitrile | 35% methyl acrylate | |
| 45% acrylonitrile | 10% methyl acrylate | 45% vinyl acetate |
| 44% acrylonitrile | 44% vinyl chloride | 12% methyl acrylate |
| 93% acrylonitrile | 7% 2-vinyl pyridine | |
| 26% acrylonitrile | 74% butadiene | |
| 40% 1 acrylonitrile | 60% butadiene | |
| 33% acrylonitrile | 67% styrene | |
| 100% acrylonitrile | | |

Several of the polymers are available commercially, such as:

| Product | Manufacturer | Composition |
|---|---|---|
| Orion | DuPont de Nemours | 90% Acrylonitriles |
| Acrilan | Chemstrand | 90% Acrylonitriles |
| Creslan | American Cyanamid | 95-96% Acrylonitriles |
| Zefran | Dow Chemical Co. | 90% Acrylonitriles |
| Verel | Eastman | About 50% acrylonitrile |
| Dyrel | Carbide &Carbon | 40% acrylonitrile-60% |
| | Chemical | Vinyl chloride |
| Darlan | B.F Goodrich | 50 Mole percent |
| | | vinylidene cyanide - 50 |
| | | Mole percent Vinyl |
| | | acetate |

A particularly useful route to nitrites is termed “cyanoethylation”, in which acrylonitrile undergoes a conjugate addition reaction with protic nucleophiles such as alcohols and amines. Other unsaturated nitrites can also be used in place of acrylonitrile.

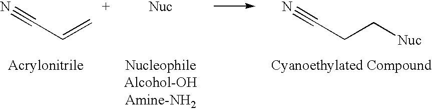

Preferred amines for the cyanoethylation reaction are primary amines and secondary amines having 1 to 30 carbon atoms, and polyethylene amine. Alcohols can be primary, secondary, or tertiary. The cyanoethylation reaction (or “cyanoalkylation” using an unsaturated nitrile other than acrylonitrile) is preferably carried out in the presence of a cyanoethylation catalyst. Preferred cyanoethylation catalysts include lithium hydroxide, sodium hydroxide, potassium hydroxide and metal ion free bases from tetraalkylammonium hydroxide, such as tetramethylammonium hydroxide, TMAH pentahydrate, BTMAH (benzyltetramethylammonium hydroxide), TBAH, choline, and TEMAH (Tris(2-hydroxyethyl)methylammonium hydroxide). The amount of catalyst used is typically between 0.05 mol % and 15 mol %, based on unsaturated nitrile.

Preferably, the cyanolates are derived from the following groups:

arabitol, erythritol, glycerol, isomalt, lactitol, maltitol, mannitol, sorbitol, xylitol, sucrose and hydrogenated starch hydrosylate (HSH)

From the group of hydroxy acids: hydroxyphenylacetic acid (mandelic acid), 2-hydroxypropionic acid (lactic acid), glycolic acid, hydroxysuccinic acid (malic acid), 2,3-dihydroxybutanedioic, acid (tartaric acid), 2-hydroxy-1,2,3-propanetricarboxylic, acid (citric acid), ascorbic acid, 2-hydroxybenzoic, acid (salicylic acid), 3,4,5-trihydroxybenzoic acid (gallic acid).

From the group of sugar acids: galactonic acid, mannonic, acid, fructonic acid, arabinonic acid, xylonic acid, ribonic, acid, 2-deoxyribonic acid, and alginic acid.

From the group of amino acids: alanine, valine, leucine, isoleucine, proline, tryptophan, phenylalanine, methionine, glycine, serine, tyrosine, threonine, cysteine, asparagine, glutamine, aspartic acid, glutamic acid, lysine, arginine, and histidine.

From the group of monomeric polyols- or polyhydric alcohols, or glycol ethers, chosen from ethanol, n- or isopropanol, butanols, glycol, propane- or butanediol, glycerol, diglycol, propyl or butyl diglycol, hexylene glycol, ethylene glycol methyl ether, ethylene glycol ethyl ether, ethylene glycol propyl ether, ethylene glycol mono-n-butyl ether, diethylene glycol methyl ether, diethylene glycol ethyl ether, propylene glycol methyl, ethyl or propyl ether, dipropylene glycol methyl or ethyl ether, methoxy, ethoxy or butoxy triglycol, 1-butoxyethoxy-2-propanol, 3-methyl-3-methoxybutanol, propylene glycol t-butyl ether, and pentaerythritol.

From the group of polymeric polyols, chosen from the group of polyethylene glycols and polypropylene glycols:

Polyethylene glycols (abbreviation PEGS) PEGs are polymers of ethylene glycol which satisfy the general formula

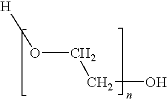

where n can assume values between 1 (ethylene glycol, see below) and about 16. Polyethylene glycols are commercially available, for example under the trade names Carbowax® PEG 200 (Union Carbide), Emkapol® 200 (ICI Americas), Lipoxol® 200 MED (HOLS America), Polyglycol® E-200 (Dow Chemical), Alkapol® PEG 300 (Rhone-Poulenc), Lutrol® E300 (BASF), and the corresponding trade names with higher numbers.

Polypropylene glycols (PPGs) which can be used according to the invention are polymers of propylene glycol which satisfy the general formula

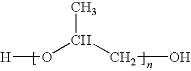

where n can assume values between 1 (propylene glycol) and about 12. Of industrial significance here are, in particular, di-, tri- and tetrapropylene glycol, i.e. the representatives where n=2, 3 and 4 in the above formula.

From the group of organic nitrogen compounds:

Amines: Amines are organic compounds and a type of functional group that contain nitrogen as the key atom. Structurally amines resemble ammonia, wherein one or more hydrogen atoms are replaced by organic substituents such as alkyl, aryl and cyclic groups. Compounds containing one or more —NH— groups of the formula:

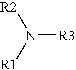

Amides—an amide is an amine where one of the nitrogen substituent is an acyl group; it is generally represented by the formula: R₁(CO)NR₂R₃, where either or both R₂ and R₃ may be hydrogen. Specifically, an amide can also be regarded as a derivative of a carboxylic acid in which the hydroxyl group has been replaced by an amine or ammonia, in which a —CH— or —CH₂— group is situated between —CONH— groups.

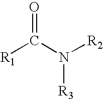

Imides—imide is a functional group consisting of two carbonyl groups bound to a primary amine or ammonia. The structure of the imide moiety is as shown, which possessing a —CH—, —CH₂—, or —CH3 group adjacent to the carbonyl group.

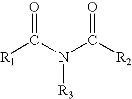

From the group of amino alcohol (or alkanolamine)—Amino alcohols are organic compounds that contain both an amine functional group and an alcohol functional, where the amine can be primary or secondary amines of the formula, wherein X is independently selected from alkylene, heteroalkylene, arylene, heteroarylene, alkylene-heteroaryl, or alkylene-aryl group.

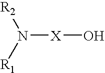

From the group of synthetic polymers: Synthetic polymers such as acetone-formaldehyde condensate, acetone-isobutyraldehyde condensate, methyl ethyl ketone-formaldehyde condensate, poly(allyl alcohol), poly(crotyl alcohol), poly(3-chloroallyl alcohol), ethylene-carbon monoxide copolymers, polyketone from propylene, ethylene and carbon monoxide, poly(methaltyl alcohol, poly(methyl vinyl ketone, and poly(vinyl alcohol).

Synthetic polymers such as acetone-formaldehyde condensate, acetone-isobutyraldehyde condensate, methyl ethyl ketone-formaldehyde condensate, poly(allyl alcohol), poly(crotyl alcohol), poly(3-chloroallyl alcohol), ethylene-carbon monoxide copolymers, polyketone from propylene, ethylene and carbon monoxide, poly(methallyl alcohol, poly(methyl vinyl ketone, and poly(vinyl alcohol) have also been cyanoethylated and can also serve as platforms for further modification into metal-binding polymers.

The nitrite groups of these cyanoethylates or cyanoalkylates can be reacted with hydroxylamine to form the aridoxime. In the process described herein for preparing amidoxime groups, hydroxylamine, hydroxylamine hydrochloride, and hydroxylamine sulfate are suitable sources of hydroxylamine. If hydroxylamine salt is used instead of hydroxylamine freebase, a base such as sodium hydroxide, sodium carbonate or metal ion free base such ammonium hydroxide, tetraalkylammonium hydroxide should be used to release hydroxylamine as freebase for the reaction.

Metal ion freebase, such as ammonium hydroxide or a group of tetraalkylammonium hydroxide, such as tetramethylammonium hydroxide, TMAH pentahydrate, BTMAH (benzyltetramethylammonium hydroxide), TBAH, choline, and TEMAH (Tris(2-hydroxyethyl)methylammonium hydroxide) are preferred.

Metals, such as copper and others, complex strongly with molecules containing amidoxime groups, for example amidoximes of sucrose and sorbitol, to bind metal contaminant residues.

The present invention offers the benefit of binding to the metal oxide surface to create an oxidation barrier, particularly where the amidoxime is derived from functionalized amidoxime polymer, such as from polyvinylalcohol, polyacrylonitriles and its copolymers.

The present invention utilizes the cyanoethylated compounds referenced in “The Chemistry of Acrylonitrile, 2nd ed.” as starting materials for synthesis of amidoximes, such reference is incorporated herein to the extent of the cyanoethylated compounds disclosed therein. The most preferred staring materials for synthesis of amidoximes are those prepared from cyanoethylated sugar alcohols, like sucrose, or reduced sugar alcohols, like sorbitol.

The present invention further offers the benefit of increasing the bulk removal of metal during the CMP process when a chelating agent disclosed herein (e.g., (1,2,3,4,5,6-(hexa-(2-amidoximo)ethoxy)hexane) combined with a compound with oxidation and reduction potentials such as hydroxylamine and its salts, hydrogen peroxide, hydrazines.

Because the chelating agents disclosed herein are not carboxylic acid based but are instead contain multiple ligand sites, the present invention further offers the benefit of more efficient and effective binding to metal ions found in semiconductor manufacturing processes, such as residue after plasma etching particularly with leading edge technology where copper is used as conducting metal.

Another advantage of the chelating agents disclosed herein is that such chelating agent could be used in dilution as a Post-copper CMP clean because these groups of compounds are less acidic than organic acid and less basic than ammonia, choline hydroxide and THEMAH.

### General Procedures on Preparation of Amidoxime

Examples of cyanoethylation to produce nitrile compounds:

Preparation of β-Ethoxypropionitrile, C₂H₅—O—CH₂—CH₂CN.

Place 25 ml of 2 percent aqueous sodium hydroxide and 26 g. (33 ml.) of ethyl alcohol in a 250 ml, reagent bottle, add 26-5 g. (33 ml.) of acrylonitrile and close the mouth of the bottle with a tightly-fitting cork. Shake the resulting clear homogeneous liquid in a shaking machine for 2 hours. During the first 15 minutes the temperature of the mixture rises 15° to 20° and thereafter falls gradually to room temperature; two liquid layers separate after about 10 minutes, Remove the upper layer and add small quantities of 5 percent acetic acid to it until neutral to litmus; discard the lower aqueous layer. Dry with anhydrous magnesium sulfate, distil and collect the β-Ethoxypropionitrile at 172-174°. The yield is 32 g.

β-n-Propoxypropionitrile, C₃H₇^{α}—O—CH₂—CH₂CN.

Introduce 0.15 g of potassium hydroxide and 33 g. (41 ml) of dry n-propyl alcohol into a 150 ml, bolt-head flask, warm gently until the solid dissolves, and then cool to room temperature. Clamp the neck of the flask and equip it with a dropping funnel, a mechanical stirrer and a thermometer (suitably supported in clamps). Introduce from the dropping funnel, with stirring, 26.5 g. (33 ml) of pure acrylonitrile over a period of 2.5-30 minutes (1 drop every ca. 2 seconds). Do not allow the temperature of the mixture to rise above 35-450; immerse the reaction flask in a cold water bath, when necessary. When all the acrylonitrile has been added, heat under reflux in a boiling water bath for 1 hour; the mixture darkens. Cool, filter and distil. Collect the β-n-Propoxypropionitrile at 187-1890. The yield is 38 g.

β-Diethylaminopropionitrile, (C₂H₅)₂N—CH₂—CH₂—CN

Mix 42.5 g (60 ml) of freshly-distilled diethyl amine and 26.5 g. (33 ml) of pure acrylonitrile in a 250 ml round-bottomed flask fitted with a reflux condenser. Heat at 50° in a water bath for 10 hours and then allow to stand at room temperature for 2 days. Distil off the excess of diethylamine on a water bath, and distil the residue from a Claisen flask under reduced pressure. Collect the β-Diethylaminopropionitrile at 75-77°/11 mm. The yield is 54 g.

β-Di-n-butylaminopropionitrile, (C₄H₉^{α})₂NCH₂—H₂—CN.

Proceed as for the diethyl compound using 64.5 g. (85 ml) of redistilled di-n-butylamine and 26.5 g. (33 ml.) of pure acrylonitrile. After heating at 50° and standing for 2 days, distil the entire product under diminished pressure (air bath); discard the low boiling point fraction containing unchanged di-n-butylamine and collect the O-Di-n-butylaminopropionitrile at 120-122° 110 mm. The yield is 55 g.

Ethyl n-propyl-2-cyanoethylmalonate

Add 8.0 g (10.0 ml) of redistilled acrylonitrile to a stirred solution of ethyl n-propyl malonate (30.2 g.) and of 30 percent methanolic potassium hydroxide (4.0 g.) in tert-butyl alcohol (100 g.). Keep the reaction mixture at 30°-35° C. during the addition and stir for a further 3 hours. Neutralize the solution with dilute hydrochloric acid (1:4), dilute with water and extract with ether. Dry the ethereal extract with anhydrous magnesium sulfate and distil off the ether: the residue (ethyl n-propyl-2-cyanoethylmalonate; 11 g) solidifies on cooling in ice, and melts at 314-320 after recrystallization from ice-cold ethyl alcohol.

Preparation of Cyanoethylated Compound

A cyanoethylated diaminocyclohexane is prepared according to U.S. Pat. No. 6,245,932, which is incorporated herein by reference, with cyanoethylated methylcyclohexylamines are readily prepared in the presence of water.

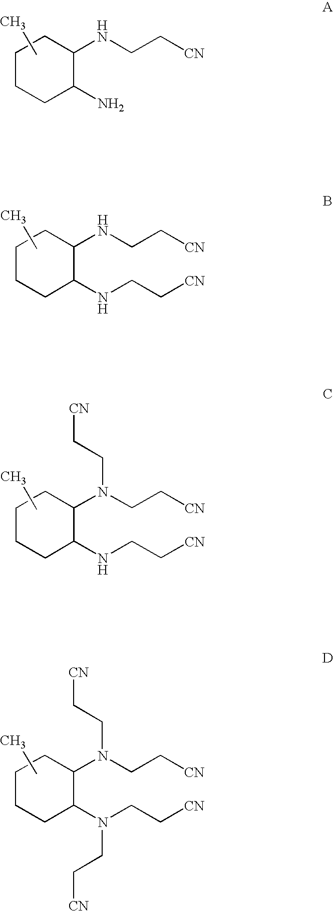

Analyses show that almost no compounds exhibiting secondary amine hydrogen reaction and represented by structures C and D are produced when water alone is used as the catalytic promoter.

Examples of reaction of nitrile compound with hydroxylamine to form amidoxime compound

Preparation and analysis of polyamidoxime (See, U.S. Pat. No. 3,345,344)

80 parts by weight of polyacrylonitrile of molecular weight of about 130,000 in the form of very fine powder (−300 mesh) was suspended in a solution of 300 parts by weight of hydroxylammonium sulfate, 140 parts by weight of sodium hydroxide and 2500 parts by weight of deionized water. The pH of the solution was 7.6. The mixture was heated to 90° C. and held at that temperature for 12 hours, all of the time under vigorous agitation. It was cooled to 35° C. and the product filtered off and washed repeatedly with deionized water. The resin remained insoluble throughout the reaction, but was softened somewhat by the chemical and heat. This caused it to grow from a very fine powder to small clusters of 10 to 20 mesh. The product weighed 130 grams. The yield 40 is always considerably more than theoretical because of firmly occluded salt. The product is essentially a polyamidoxime having the following reoccurring unit.

The mixture of hydroxylamine sulfate and sodium hydroxide can be replaced with equal molar of hydroxylamine freebase solution.

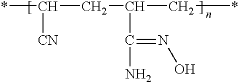

Portions of this product were then analyzed for total nitrogen and for oxime nitrogen by the well-known Dumas and Raschig methods and the following was found:

| | Percent |
|---|---|
| Total nitrogen (Dumas method) | 22.1 |
| Oxime nitrogen (Raschig method) | 6.95 |
| Amidoxime nitrogen (twice the amount of | 13.9 |
| oxime nitrogen) (calculated) | |
| Nitrile nitrogen (difference between the total | 8.2 |
| nitrogen and amidoxime nitrogen) (calculated) | |

Conversion of reacted product from cyanoethylation of cycloaliphatic vicinal primary amines (See, U.S. Pat. No. 6,245,932).

For example, Cyanoethylated methylcyclohexylamines

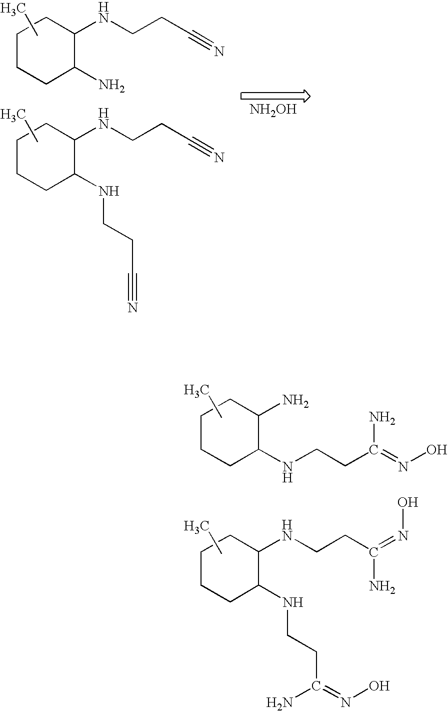

Due to large number of the amidoxime compounds are not commercially available. The amidoxime chelating compound can also prepare in-situ while blending the cleaning formulation.

The following are photoresist stripper formulations that can be used with the amidoximes compounds of the present invention.

| | | Start | | After Step 1 | | After Step 2 | | End | | Stripper |
|---|---|---|---|---|---|---|---|---|---|---|
| Ingredient | MW | mole | Wt | mole | Wt | mole | Wt | mole | Wt | Composition |

Step 1

| | | | | | | | | | | | |
|---|---|---|---|---|---|---|---|---|---|---|---|
| Amine | 2-Pyrolidone | 85.11 | 1.00 | 85.11 | 0.00 | 0.00 | 0.00 | 0.00 | 0.00 | 0.00 | 0% |
| Nitrile | Acrylonitrile | 53.00 | 1.00 | 53.00 | 0.00 | 0.00 | 0.00 | 0.00 | 0.00 | 0.00 | 0% |
| Metal Ion | TMAH | 91.00 | 0.05 | 4.55 | 0.05 | 4.55 | 0.05 | 4.55 | 0.05 | 4.55 | 2% |
| free base | | | | | | | | | | | |
| | Water | 18.00 | 0.76 | 13.65 | 0.76 | 13.65 | 0.76 | 13.70 | 0.76 | 13.68 | 6% |
| Cyanoethylated | | 137.10 | 0.00 | 0.00 | 1.00 | 137.10 | 0.00 | 0.00 | 0.00 | 0.00 | 0% |
| Compound | | | | | | | | | | | |

Step 2

| | | | | | | | | | | | |
|---|---|---|---|---|---|---|---|---|---|---|---|
| Oxidizing/ | Hydroxylamine | 31.00 | 1.00 | 31.00 | 0.00 | 0.00 | 0.00 | 0.00 | 0.00 | 0.00 | 0% |
| Reducing | | | | | | | | | | | |
| compound | | | | | | | | | | | |
| Water | Water | 18.00 | 1.72 | 31.00 | 0.00 | 0.00 | 1.72 | 31.00 | 1.72 | 31.00 | 14% |
| Amidoxime | Amidoxime | 170.00 | 0.00 | 0.00 | 0.00 | 0.00 | 1.00 | 170.00 | 1.00 | 170.00 | 78% |

| | | |
|---|---|---|
| 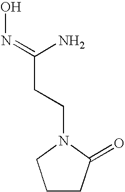 | 219.20 | 100% |

| | Ingredient | Stripper Composition |
|---|---|---|
| Metal Ion free base | TMAH | 2% |
| Water | Water | 20% |
| Amidoxime | 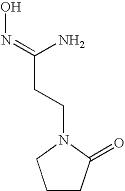 | 78% 100% |

Example of Amidoxime derived from Ammonia

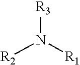

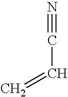

H₂N—OH

| R1 | R2 | R3 | Nitrile | Amidoxime |
|---|---|---|---|---|
| —H | —H | —H | 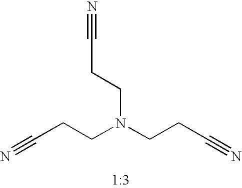 | 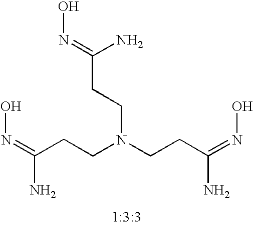 |
| CH3CH2 | H | H | 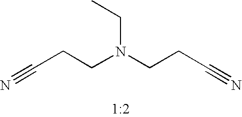 | 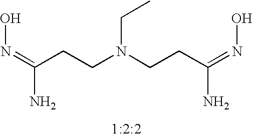 |
| CH3CH2 | CH3CH2 | H | 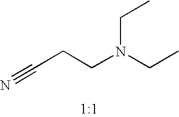 | 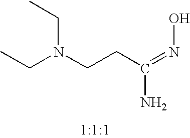 |

Amidoxime derived from Citric acid

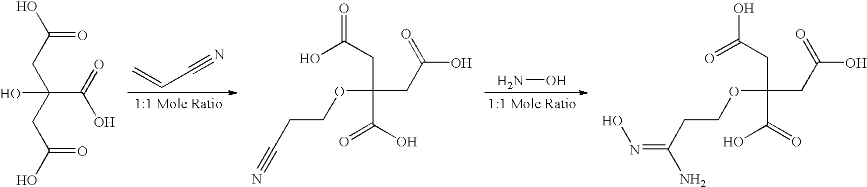

| Reactants | 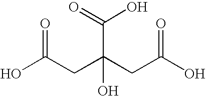 |
|---|---|
| CA:AN:HA 1:1:1 | 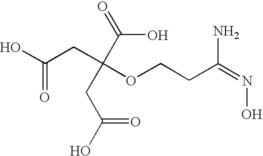 |
| CA:AN:HA 1:1:1 | 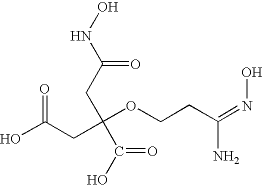 |
| CA:AN:HA 1:1:1 | 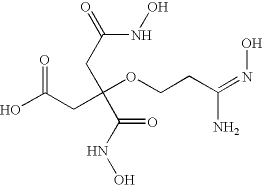 |
| CA:AN:HA 1:1:1 | 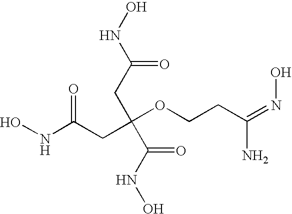 |

Amidoxime derived from Lactic acid

| 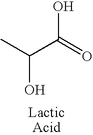 | 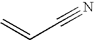 | Amidoxime Compounds | |
|---|---|---|---|
| | 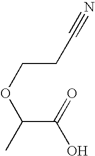 | 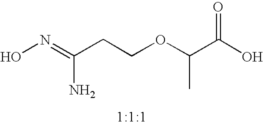 | 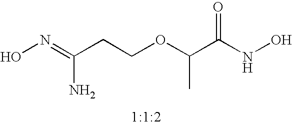 |

Amidoxime derived from Propylene Glycol

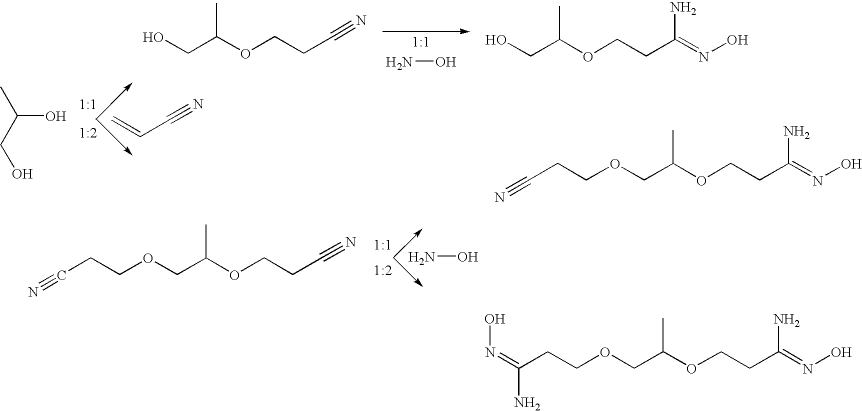

| | Amidoxime Compounds | | |
|---|---|---|---|
| Reactant | PG:AN:HA 1:1:1 | PG:AN:HA 1:2:1 | PG:AN:HA 1:2:2 |
| 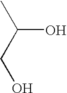 | 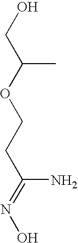 | 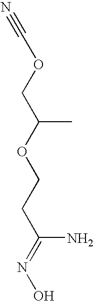 | 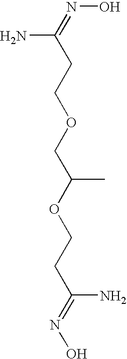 |

Amidoxime derived from Pentaerythritol—DS1

| | | | |
|---|---|---|---|
| 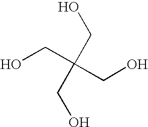 | 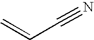 | H₂N—OH | Amidoxime Compounds |

| | | |
|---|---|---|
| 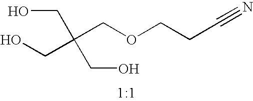 | 1 | 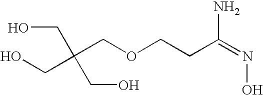 |

Amidoxime derived from Pentaerythritol—DS2

| | | | |
|---|---|---|---|
| 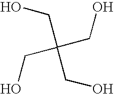 | 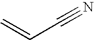 | H₂N—OH | Amidoxime Compounds |

| | | |
|---|---|---|
| 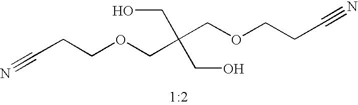 | 1 | 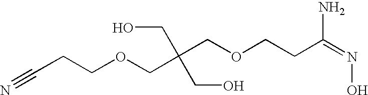 |
| | 2 | 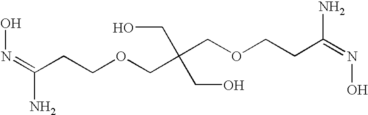 |

Amidoxime derived from Pentaerythritol—DS3

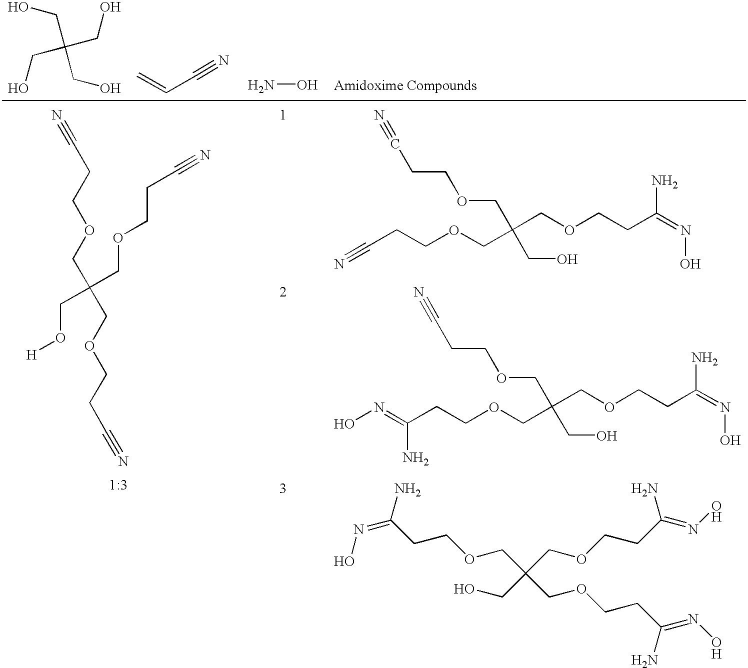

Amidoxime derived from Pentaerythritol—DS4

| | | | |
|---|---|---|---|
| 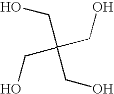 | 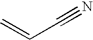 | H₂N—OH | Amidoxime Compounds |

| | | |
|---|---|---|
| 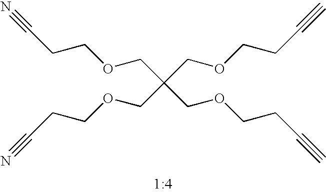 | 1 | 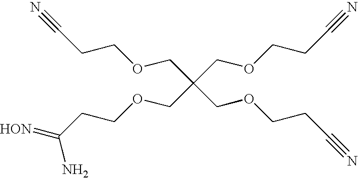 |
| | 2 | 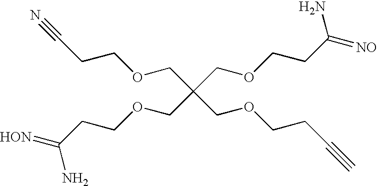 |
| | 3 | 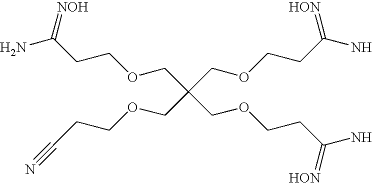 |
| | 4 | 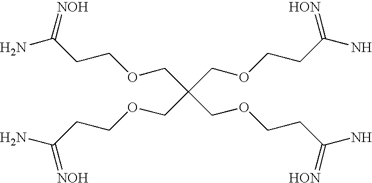 |

α-Substituted Acetic Acid

| R | 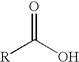 |
|---|---|
| —CH₃ | Acetic Acid |
| —CH₂OH | Glycolic Acid |
| —CH₂NH₂ | Glycine |
| —CHO | Glyoxylic Acid |

| 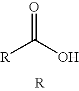 | 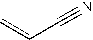 | H₂N—OH 1 2 3 | | |
|---|---|---|---|---|
| —CH₃ | | 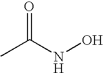 | | |
| —CH₂OH | 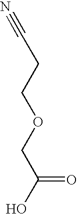 | 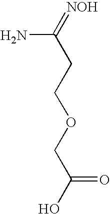 | 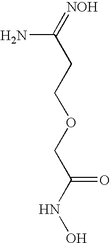 | |
| —CH₂NH₂ | 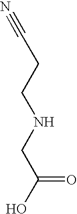 | 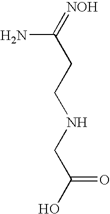 | 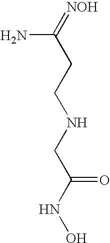 | |
| —CH₂NH₂ | 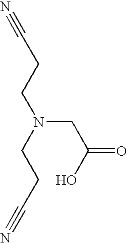 | 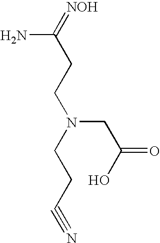 | 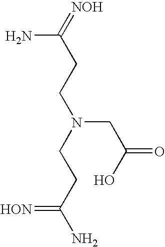 | 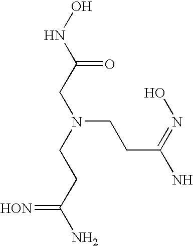 |
| —CHO | 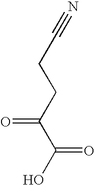 | 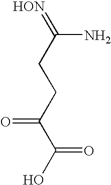 | 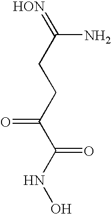 | |

Amidoxime derived from Iminodiacetic acid

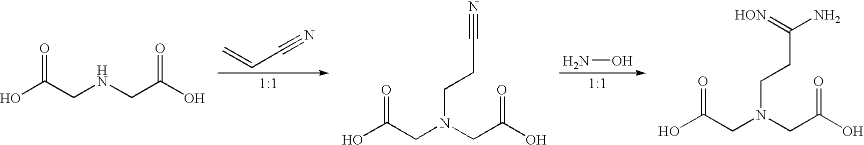

| Reactants | 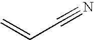 | H₂N—OH | 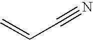 | H₂N—OH | 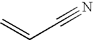 | H₂N—OH |
|---|---|---|---|---|---|---|
| 1 | 1 | 1 | 1 | 2 | 1 | 3 |

| | | | |
|---|---|---|---|
| 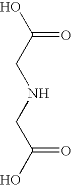 | 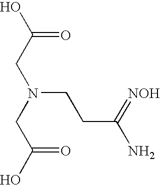 | 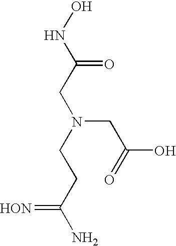 | 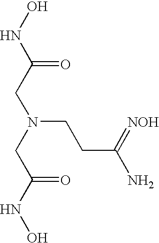 |

Amidoxime derived from 2,5-piperazinedione

| Reactants | 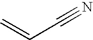 | H₂N—OH | 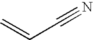 | H₂N—OH | 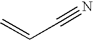 | H₂N—OH |
|---|---|---|---|---|---|---|
| 1 | 1 | 1 | 2 | 1 | 2 | 2 |

| | | | |
|---|---|---|---|
| 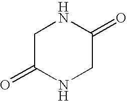 | 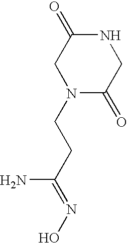 | 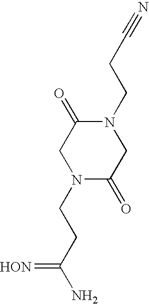 | 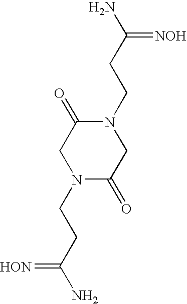 |

Amidoxime derived from cyanopyridine

| Reactants | H₂N—OH | 1594-57-6 |
|---|---|---|
| 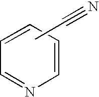 | 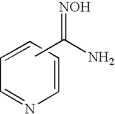 | 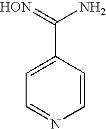 |
| 2, 3 or 4 Cyanopyridine | 2, 3 or 4 Amidoxime | 4-Amidoxime-pyridine |
| | pyridine | |

Cyanoethylation of Sorbitol to produce multi substituted-(2-amidoximo)ethoxy)hexane.

1. A one-liter three-necked round-bottomed flask was equipped with a mechanical stirrer, reflux condenser, thermometer, and 100 ml addition funnel under nitrogen. Lithium hydroxide monohydrate (1.0 g, 23.8 mmol, 0.036 eq) dissolved in water (18.5 ml) was added to the flask, followed by the addition of sorbitol (120 g, 659 mmol) in one portion, and then water (100 ml). The solution was warmed to 42° C. in a water bath and treated with acrylonitrile (43.6 ml, 659 mmol, and 1.0 eq) drop-wise via the addition funnel for a period of 2 hr, while maintaining the temperature at 42° C. After the addition was complete, the solution was warmed to 50-55° C. for 4 hr and then allowed to cool to room temperature. The reaction was neutralized by addition of acetic acid (2.5 ml) and allowed to stand overnight at room temperature. The solution was evaporated under reduced pressure to give the product as a clear, viscous oil (155.4 g).

Tetramethylammonium hydroxide can be used to substitute lithium hydroxide.

Elemental analysis: Found, 40.95% C, 3.85% N. The IR spectrum showed a nitrile peak at 2255 cm⁻¹ indicative of the nitrile group.

A one liter three-neck round-bottomed flask was equipped with a mechanical stirrer, reflux condenser, thermometer, and 100 ml addition funnel under nitrogen. Lithium hydroxide (1.0 g, 23.8 mmol, 0.036 eq) dissolved in water (18.5 ml) was added to the flask, followed by the addition of the first portion of sorbitol (60.0 g, 329 mmol) and then water (50 ml). The solution was warmed to 42° C. in a water bath and treated with acrylonitrile (42 ml, 633 mmol, 0.96 eq) drop-wise via the addition funnel for a period of 1 hr while maintaining the temperature at 42° C. The second portion of sorbitol (60 g, 329 mmol) and water (50 ml) were added to the flask. The second portion of the acrylonitrile (89.1 ml, 1.344 mol, 2.04 eq) was added in a drop-wise fashion over a period of 1 hr. After the addition was complete, the solution was warmed to 50-55° C. for 4 hr and then allowed to cool to room temperature. The reaction was neutralized by addition of acetic acid (2.5 ml) and allowed to stand overnight at room temperature. The solution was evaporated under reduced pressure to give the product as a clear, viscous oil (228.23 g).

Tetramethylammonium hydroxide can be used to substitute lithium hydroxide.

Elemental analysis: Found: 49.16% C, 10.76% N. The IR spectrum showed a nitrile peak at 2252 cm⁻¹ indicative of the nitrile group.

3. A 1000 ml 3-necked round-bottomed flask equipped with an mechanical stirrer, reflux condenser, nitrogen purge, dropping funnel, and thermometer was charged with water (18.5 ml) and lithium hydroxide monohydrate (1.75 g) and the first portion of sorbitol (44.8 g). The solution was heated to 42° C. with a water bath with stirring and the second portion of sorbitol (39.2 g) was added directly to the reaction flask. The first portion of acrylonitrile (100 ml) was then added to the reaction drop-wise via a 500 ml addition funnel over a period of 2 hr. The reaction was slightly exothermic, raising the temperature to 51° C. The final portion of sorbitol (32 g) was added for a total of 0.638 moles followed by a final portion of acrylonitrile (190 ml) over 2.5 hr keeping the reaction temperature below 60° C. (A total of 4.41 moles of acrylonitrile was used.) The reaction solution was then heated to 50-55° C. for 4 hr. The solution was then allowed to cool to room temperature and the reaction was neutralized by addition of acetic acid (2.5 ml), Removal of the solvent under reduced pressure gave the product as a clear, viscous oil (324 g).

Tetramethylammonium hydroxide can be used to substitute lithium hydroxide.

The IR spectrum showed a nitrile peak at 2251 cm⁻¹, indicative of the nitrile group.

4. Preparation of (1,2,3,4,5,6-(hexa-(2-amidoximo)ethoxy)hexane.

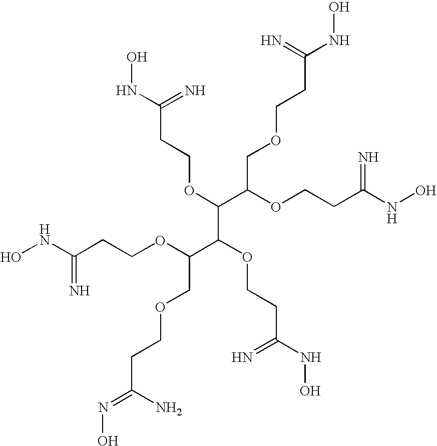

A 1000 mL three-necked round-bottomed flask was equipped with a mechanical stirrer, condenser, and addition funnel under nitrogen. CE-Sorb6 (14.77 g, 29.5 mmol) and water (200 mL) were added to the flask and stirred. In a separate 500 mL Erlenmeyer flask, hydroxylamine hydrochloride (11.47 g, 165 mmol, 5.6 eq) was dissolved in water (178 mL) and then treated with ammonium hydroxide (22.1 mL of 28% solution, 177 mmol, 6.0 eq) for a total volume of 200 mL. The hydroxylamine solution was then added in one portion directly to the mixture in the round-bottomed flask at room temperature. The stiffed mixture was heated at 80° C. for 2 hr, pH=8-9, and then allowed to cool to room temperature.

Hydroxylamine freebase (50%) aqueous solution can be used to replace the solution by blending hydroxylamine chloride and ammonium hydroxide.

The JR spectrum indicated loss of most of the nitrile peak at 2250 cm⁻¹ and the appearance of a new peak at 1660 cm⁻¹, indicative of the amidoxime or hydroxamic acid.

Preparation and analysis of polyamidoxime is essentially that described in U.S. Pat. No. 3,345,344, which is incorporated herein by reference in its entirety. In that process 80 parts by weight of polyacrylonitrile of molecular weight of about 130,000 in the form of very fine powder (−300 mesh) was suspended in a solution of 300 parts by weight of hydroxylammonium sulfate, 140 parts by weight of sodium hydroxide and 2500 parts by weight of deionized water. The pH of the solution was 7.6. The mixture was heated to 90° C. and held at that temperature for 12 hours, all of the time under vigorous agitation. It was cooled to 35° C. and the product filtered off and washed repeatedly with deionized water. The resin remained insoluble throughout the reaction, but was softened somewhat by the chemical and heat. This caused it to grow from a very fine powder to small clusters of 10 to 20 mesh. The product weighed 130 grams. The yield is always considerably more than theoretical because of fumly occluded salt. The product is essentially a poly-amidoxime having the following reoccurring unit

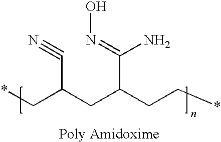

The following depicts metal complexing using amidoxime compounds.

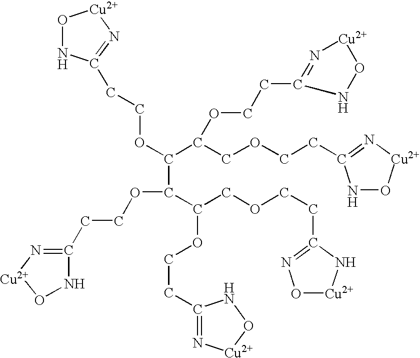

Amidoxime chelating agents can substitute for organic carboxylic acids, organic carboxylic ammonium salt or an amine carboxylates being used in cleaning formulations and processes.

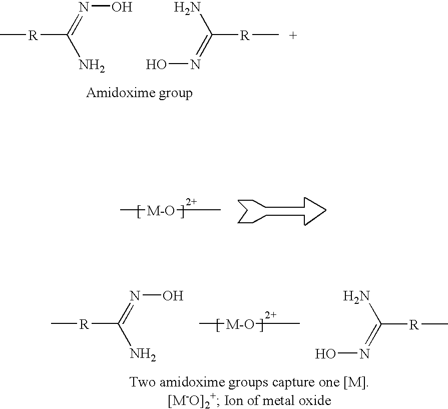

Nomenclatures are translated from chemical structures to their corresponding chemical names using ChemBioDraw Ultra from CambridgeSoft, Mass. In the case for products from the reaction of sorbitol, the cyanoethylated sorbitol is given by its CAS# [2465-92-1] as 1,2,3,4,5,6-hexakis-O-(2-kyanoetyl)hexitol with chemical formula of C₂₄H₁₃₂N₆O₆ and the corresponding amidoxime compound as 1,2,3,4,5,6-hexakis-O-[3-(hydroxyamino)-3-iminopropyl Hexitol, CAS# [950752-25-7].

Reactions to produce nitrite precursors to amidoxime compounds

Cyanoethylation of Diethylaminexine

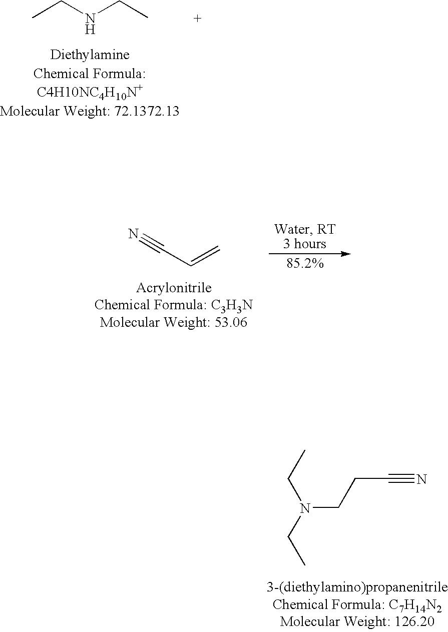

A solution of diethylamine (1 g, 13.67 mmol) and acrylonitrile (0.798 g, 15 mmol, 1.1 eq) in water (10 cm³) were stirred at room temperature for 3 hours, after which the mixture was extracted with dichloromethane (2×50 cm³). The organic extracts were evaporated under reduced pressure to give the pure cyanoethylated compound 3-(diethylamino)propanenitrile (1.47 g, 85.2%) as an oil.

Monocyanoethylation of Glycine

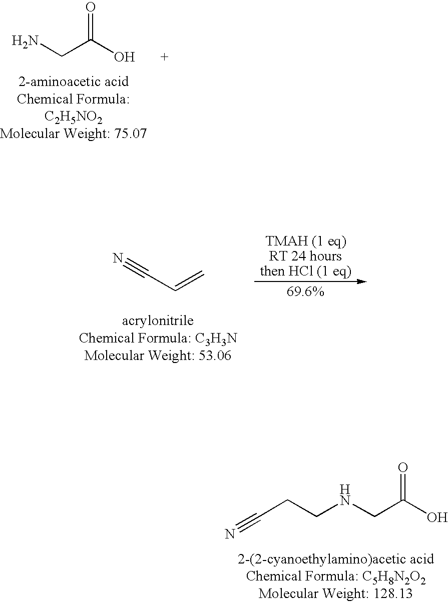

Glycine (5 g, 67 mmol) was suspendeed in water (10 cm³) and TMAH (25% in water, 24.3 g, 67 mmol) was added slowly, keeping the temperature at <30° C. with an ice-bath. The mixture was then cooled to 10° C. and acrylonitrile (3.89 g, 73 mmol) was added. The mixture was stirred overnight, and allowed to warm to room temperature slowly. The mixture was then neutralized with HCl (6M, 11.1 cm³), concentrated to 15 cm³ and diluted to 100 cm³ with EtOH. The solid precipitated was collected by filtration, dissolved in hot water (6 cm³) and reprecipitated with EtOH (13 cm³) to give 2-(2-cyanoethylamino)acetic acid (5.94 g, 69.6%) as a white solid, mp 192° C. (lit mp 190-191° C.).

Cyanoethylation of Piperazinexine

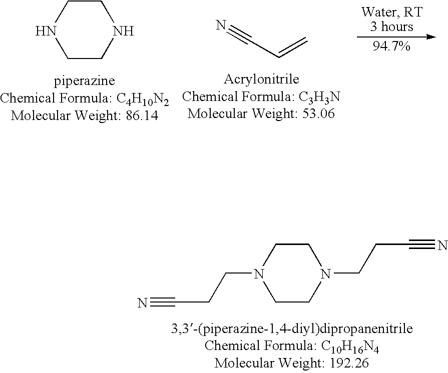

A solution of piperazine (1 g, 11.6 mmol) and acrylonitrile (1.6 g, 30.16 mmol, 2.6 eq) in water (10 cm³) were stirred at room temperature for 5 hours, after which the mixture was extracted with dichloromethane (2×50 cm³). The organic extracts were evaporated under reduced pressure to give the pure doubly cyanoethylated compound 3,3′-(piperazine-1,4-diyl)dipropanenitrile (2.14 g, 94.7%) as a white solid, mp 66-67° C.

Cyanoethylation of 2-ethoxyethanol

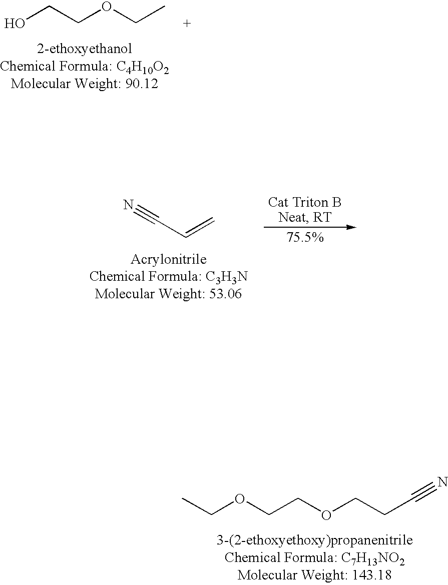

To an ice-water cooled mixture of 2-ethoxyethanol (1 g, 11.1 mmol) and Triton B (40% in MeOH, 0.138 g, 0.33 mmol) was added acrylonitrile (0.618 g, 11.6 mmol) and the mixture was stirred at room temperature for 24 hours. It was then neutralized with 0.1 M HCl (3.3 cm³) and extracted with CH₂Cl₂ (2×10 cm³). The extracts were concentrated under reduced pressure and the residue was Kugelrohr-distilled to give the product 3-(2-ethoxyethoxy)propanenitrile (1.20 g, 75.5%) as a colourless oil, bp 100-130° C./20 Torr.

Cyanoethylation of 2-(2-dimethylaminoethoxy)ethanol

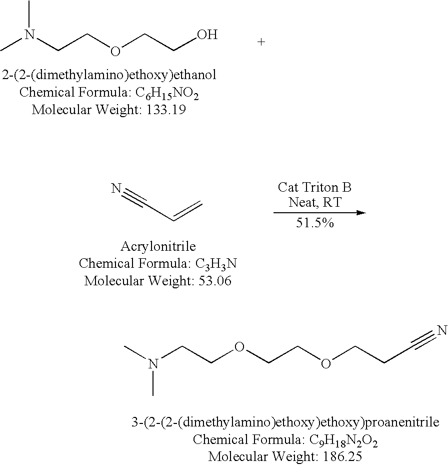

To an ice-water cooled mixture of 2-(2-dimethyleminothoxy)ethanol (1 g, 7.5 mmol) and Triton B (40% in MeOH, 0.094 g, 0.225 mmol) was added acrylonitrile (0.418 g, 7.9 mmol) and the mixture was stirred at room temperature for 24 hours. It was then neutralized with 0.1 M HCl (2.3 cm³) and extracted with CH₂Cl₂ (2×10 cm³) The extracts were concentrated under reduced pressure and the residue was purified by column chromatography (silica, Et₂O, 10% CH₂Cl₂, 0-10% EtOH) to give 3-(2-(2-(dimethylamino)ethoxy)ethoxy)propanenitrile as an oil.

Cyanoethylation of Isobutyraldehyde

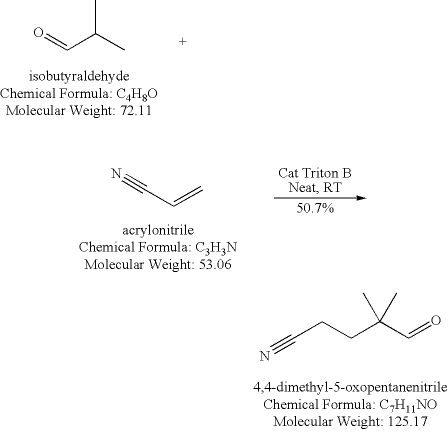

Isobutyraldehyde (1 g, 13.9 mmol) and acrylonitrile (0.81 g, 15 mmol) were mixed thoroughly and cooled with an ice-bath. Triton B (40% in MeOH, 0.58 g, 1.4 mmol) was added. The mixture was stirred at room temperature overnight. It was then neutralized with 0.1 M HCl (14 cm³) and extracted with CH₂Cl₂ (100 cm³). The extracts were concentrated under reduced pressure and the residue was Kugelrohr-distilled to give the product 4,4-dimethyl-5-oxopentanenitrile (0.8 g, 50.7%) as an oil, bp 125-130° C./20 Torr.

Cyanoethylation of Aniline

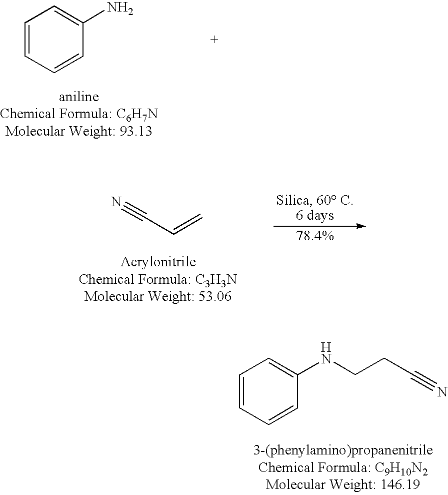

Silica was activated by heating it above 100° C. in vacuum and was then allowed to cool to room temperature under nitrogen. To the activated silica (10 g) was absorbed aniline (1.86 g, 20 mmol) and acrylonitrile (2.65 g, 50 mmol) and the flask was capped tightly. The contents were then stirred with a magnetic stirrer for 6 days at 60° C. After this time the mixture was cooled to room temperature and extracted with MeOH. The extracts were evaporated to dryness and the residue was Kugelrohr-distilled under high vacuum to give the product 3-(phenylamino)propanenitrile (2.29 g, 78.4%) as an oil which crystallised on standing; bp 120-150° C./1-2 Torr (lit bp 120° C./1 Torr), mp 50.5-52.5° C.

Cyanoethylation of Ethylenediamine

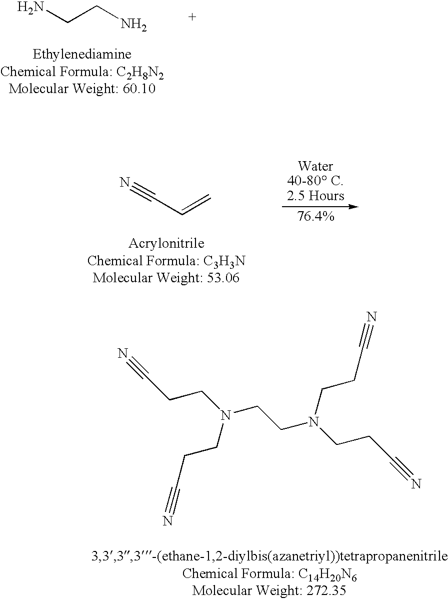

Acrylonitrile (110 g, 137 cm³, 2.08 mol) was added to a vigorously stirred mixture of ethylenediamine (25 g, 27.8 cm³, 0.416 mol) and water (294 cm³) at 40° C. over 30 min. During the addition, it was necessary to cool the mixture with a 25° C. water bath to maintain temperature at 40° C. The mixture was then stirred for additional 2 hours at 40° C. and 2 hours at 80° C. Excess acrylonitrile and half of the water were evaporated off and the residue, on cooling to room temperature, gave a white solid which was recrystallised from MeOH-water (9:1) to give pure product 3,3′,3″,3′″-(ethane-1,2-diylbis(azanetriyl))tetrapropanenitrile (86.6 g, 76.4%) as white crystals, mp 63-65° C.

Cyanoethylation of Ethylene Glycol

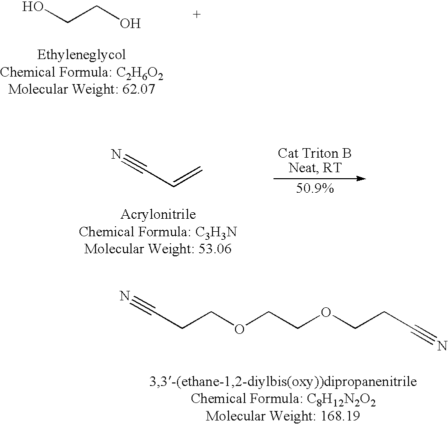

Small scale: Ethylene glycol (1 g, 16.1 mmol) was mixed with Triton B (40% in MeOH, 0.22 g, 0.53 mmol) and cooled in an ice-bath while acrylonitrile (1.71 g, 32.2 mmol) was added. The mixture was stirred at room temperature for 60 hours after which it was neutralized with 0.1 M HCl (0.6 cm³) and extracted with CH₂Cl₂ (80 cm³) The extracts were concentrated under reduced pressure and the residue was Kugelrohr-distilled to give 3,3′-(ethane-1,2-diylbis(oxy))dipropanenitrile (1.08 g, 39.9%) as a light coloured oil, hp 150-170° C./20 Torr.

Large scale: Ethylene glycol (32.9 g, 0.53 mol) was mixed with Triton B (40% in MeOH, 2.22 g, 5.3 mmol) and cooled in an ice-bath while acrylonitrile (76.2 g, 1.44 mol) was added. The mixture was allowed to warm slowly to room temperature and stirred for 60 hours after which it was neutralized with 0.1 M HCl (50 cm³) and extracted with CH₂Cl₂ (300 cm³) The extracts were passed through a silica plug three times to reduce the brown coloring to give 86 g (quantitative yield) of the product as an amber coloured oil, pure by ¹H-NMR, containing 10 g of water (total weight 96 g, amount of water calculated by ¹H NMR integral sizes).

Cyanoethylation of Diethyl Malonate

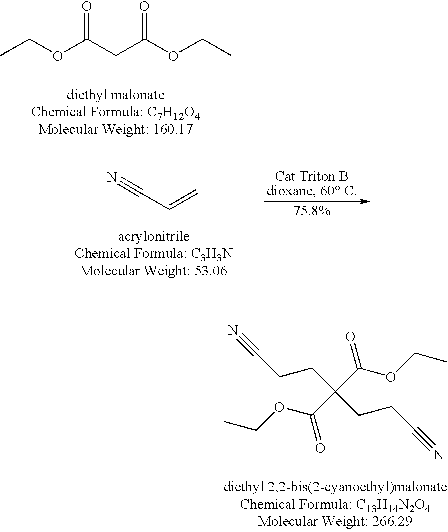

To a solution of diethyl malonate (1 g, 6.2 mmol) and Triton 13 (40% in MeOH, 0.13 g, 0.31 mmol) in dioxane (1.2 cm³) was added dropwise acrylonitrile (0.658 g, 12.4 mmol) and the mixture was stirred at 60° C. overnight. The mixture was then cooled to room temperature and neutralized with 0.1 M HCl (3 cm³) and poured to ice-water (10 cm³). Crystals precipitated during 30 min. These were collected by filtration and recrystallised from EtOH (cooling in freezer before filtering off) to give diethyl 2,2-bis(2-cyanoethyl)malonate (1.25 g, 75.8%) as a white solid, mp 62.2-63.5° C.

Hydrolysis of Diethyl 2,2-bis(2-cyanoethyl)malonate

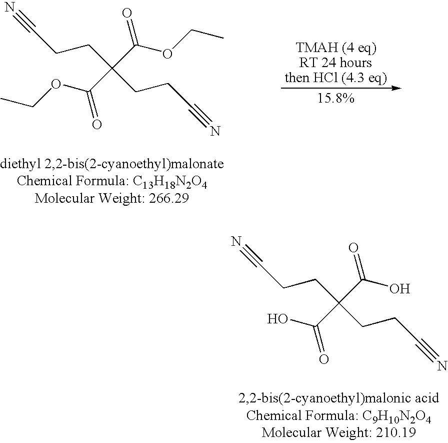

Diethyl 2,2-bis(2-cyanoethyl)malonate (2 g, 7.51 mmol) was added to TMAH (25% in water, 10.95 g, 30.04 mmol) at room temperature. The mixture was stirred for 24 hours, and was then cooled to 0° C. A mixture of 12M HCl (2,69 cm³, 32.1 mmol) and ice (3 g) was added and the mixture was extracted with CH₂Cl₂ (5×50 cm³). The extracts were evaporated under vacuum to give 2,2-bis(2-cyanoethyl)malonic acid (0.25 g, 15.8%) as a colourless very viscous oil (lit decomposed. 158° C.).

Dicyanoethylation of Glycine to Give 2-(bis(2-cyanoethyl)amino)acetic Acid

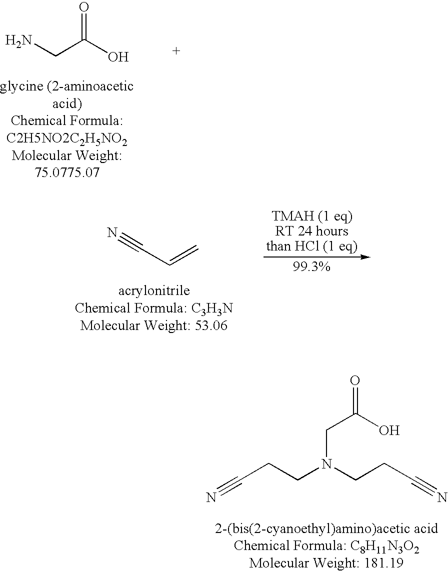

Glycine (5 g, 67 mmol) was suspended in water (10 cm³) and TMAH (25% in water, 24.3 g, 67 mmol) was added slowly, keeping the temperature at <30° C. with an ice-bath. The mixture was then cooled to 10° C. and acrylonitrile (7.78 g, 146 mmol) was added. The mixture was stirred overnight, and allowed to warm to room temperature slowly. It was then heated at 50° C. for 2 hours, using a reflux condenser, After cooling with ice, the mixture was neutralized with HCl (6M, 11.1 cm³) and concentrated to a viscous oil. This was dissolved in acetone (100 cm³) and filtered to remove NMe₄Cl. The filtrate was concentrated under reduced pressure to give an oil that was treated once more with acetone (100 cm³) and filtered to remove more NMe₄Cl. Concentration of the filtrate gave 2-(bis(2-cyanoethyl)amino)acetic acid (11.99 g, 99.3%) as a colourless, viscous oil that crystallised over 1 week at room temperature to give a solid product, mp 73° C. (lit mp 77.8-78.8° C. Duplicate ¹³C signals indicate a partly zwitterionic form in CDCl₃ solution. When NaOH is used in the literature procedure, the NaCl formed is easier to remove and only one acetone treatment is necessary.

Dicyanoethylation of N-methyldiethanolamine to Give 3,3′-(2,2′-(methylazanediyl)bis(ethane-2,1-diyl)bis(oxy))dipropanenitrile

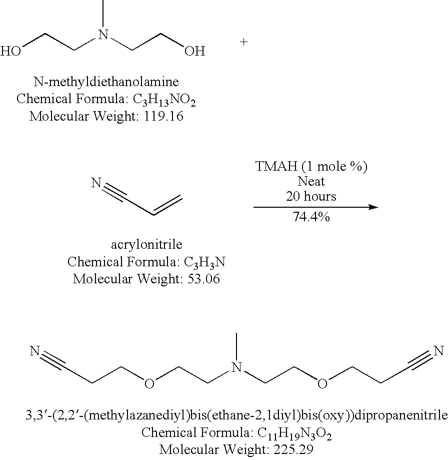

To a cooled, stirred mixture of N-methyldiethanolamine (2 g, 17 mmol) and acrylonitrile (2.33 g, 42 mmol) was added TMAH (25% in water, 0.25 cm⁻¹, 0.254 go 7 mmol). The mixture was then stirred overnight, and allowed to warm to room temperature slowly. It was then filtered through silica using a mixture of Et₂O and CH₂Cl₂ (1:1, 250 cm³) and the filtrated was evaporated under reduced pressure to give 3,3′-(2,2′-(methylazanediyl)bis(ethane-2,1-diyl)bis(oxy))dipropanenitrile (2.85 g, 74.4%) as a colourless oil.

Dicyanoethylation of Glycine Anhydride

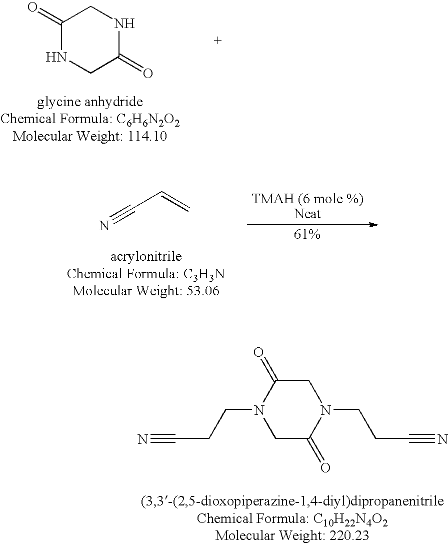

Glycine anhydride (2 g, 17.5 mmol) was mixed with acrylonitrile (2.015 g, 38 mmol) at 0° C. and TMAH (25% in water, 0.1 cm³, 0.1 g, 2.7 mmol) was added. The mixture was then stirred overnight, allowing it to warm to room temperature slowly. The solid formed was recrystallised from EtOH to give 3,3′-(2,5-dioxopiperazine-1,4-diyl)dipropanenitrile (2.35 g, 61%) as a white solid, mp 171-173° C. (lit mp 166° C.). N,N-Dicyanoethylation of acetamide

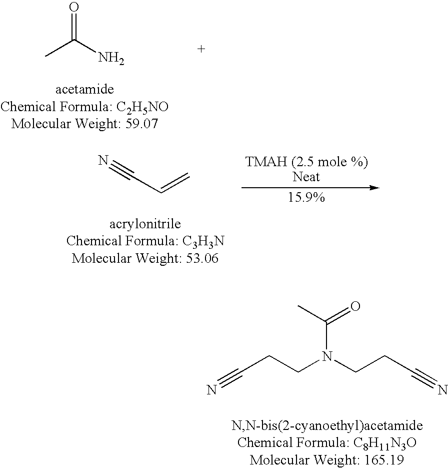

Acetamide (2 g, 33.9 mmol) was mixed with acrylonitrile (2.26 g, 42.7 mmol) at 0° C. and TMAH (25% in water, 0.06 cm³, 0.06 g, 1.7 mmol) was added. The mixture was then stirred overnight, allowing it to warm to room temperature slowly. The mixture was filtered through a pad of silica with the aid of Et₂OCH₂Cl₂ (200 cm³) and the filtrate was concentrated under reduced pressure. The product was heated with spinning in a Kugelrohr at 150° C./2 mmHg to remove side products and to give N,N-bis(2-cyanoethyl)acetamide (0.89 g, 15.9%) as a viscous oil.

The N-substituent in the amides is non-equivalent due to amide rotation. Tricyanoethylation of ammonia

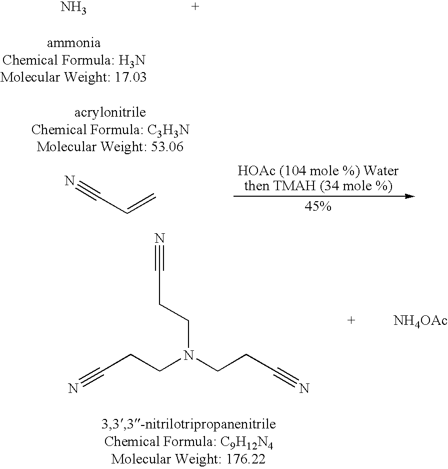

Ammonia (aq 35%, 4.29, 88 mmol) was added dropwise to ice-cooled AcOH (5.5 g, 91.6 mmol) in water (9.75 cm³), followed by acrylonitrile (4.65 g, 87.6 mol). The mixture was stirred under reflux for 3 days, after which it was cooled with ice and aq TMAH (25% in water, 10.94 g, 30 mmol) was added. The mixture was kept cooled with ice for 1 hours. The crystals formed was collected by filtration and washed with water. The product was dried in high vacuum to give 3,3′,3″-nitrilotripropanenitrile (2.36 g, 45.8%) as a white solid, mp 59-61° C. (lit mp 59° C.).

When NaOH was used to neutralize the reaction (literature procedure), the yield was higher, 54.4%.

Dicyanoethylation of Cyanoacetamide

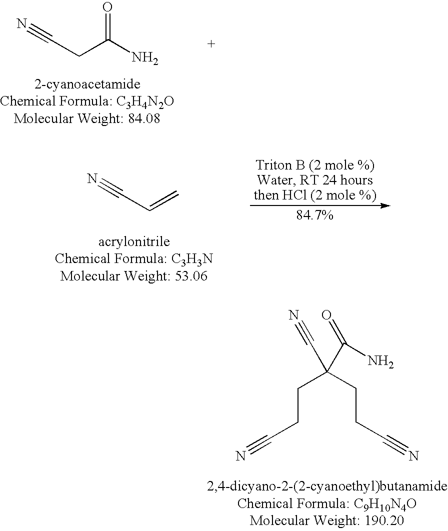

To a stirred mixture of cyanoacetamide (2.52 g, 29.7 mmol) and Tri ton B (40% in MeOH, 0.3 g, 0.7 mmol) in water (5 cm³) was added acrylonitrile (3.18 g, 59.9 mmol) over 30 minutes with cooling. The mixture was then stirred at room temperature for 30 min and then allowed to stand for 1 hours. EtOH (20 g) and 1M HCl (0.7 cm³) were added and the mixture was heated until all solid had dissolved. Cooling to room temperature gave crystals that were collected by filtration and recrystallised from EtOH to give 2,4-dicyano-2-(2-cyanoethyl)butanamide (4.8 g, 84.7%) as a pale yellow solid, mp 118-120° C. (lit mp 118° C.), N,N-Dicyanoethylation of anthranilonitrile

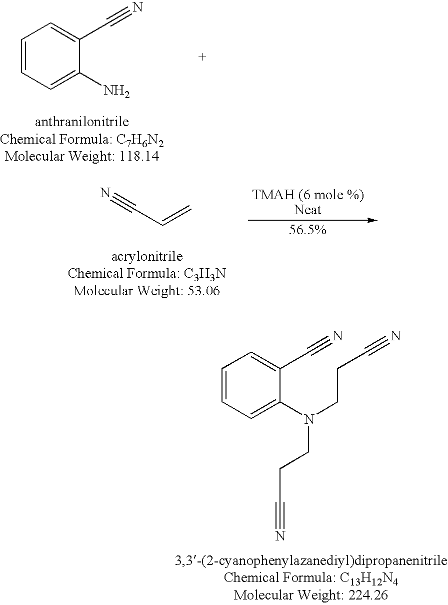

Anthranilonitrile (2 g, 16.9 mmol) was mixed with acrylonitrile (2.015 g, 38 mmol) at 0° C. and TMAH (25% in water, 0.1 cm³, 0.1 g, 2.7 mmol) was added. The mixture was then stirred overnight, allowing it to warm to room temperature slowly. The product was dissolved in CH₂CO₂ and filtered through silica using a mixture of Et₂O and CH₁₂CO₂ (1:1, 250 cm³). The filtrate was evaporated to dryness and the solid product was recrystallised from EtOH (5 cm³) to give 3,3′-(2-cyanophenylazanediyl)dipropanenitrile (2.14 g, 56.5%) as an off-white solid, mp 79-82° C.

Dicyanoethylation of Malononitrile

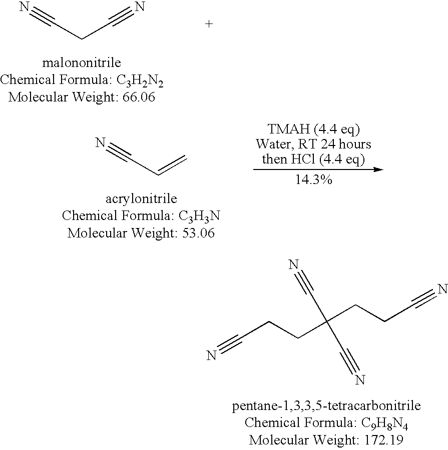

Malononitrile (5 g, 75.7 mmol) was dissolved in dioxane (10 cm³), followed by trimethylbenzylammonium hydroxide (Triton B, 40% in MeOH, 1.38 g, 3.3 mmol). The mixture was cooled while acrylonitrile (8.3 g, 156 mmol) was added. The mixture was stirred overnight, allowing it to warm to room temperature slowly. It was then neutralized with HCl (1 M, 3.3 cm³) and poured into ice-water. The mixture was extracted with CH₂Cl₂ (200 cm³) and the extracts were evaporated under reduced pressure. The product was purified by column chromatography (silica, 1:1 EtOAc-petroleum) followed by recrystallisation to give 1,3,3,5-tetracarbonitrile (1.86 g, 14.3%), mp 90-92° C. (lit mp 92° C.).

Tetracyanoethylation of Pentaerythritol

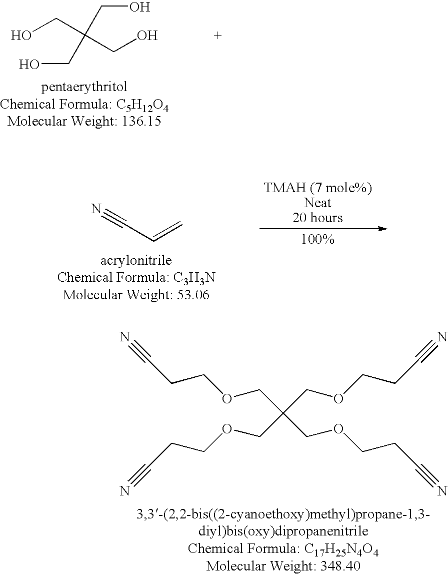

Pentaerythritol (2 g, 14.7 mmol) was mixed with acrylonitrile (5 cm³, 4.03 g, 76 mmol) and the mixture was cooled in an ice-bath while tetramethylammonium hydroxide (=TMAH, 25% in water, 0.25 cm³, 0.254 g, 7 mmol) was added. The mixture was then stirred at room temperature for 20 hours. After the reaction time the mixture was filtered through silica using a mixture of Et₂O and CH₂Cl₂ (1:1, 250 cm³) and the filtrated was evaporated under reduced pressure to give 3,3′-(2,2-bis((2-cyanoethoxy)methyl)propane-1,3-diyl)bis(oxy)dipropanenitrile (5.12 g, 100%) as a colourless oil.

Hexacyanoethylation of Sorbitol

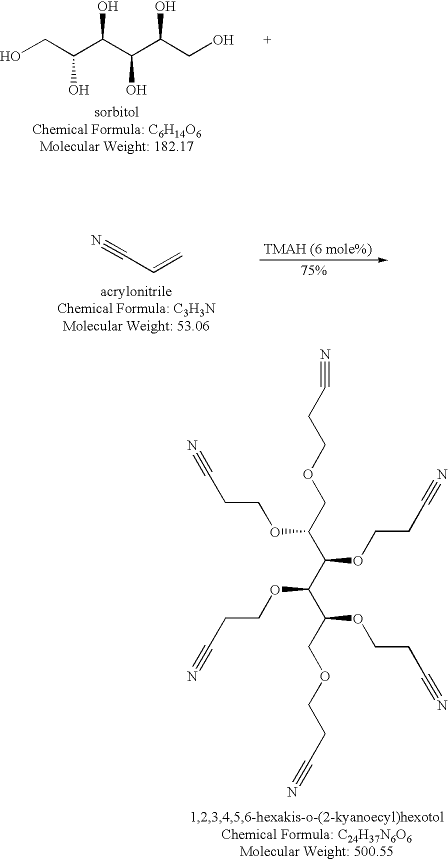

Sorbitol (2 g, 11 mmol) was mixed with acrylonitrile (7 cm³, 5.64 g, 106 mmol) and the mixture was cooled in an ice-bath while tetramethylammonium hydroxide (=TMAH, 25% in water, 0.25 cm³, 0.254 g, 7 mmol) was added. The mixture was then stirred at room temperature for 48 hours, adding another 0.25 cm³ of TMAH after 24 hours. After the reaction time the mixture was filtered through silica using a mixture of Et₂O and CH₂Cl₂ (1:1, 250 cm³) and the filtrate was evaporated under reduced pressure to live a fully cyanoethylated product (4.12 g, 75%) as a colourless oil.

Tricyanoethylation of diethanolamine to give 3,3′-(2,2′-(2-cyanoethylazanediyl)bis(ethane-2,1-diyl)bis(oxy))dipropanenitrile

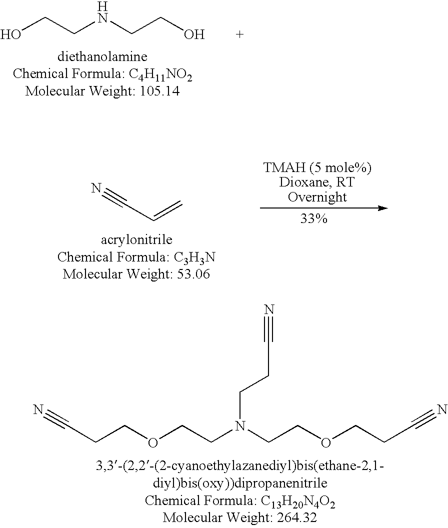

To an ice-cooled stirred solution of diethanolamine (2 g, 19 mmol) and TMAH (25% in water, 0.34 cm³, 0.35 g, 9.5 mmol) in dioxane (5 cm³) was added acrylonitrile (3.53 g, 66.1 mmol) dropwise. The mixture was then stirred overnight, and allowed to warm to room temperature. More acrylonitrile (1.51 g, 28 mmol) and TMAH (0.25 cm³, 7 mmol) was added and stirring was continued for additional 24 h, The crude mixture was filtered through a pad of silica (Et₂O/CH₂Cl₂ as eluent) and evaporated to remove dioxane. The residue was purified by column chromatography (silica, Et₂O to remove impurities followed by EtOAc to elute product) to give 3,3′-(2,2′-(2-cyanoethylazanediyl)bis(ethane-2,1-diyl)bis(oxy))dipropanenitrile (1.67 g, 33%) as an oil.

Reactions to Produce Amidoxime Compounds

Reaction of Acetonitrile to Give N′-hydroxyacetimidamide

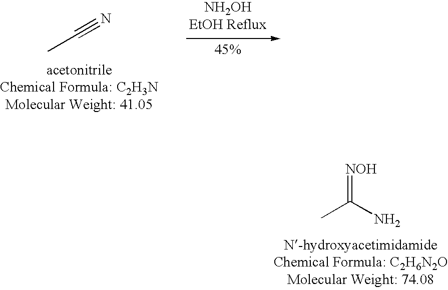

A solution of acetonitrile (0.78 g, +9 mmol) and hydroxylamine (50% in water, 4.65 cm³, 5.02 g, 76 mmol, 4 eq) in EtOH (100 cm³) was stirred under reflux for 1 hours, after which the solvent was removed under reduced pressure and the residue was recrystallised from iPrOH to give the product N′-hydroxyacetimidamide (0.63 g, 45%) as a solid, mp 134.5-136.5° C.

Reaction of Octanonitrile to give N′-hydroxyoctanimidamide

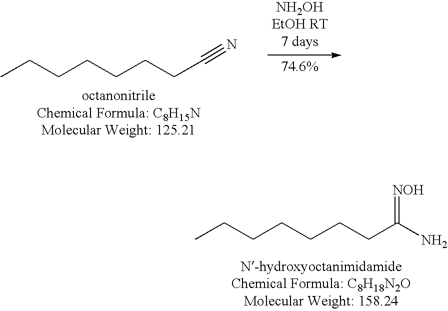

Octanonitrile (1 g, 7.99 mmol) and hydroxylamine (50% in water, 0.74 cm3, 0.79 g 12 mmol, 1.5 eq) in EtOH (1 cm³) were stirred at room temperature for 7 days. Water (10 cm³) was then added. This caused crystals to precipitate, these were collected by filtration and dried in high vacuum line to give the product N′-hydroxyoctanimidamide (0.94 g, 74.6%) as a white solid, mp 73-75° C.

Reaction of Chloroacetonitrile to Give 2-chloro-N′-hydroxyacetimidamide

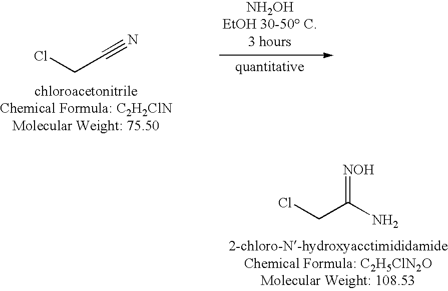

Chloroacetonitrile (1 g, 13 mmol) and hydroxylamine (50% in water, 0.89 cm³, 0.96 g, 14.6 mmol, 1.1 eq) in EtOH (1 cm³) were stirred at 30-50° C. for 30 min. The mixture was then extracted with Et₂O (3×50 cm³). The extracts were evaporated under reduced pressure to give the product 2-chloro-N′-hydroxyacetimidamide (0.81 g, 57.4%) as a yellow solid, mp 79-80° C.

Reaction of Ethyl 2-cyanoacetate to Give 3-amino-N-hydroxy-3-(hydroxyimino)propanamide

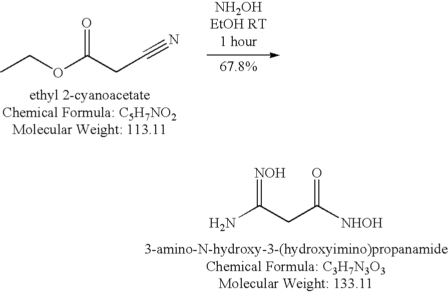

Ethyl cyanoacetate (1 g, 8.84 mmol) and hydroxylamine (50% in water, 1.19 cm3, 1.29 g, 19.4 mmol, 2.2 eq) in EtOH (1 cm³) were allowed to stand at room temperature for 1 hour with occasional swirling. The crystals formed were collected by filtration and dried in high vacuum line to give a colourless solid, 3-amino-N-hydroxy-3-(hydroxyimino)propanamide, mp 158° C. (decomposed) (lit mp 150° C.).

Reaction of 3-hydroxypropionitrile to Give N′,3-dihydroxypropanimidamide

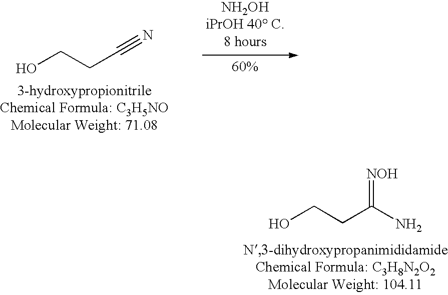

Equal molar mixture of 3-hydrxoypropionitrile and hydroxylamine heated to 40° C. for 8 hours with stirring. The solution is allowed to stand overnight yielding a fine slightly off white precipitate. The precipitated solid was filtered off and washed with iPrOH and dried to a fine pure white crystalline solid N′,3-dihydroxypropanimidamide mp 94° C.

Reaction of 2-cyanoacetic Acid to Give Isomers of 3-amino-3-(hydroxyimino)propanoic Acid

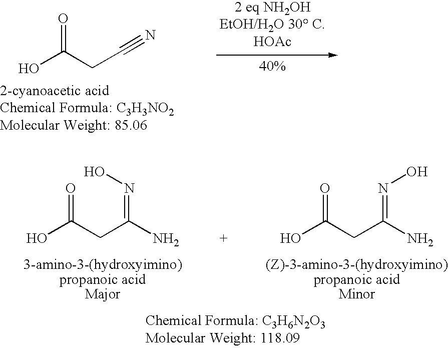

2-Cyanoacetic acid (1 g, 11.8 mmol) was dissolved in EtOH (10 cm³) and hydroxylamine (50% in water, 0.79 cm3, 0.85 g, 12.9 mmol, 1.1 eq) was added. The mixture was warmed at 40° C. for 30 min and the crystals formed (hydroxylammonium cyanoacetate) were filtered off and dissolved in water (5 cm³). Additional hydroxylamine (50% in water, 0.79 cm3, 0.85 g, 12.9 mmol, 1.1 eq) was added and the mixture was stirred at room temperature overnight. Acetic acid (3 cm³) was added and the mixture was allowed to stand for a few hours. The precipitated solid was filtered off and dried in high vacuum line to give the product 3-amino-3-(hydroxyimino)propanoic acid (0.56 g, 40%) as a white solid, mp 136.5° C. (lit 144° C.) as two isomers.

Characterization of the product using FTIR and NMR are as follows. vmax(KBr)/cm^{-1 3500}-3000 (br), 3188, 2764, 1691, 1551, 1395, 1356, 1265 and 1076; δH (300 MHz; DMSO-d6; Me4Si) 10.0-9.0 (br, NOH and COOH), 5.47 (2H, br s, NH₂) and 2.93 (2H, s, CH₂); δC (75 MHz; DMSO-d6; Me4Si) 170.5 (COOH minor isomer), 170.2 (COOH major isomer), 152.8 (C(NOH)NH₂ major isomer) 148.0 (C(NOH)NH₂ minor isomer), 37.0 (CH₂ minor isomer) and 34.8 (CH₂ major isomer).

Reaction of Adiponitrile to Give N′1,N′6-dihydroxyadipimidamide

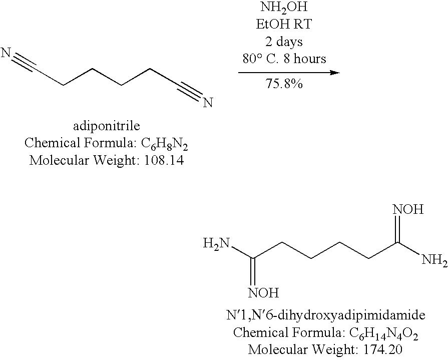

Adiponitrile (1 g, 9 mmol) and hydroxylamine (50% in water, 1.24 cm3, 1.34 g, 20 mmol, 2.2 eq) in EtOH (10 cm³) were stirred at room temperature for 2 days and then at 80° C. for 8 hours. The mixture was allowed to cool and the precipitated crystals were collected by filtration and dried in high vacuum line to give the product N′1,N′6-dihydroxyadipimidamide (1.19 g, 75.8%) as a white solid, mp 160.5 (decomposed) (lit decomposed 168-170° C.

Reaction of Sebaconitrile to give N′1,N′10-dihydroxydecanebis(imidamide)

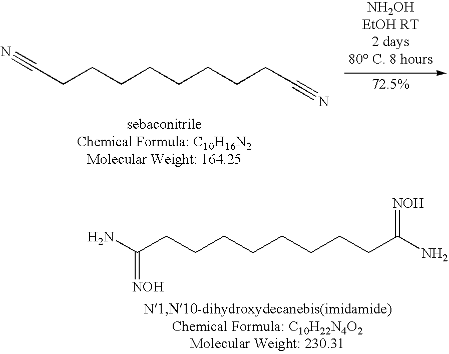

Sebaconitrile (1 g 6 mmol) and hydroxylamine (50% in water, 0.85 cm³, 0.88 g, 13.4 mmol, 2.2 eq) in EtOH (12 cm³) were stirred at room temperature for 2 days and then at 80° C. for 8 h. The mixture was allowed to cool and the precipitated crystals were collected by filtration and dried in high vacuum line to give the product N′1,N′10-dihydroxydecanebis(imidamide) (1 g, 72.5%); mp 182° C.

Reaction of 2-cyanoacetamide to Give 3-amino-3-(hydroxyimino)propanamide

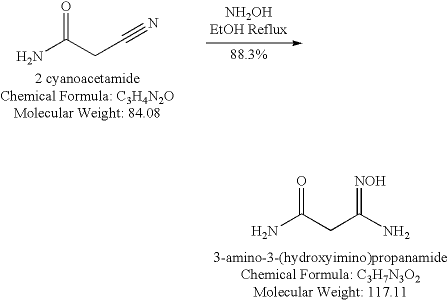

2-Cyanoacetamide (1 g, 11.9 mmol) and hydroxylamine (0.8 cm³, 13 mmol, 11.1 eq) in EtOH (6 cm³) were stirred under reflux for 2.5 hours. The solvents were removed under reduced pressure and the residue was washed with CH₂Cl₂ to give the product 3-amino-3-(hydroxyimino)propanamide (1.23 g, 88.3%) as a white solid, mp 159° C.

Reaction of Glycolonitrile to Give N′,2-dihydroxyacetimidamide

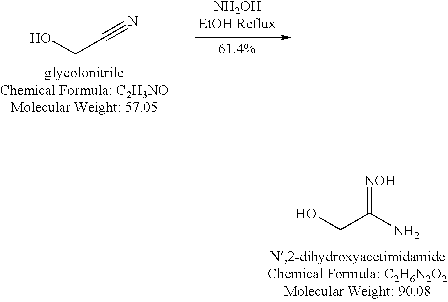

Glycolonitrile (1 g, 17.5 mmol) and hydroxylamine (50% in water, 2.15 cm³, 35 mmol, 2 eq) in EtOH (10 cm³) were stirred under reflux for 6 hours and then at room temperature for 24 hours. The solvent was evaporated and the residue was purified by column chromatography (silica, 1:3 EtOH—CH₂Cl₂) to give the product N′,2-dihydroxyacetimidamide (0.967 g, 61.4%) as an off-white solid, mp 63-65° C.

Reaction of 5-hexynenitrile to Give 4-cyano-N′-hydroxybutanimidamide

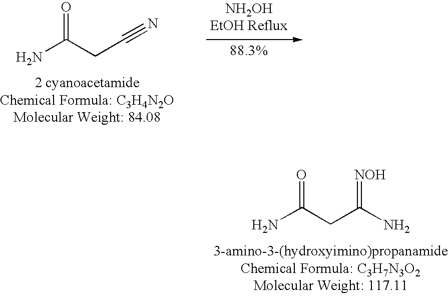

A solution of 5-hexynenitrile (0.93 g, 10 mmol) and hydroxylamine (50% in water, 1.22 cm³, 20 mmol) was stirred under reflux for 10 hours, after which volatiles were removed under reduced pressure to give the product 4-cyano-N′-hydroxybutanimidamide (1.30 g, 100%) as a white solid, mp 99.5-101° C.

Reaction of Iminodiacetonitrile to give 2,2′-azanediylbis(N′-hydroxyacetimidamide)

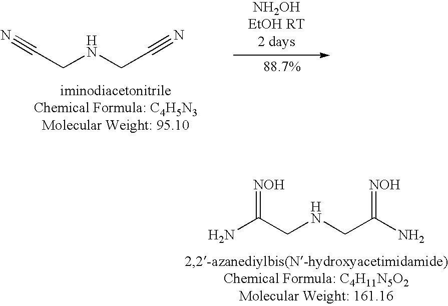

Commercial iminodiacetonitrile (Alfa-Aesar) was purified by dispersing the compound in water and extracting with dichloromethane, then evaporating the organic solvent from the extracts to give a white solid. Purified iminodiacetonitrile (0.82 g) and hydroxylamine (50% in water, 2.12 ml, 2.28 g, 34.5 mmol, 4 eq) in MeOH (6.9 ml) and water (6.8 ml) were stirred at room temperature for 48 hours. Evaporation of volatiles under reduced pressure gave a colorless liquid which was triturated with EtOH (40° C.) to give 2,2′-azanediylbis(N′-hydroxyacetimidamide) (1.23 g, 88.7%) as a white solid, mp 135-136° C., (lit mp 138° C.).

Reaction of 3-methylaminopropionitrile to Give N′-hydroxy-3-(methylamino)propanimidamide

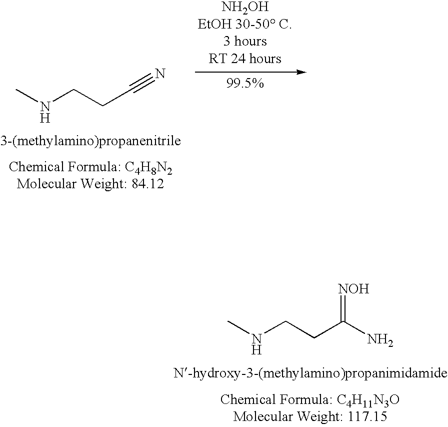

A solution of 3-methylaminopropionitrile (1 g, 11.9 mmol) and hydroxylamine (50% in water, 0.8 cm3, 0.864 g, 13.1 mmol, 1.1 eq) in EtOH (1 cm³) was stirred at 30-50° C. for 3 hours and then at room temperature overnight. The solvent was removed under reduced pressure (rotary evaporator followed by high vacuum line) to give the product N′-hydroxy-3-(methylamino)propanimidamide (1.387 g, 99.5% c) as a thick pale yellow oil.

Reaction of 3-(diethylamino)propanenitrile to Give 3-(diethylamino)-N′-hydroxypropanimidamide

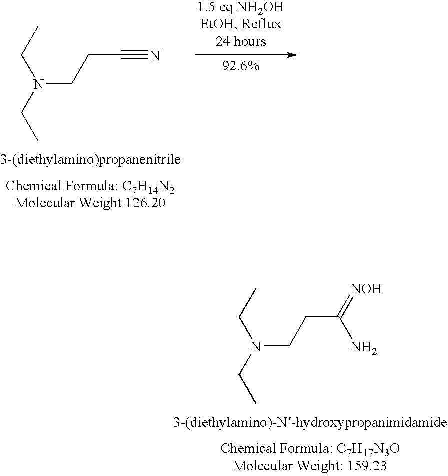

A solution of 3-(diethylamino)propanenitrile (1 g, 8 mmol) and NH₂OH (50% in water, 0.73 cm³, 11.9 mmol) in EtOH (10 cm³) were heated to reflux for 24 hours, after which the solvent and excess hydroxylamine were removed by rotary evaporator. The residue was freeze-dried and kept in high vacuum line until it slowly solidified to give 3-(diethylamino)-N′-hydroxypropanimidamide (1.18 g, 92.6%) as a white solid, mp 52-54° C.

Reaction of 3,3′,3″-nitrilotripropanenitrile with Hydroxylamine to Give 3,3′3″-nitrilotris(N′-hydroxypropanimidamide)

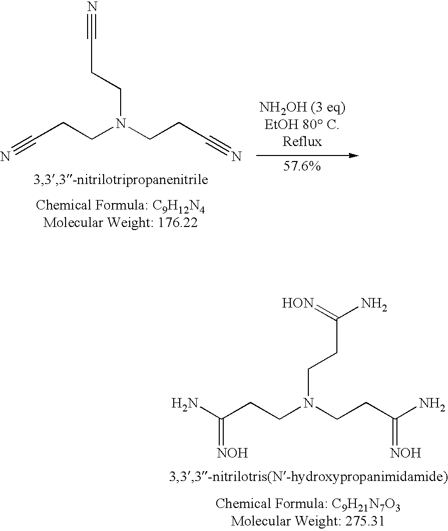

A solution of 3,3′,3″-nitrilotripropanenitrile (2 g, 11.35 mmol) and hydroxylamine (50% in water, 2.25 g, 34 mmol) in EtOH (25 cm³) was stirred at 80° C. overnight, then at room temperature for 24 hours. The white precipitate was collected by filtration and dried in high vacuum to give 3,3′3″-nitrilotris(N′-hydroxypropanimidamide) (1.80 g, 57.6%) as a white crystalline solid, mp 195-197° C. (decomposed).

Reaction of 3-(2-ethoxyethoxy)propanenitrile to Give 3-(2-ethoxyethoxy)-N′-hydroxypropanimidamide

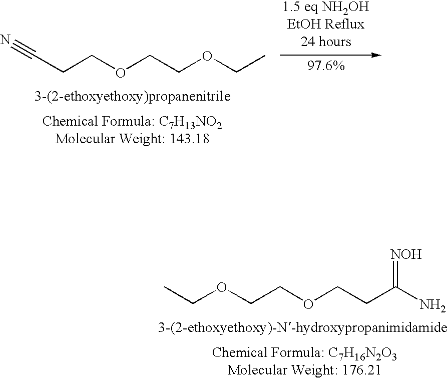

A solution of 3-(2-ethoxyethoxy)propanenitrile (1 g, 7 mmol) and NH₂OH (50% in water, 0.64 cm³, 10.5 mmol) in EtOH (10 cm³) were heated to reflux for 24 hours, after which the solvent and excess hydroxylamine were removed by rotary evaporator. The residue was freeze-dried and kept in high vacuum line for several hours to give 3-(2-ethoxyethoxy)-N′-hydroxypropanimidamide (1.2 g, 97.6%) as a colourless oil.

Reaction of 3-(2-(2-(dimethylamino)ethoxy)ethoxy)propanenitrile to Give 3-(2-(2-(dimethylamino)ethoxy)ethoxy)-N′-hydroxypropanimidamide

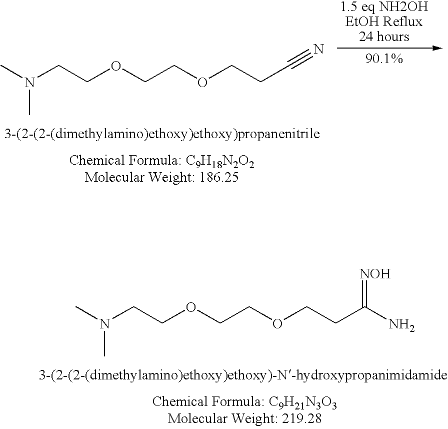

A solution of 3-(2-(2-(dimethylamino)ethoxy)ethoxy)propanenitrile (0.5 g, 2.68 mmol) and NH₂OH (50% in water, 0.25 cm³, 4 mmol) in EtOH (10 cm³) were stirred at 80° C. for 24 hours, after which the solvent and excess hydroxylamine were removed by rotary evaporator. The residue was freeze-dried and kept in high vacuum line for several hours to give 3-(2-(2-(dimethylamino)ethoxy)ethoxy)-N′-hydroxypropanimidamide (0.53 g, 90.1%) as a light yellow oil.

Reaction of 3,3′(2,2′-(2-cyanoethylazanediyl)bis(ethane-2,1-diyl)bis(oxy))dipropanenitrile with Hydroxylamine to Give 3,3′-(2,2′-(3-amino-3-(hydroxyimino)propylazanediyl)bis(ethane-2,1-diyl))bis(oxy)bis(N′-hydroxypropanimidamide)

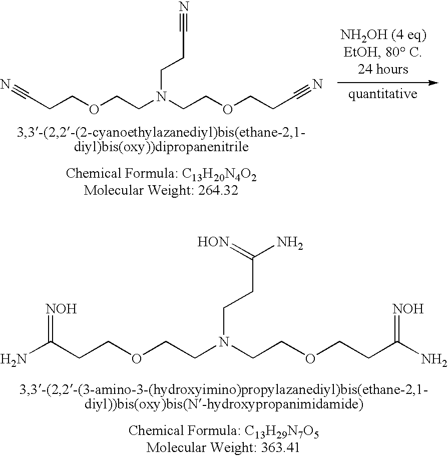

Treatment of 3,3′-(2,2′2(2-cyanoethylazanediyl)bis(ethane-2,1-diyl)bis(oxy))dipropanenitrile (0.8 g, 3 mmol) with NH₂OH (0.74 cm³, 12.1 mmol) in EtOH (8 cm³) gave 3,3′-(2,2′-(3-amino-3-(hydroxyimino)propylazanediyl)bis(ethane-2,1-diyl))bis(oxy)bis(N′-hydroxypropanimidamide) (1.09 g, 100%) as an oil.

Reaction of Iminodipropionitrile to Give 3,3′-azanediylbis(N′-hydroxypropanimidamide)

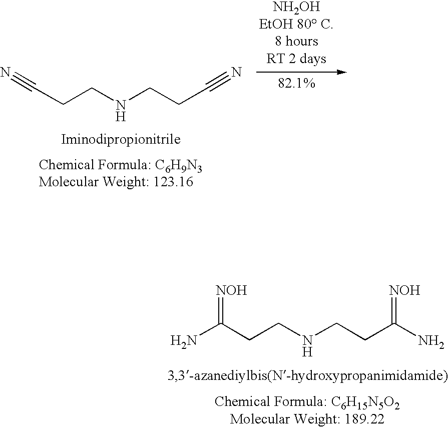

Iminodipropionitrile (1 g, 8 mmol) and hydroxylamine (50% in water, 1 cm³, 1.07 g, 16 mmol, 2 eq) in EtOH (8 cm³) were stirred at room temperature for 2 days and then at 80° C. for 8 hours. The mixture was allowed to cool and the precipitated crystals were collected by filtration and dried in high vacuum line to give the product 3,3′-azanediyibis(N′-hydroxypropanimidamide) (1.24 g, 82.1%) as a white solid, mp 180° C. (lit 160° C.).

Reaction of 3,3′,3″,3′″-(ethane-1,2-diylbis(azanetriyl))tetrapropanenitrile to Give 3,3′,3″,3′″-(ethane-1,2-diylbis(azanetriyl))tetrakis(N′-hydroxypropanimidamide) to Produce EDTA Analogue

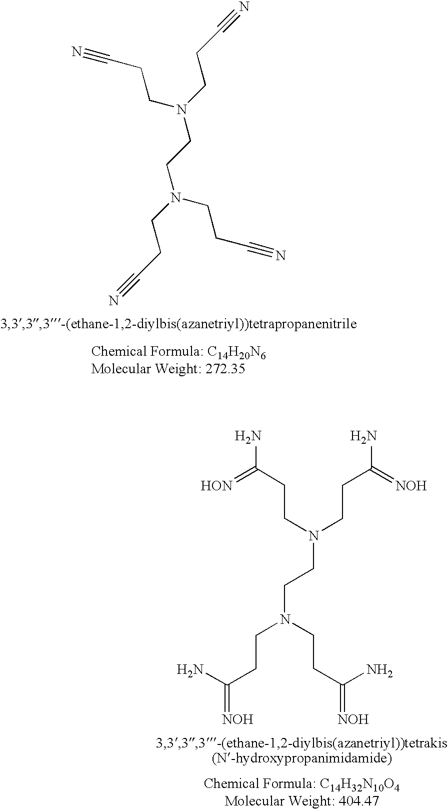

A solution of 3,3′,3″,3′″-(ethane-1,2-diylbis(azanetriyl))tetrapropanenitrile (1 g, 4 mmol) and NH₂OH (50% in water, 1.1 cm³, 18.1 mmol) in EtOH (10 cm³) was stirred at 80° C. for 24 hours and was then allowed to cool to room temperature. The solid formed was collected by filtration and dried under vacuum to give 3,3′,3″,3′″-(ethane-1,2-diylbis(azanetriyl))tetrakis(N′-hydroxypropanimidamide) (1.17 g, 76.4%) as a white solid, mp 191-192° C.

Reaction of 3,3′-(2,2-bis((2-cyanoethoxy)methyl)propane-1,3-diyl)bis(oxy)dipropanenitrile with Hydroxylamine to Give 3,3′-(2,2-bis((3-(hydroxyamino)-3-iminopropoxy)methyl)propane-1,3-diyl)bis(oxy)bis(N-hydroxypropanimidamide)

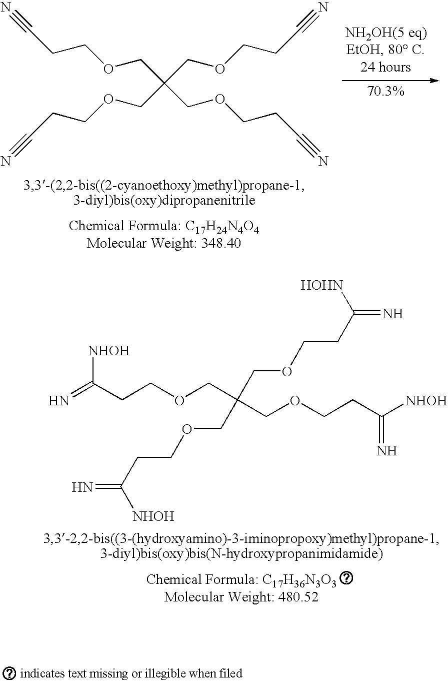

To a solution of 3,3′-(2,2-bis((2-cyanoethoxy)methyl)propane-1,3-diyl)bis(oxy)dipropanenitrile (1 g, 2.9 mmol) in EtOH (10 ml) was added NH₂OH (50% in water, 0.88 ml, 0.948 g, 14.4 mmol), the mixture was stirred at 80° C. for 24 hours and was then cooled to room temperature. Evaporation of the solvent and excess NH₂OH in the rotary evaporator followed by high vacuum for 1 hours gave 3,3′-(2,2-bis((3-(hydroxyamino)-3-iminopropoxy)methyl)propane-1,3-diyl)bis(oxy)bis(N-hydroxypropanimidamide) (0.98 g, 70.3%) as a white solid, mp 60° C.

Reaction of 3,3′-(2-cyanophenylazanediyl)dipropanenitrile with Hydroxylamine to Give 3,3′-(2-(N′-hydroxycarbamimidoyl)phenylazanediyl)bis(N′-hydroxypropanimidamide)

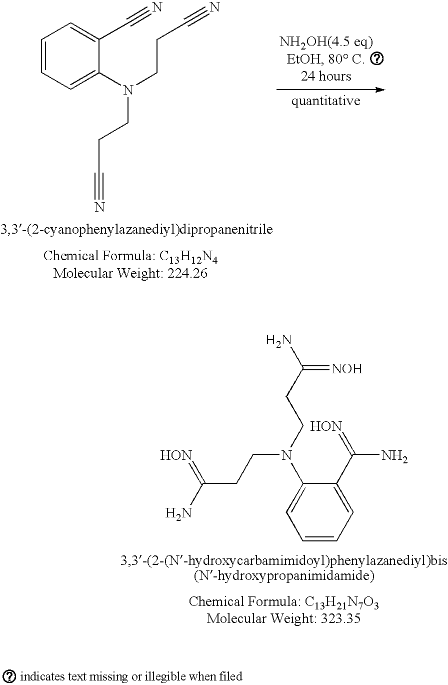

Treatment of 3,3′-(2-cyanophenylazanediyl)dipropanenitrile (1 g, 4.46 mmol) with NH2OH (1.23 ml, 20 mmol) in EtOH (10 ml) gave a crude product that was triturated with CH₂Cl₂ to give 3,3′-(2-(N′-hydroxycarbamimidoyl)phenylazanediyl)bis(N′-hydroxypropanimidamide) (1.44 g, 100%) as a solid, decomposed. 81° C.

Reaction of N,N-bis(2-cyanoethyl)acetamide with Hydroxylamine to Give N,N-bis(3-amino-3-(hydroxyimino)propyl)acetamide

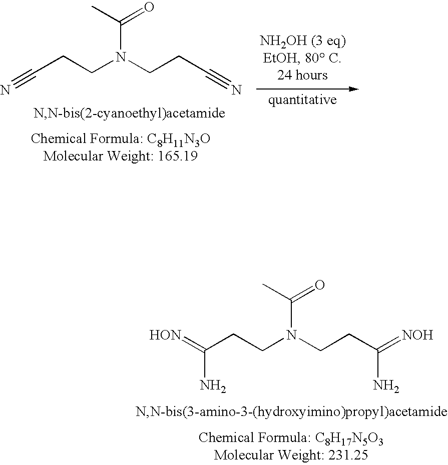

Treatment of N,N-bis(2-cyanoethyl)acetamide (0.5 g, 3.03 mmol) with NH₂OH (0.56 ml, 9.1 mmol) in EtOH (5 ml) gave N,N-bis(3-amino-3-(hydroxyimino)propyl)acetamide (0.564 g, 100%) as a white solid, mp 56.4-58° C.

Reaction of 3,3′-(2,2′-(methylazanediyl)bis(ethane-2,1-diyl)bis(oxy))dipropanenitrile with Hydroxylamine to Give 3,3′-(22′-(methylazanediyl)bis(ethane-2,1-diyl)bis(oxy))bis(N′-hydroxypropanimidamide).

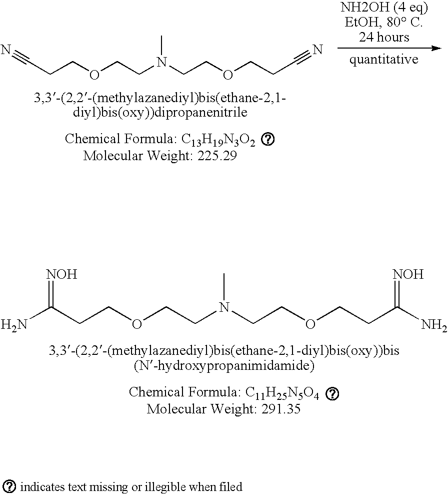

Treatment of 3,3′-(2,2′-(methylazanediyl)bis(ethane-2,1-diyl)bis(oxy))dipropanenitrile (1 g 4.4 mmol) with NH₂OH (0.82 mL, 13.3 mmol) in EtOH (10 ml) gave 3,3′-(2,2′-(methylazanediyl)bis(ethane-2,1-diyl)bis(oxy))bis(N′-hydroxypropanimidamide) (1.28 g, 100%) as an oil.

Reaction of Glycol Derivative 3,3′-(ethane-1,2-diylbis(oxy))dipropanenitrile to Give 3,3′-(ethane-1,2-diylbis(oxy))bis(N′-hydroxypropanimidamide)

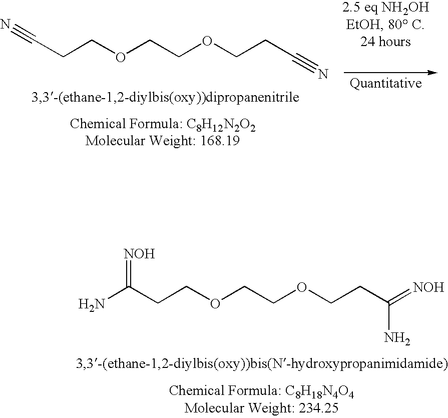

A solution of 3,3′-(ethane-1,2-diylbis(oxy))dipropanenitrile (1 g, 5 mmol) and NH₂OH (50% in water, 0.77 cm³ 12.5 mmol) in EtOH (10 cm³) was stirred at 80° C. for 24 hours and then at room temperature for 24 hours. The solvent and excess NH₂OH were evaporated off and the residue was freeze-dried to give 3,3′-(ethane-1,2-diylbis(oxy))bis(N′-hydroxypropanimidamide) (1.33 g, 100%) as a viscous oil.

Reaction of 3,3′-(piperazine-1,4-diyl)dipropanenitrile to give 3,3′-(piperazine-1,4-diyl)bis(N′-hydroxypropanimidamide)

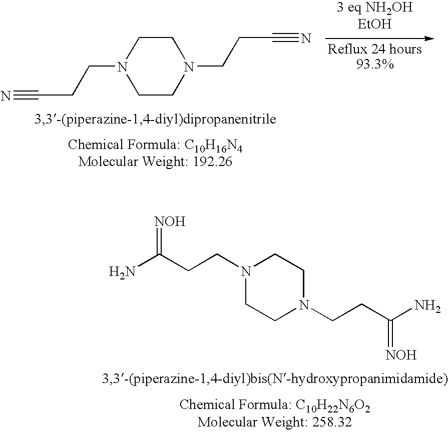

A solution of 3,3′-(piperazine-1,4-diyl)dipropanenitrile (1 g, 5.2 mmol) and NH₂OH (50% in water, 0.96 cm³, 15.6 mmol) in EtOH (10 cm³) were heated to reflux for 24 hours, after which the mixture was allowed to cool to room temperature. The solid formed was collected by filtration and dried in high vacuum line to give 3,3′-(piperazine-1,4-diyl)bis(N′-hydroxypropanimidamide) (1.25 g, 93.3%) as a white solid, decp 238° C. (brown coloration at >220° C.

Reaction of Cyanoethylated Sorbitol Compound with Hydroxylamine to Give 1,2,3,4,5,6-hexakis-O-[3-(hydroxyamino)-3-iminopropyl Hexitol

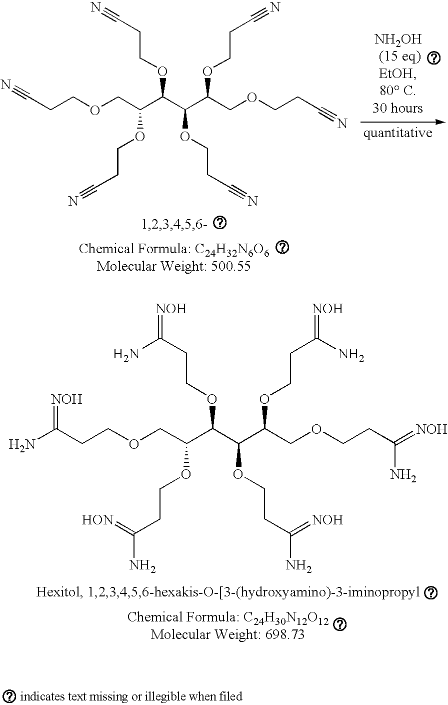

A solution of cyanoethylated product of sorbitol (0.48 g, 0.96 mmol) and NH₂OH (50% in water, 0.41 ml, 0.44 g, 6.71 mmol) in EtOH (5 ml) was stirred at 80° C. for 24 hours. Evaporation of solvent and NMR analysis of the residue showed incomplete conversion. The product was dissolved in water (10 ml) and EtOH (100 ml) and NH₂OH (0.5 g, 7.6 mmol) was added. The mixture was stirred at 80° C. for a further 7 hours. Removal of all volatiles after the reaction gave 1,2,3,4,5,6-hexakis-O-[3-(hydroxyamino)-3-iminopropyl Hexitol, (0.67 g, 100%) as a white solid, mp 92-94° C. (decomposed).

Reaction of Benzonitrile to give N′-hydroxybenzimidamide

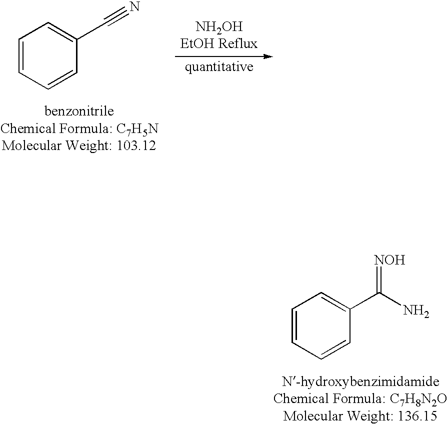

Benzonitrile (0.99 cm³, 1 g, 9.7 mmol) and hydroxylamine (50% in water, 0.89 cm³, 0.96 g, 14.55 mmol, 1.5 eq) were stirred under reflux in EtOH (10 cm³) for 48 hours. The solvent was evaporated under reduced pressure and water (10 cm³) was added to the residue. The mixture was extracted with dichloromethane (100 cm³) and the organic extract was evaporated under reduced pressure. The residue was purified by column chromatography to give the product N′-hydroxybenzimidamide (1.32 g, 100%) as a white crystalline solid, mp 79-81° C. (lit 79-80° C. This procedure is suitable for all starting materials bearing a benzene ring.

Reaction of 3-phenylpropionitrile to Give N′-hydroxy-3-phenylpropanimidamide

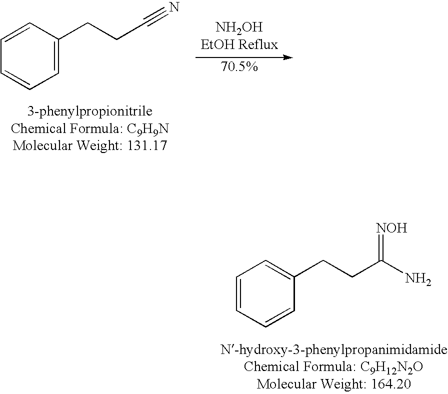

Phenylpropionitrile (1 g, 7.6 mmol) was reacted with hydroxylamine (50% in water, 0.94 cm³, 15.2 mmol, 2 eq) in EtOH (7.6 cm³) in the same manner as in the preparation of N′-hydroxybenzimidamide (EtOAc used in extraction) to give the product N′-hydroxy-3-phenylpropanimidamide (0.88 g, 70.5%) as a white solid, mp 42-43° C.

Reaction of M-tolunitrile to Give N′-hydroxy-3-methylbenzimidamide

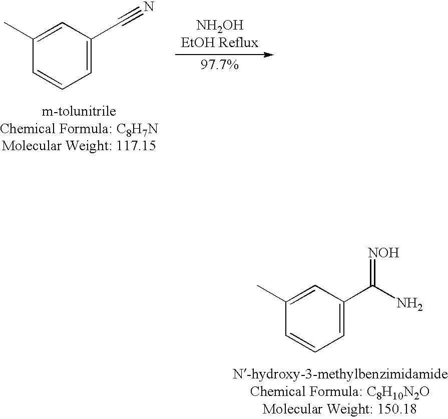

The reaction of m-tolunitrile (1 g, 8.54 mmol) and hydroxylamine (0.78 cm³, 12.8 mmol, 1.5 eq) in EtOH (8.5 cm³) was performed in the same manner as in the preparation of N′-hydroxybenzimidamide, to give the product N′-hydroxy-3-methylbenzimidamide (1.25 g, 97.7%) as a white solid, mp 92° C. (lit 88-90° C.).

Reaction of benzyl cyanide to give N′-hydroxy-2-phenylacetimidamide

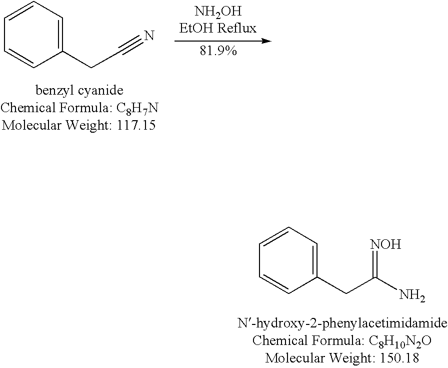

Benzyl cyanide (1 g, 8.5 mmol) and hydroxylamine (50% in water, 1.04 Cm³, 17 mmol, 2 eq) in EtOH (8.5 cm³) were reacted in the same manner as in the preparation of N′-hydroxybenzimidamide (EtOAc used in extraction) to give the product N′-hydroxy-2-phenylacetimidamide (1.04 g, 81.9%) as a pale yellow solid, mp 63.5-64.5° C. (lit 57-59° C.).

Reaction of Anthranilonitrile to Give 2-amino-N′-hydroxybenzimidamide

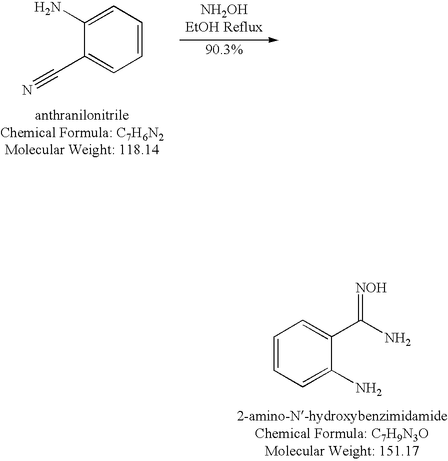

Anthranilonitrile (1 g, 8.5 mmol) and hydroxylamine (50% in water, 0.57 cm³, 9.3 mmol, 1.1 eq) in EtOH (42.5 cm³) were stirred under reflux for 24 hours, after which the volatiles were removed under reduced pressure and residue was partitioned between water (5 cm³) and CH₂Cl₂ (100 cm³). The organic phase was evaporated to dryness in the rotary evaporator followed by high vacuum line to give the product 2-amino-N′-hydroxybenzimidamide (1.16 g, 90.3%) as a solid, mp 85-86° C.

Reaction of Phthalonitrile to Give Isoindoline-1,3-dione Dioxime

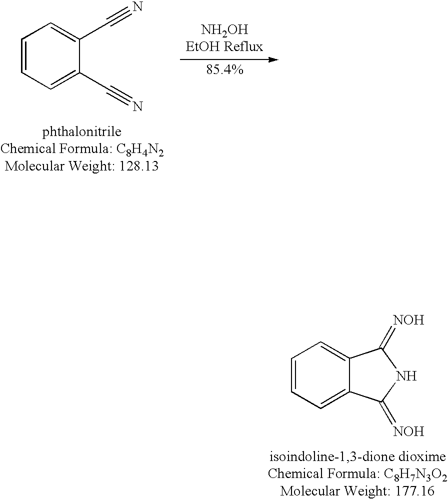

Phthalonitrile (1 g, 7.8 mmol) and hydroxylamine (1.9 cm³, 31.2 mmol, 4 eq) in EtOH (25 cm³) were stirred under reflux for 60 hours, after which the volatiles were removed under reduced pressure and the residue was washed with EtOH (2 cm³) and CH₂Cl₂ (2 cm³) to give the cyclised product isoindoline-1,3-dione dioxime (1.18 g, 85.4%) as a pale yellow solid, mp 272-275° C. (decomposed) (lit 271° C.).

Reaction of 2-cyanophenylacetonitrile to Give the Cyclised Product 3-aminoisoquinolin-1(4H)-one Oxime or 3-(hydroxyamino)-3,4-dihydroisoquinolin-1-amine.

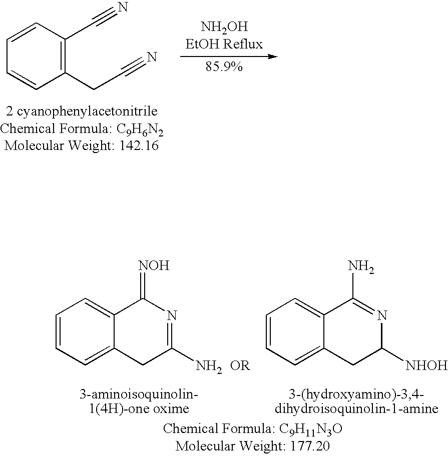

A solution of 2-cyanophenylacetonitrile (1 g, 7 mmol) and hydroxylamine (1.7 cm³ 28.1 mmol, 4 eq) in EtOH (25 cm³) were stirred under reflux for 60 hours, after which the volatiles were removed under reduced pressure. The residue was recrystallised from EtOH-water (1:4, 15 cm³) to give the cyclised product 3-aminoisoquinolin-1(4H)-one oxime or 3-(hydroxyamino)-3,4-dihydroisoquinolin-1-amine (1.15 g, 85.9%) as a solid, mp 92.5-94.5° C.

Reaction of Cinnamonitrile to Give N′-hydroxycinnamimidamide

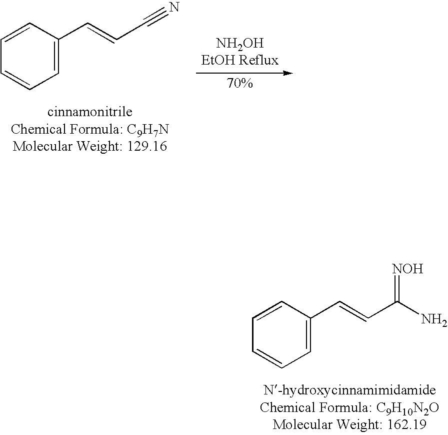

Cinnamonitrile (1 g, 7.74 mmol) and hydroxylamine (0.71 cm³, 11.6 mmol, 1.5 eq) were reacted in EtOH (7 cm³) as described for AO6 (two chromatographic separations were needed in purification) to give N′-hydroxycinnamimidamide (0.88 g, 70%) as a light orange solid, mp 85-87° C. (lit 93° C.).

Reaction of 5-cyanophthalide to Give the Product N′-hydroxy-1-oxo-1,3-dihydroisobenzofuran-5-carboximidamide

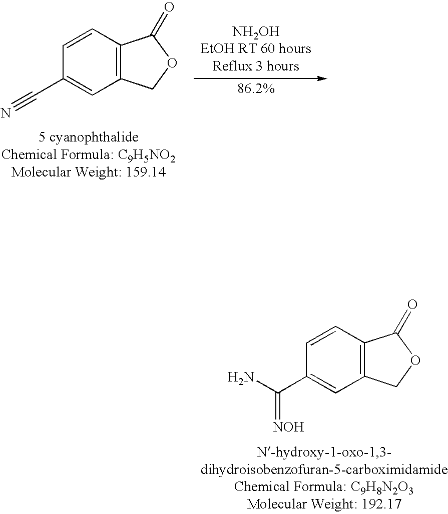

A solution of 5-cyanophthalide (1 g, 6.28 mmol) and hydroxylamine (50% in water, 0.77 cm³ 0.83 g, 12.6 mmol, 2 eq) in EtOH (50 cm³) was stirred at room temperature for 60 hours and then under reflux for 3 hours. After cooling to room temperature and standing overnight, the solid formed was collected by filtration and dried in high vacuum line to give the product N′-hydroxy-1-oxo-1,3-dihydroisobenzofuran-5-carboximidamide (1.04 g, 86.2%) as a white solid, mp 223-226° C. (decomposed).

Reaction of 4-chlorobenzonitrile to Give the Product 4-chloro-N′-hydroxybenzimidamide

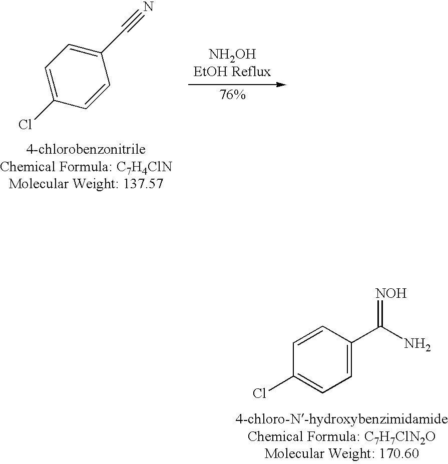

A solution of 4-chlorobenzonitrile (1 g, 7.23 mmol) and hydroxylamine (50% in water, 0.67 cm³, 10.9 mmol, 1.5 eq) in EtOH (12.5 cm³) was stirred under reflux for 48 hours. The solvent was removed under reduced pressure and the residue was washed with CH₂Cl₂ (10 cm³) to give the product 4-chloro-N′-hydroxybenzimidamide (0.94 g, 76%) as a white solid, mp 133-135° C.

Reaction of 3-(phenylamino)propanenitrile to Give N′-hydroxy-3-(phenylamino)propanimidamide

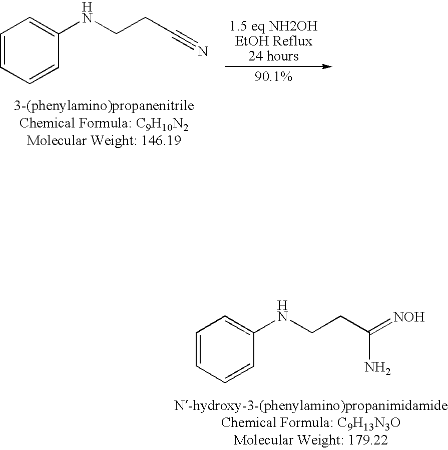

A solution of 3-(phenylamino)propanenitrile (1 g, 6.84 mmol) and NH₂OH (50% in water, 0.63 cm³, 10.26 mmol) in EtOH (10 cm³) were heated to reflux for 24 hours, after which the solvent and excess hydroxylamine were removed by rotary evaporator. To the residue was added water (10 cm³) and the mixture was extracted with CH₂Cl₂ (100 cm³). The extracts were concentrated under reduced pressure and the residue was purified by column chromatography (silica, Et₂O) to give N′-hydroxy-3-(phenylamino)propanimidamide (0.77 g, 62.8%) as a white solid, mp 93-95° C. (lit mp 91-91.5° C.).

Reaction of 4-pyridinecarbonitrile to Give the Product N′-hydroxyisonicotinimidamide

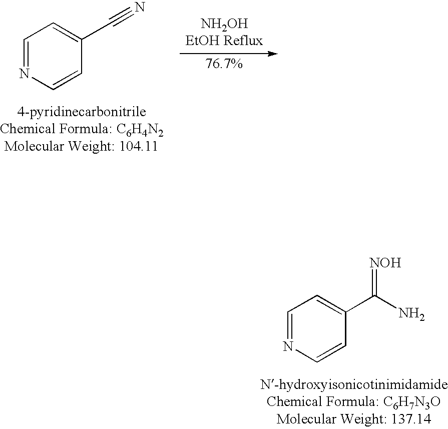

Pyridinecarbonitrile (1 g, 9.6 mmol) and hydroxylamine (50% in water, 0.88 cm³, 14.4 mmol, 1.5 eq) in EtOH (10 cm³) were stirred under reflux for 18 hours, after which the volatiles were removed under reduced pressure and the residue was recrystallised from EtOH to give the product N′-hydroxyisonicotinimidamide (1.01 g, 76.7%) as a solid, mp 203-205° C.

With reference to the present invention, as hereinafter more fully described, the claimed compounds can be applied to applications in the state of the art forming a background to the present invention includes the following U.S. patents, the disclosures of which hereby are incorporated herein, in their respective entireties.

### EXAMPLES OF EMBODIMENTS OF THE PRESENT INVENTION

Note that all patents cited in the examples are incorporated herein by reference regarding the proportions, amounts and support for the compositions and methods described in the examples.

### Example 1

The patents referred to in the examples herein and elsewhere in the description and summary are each hereby incorporated by reference in their entirety. One embodiment involves a method for removing organometallic and organosilicate residues remaining after a dry etch process from semiconductor substrates. The substrate is exposed to a conditioning solution of phosphoric acid, hydrofluoric acid, and a carboxylic acid, such as acetic acid, which removes the remaining dry etch residues while minimizing removal of material from desired substrate features. The approximate proportions of the conditioning solution are typically 80 to 95 percent by weight amidoxime compound and acetic acid, 1 to 15 percent by weight phosphoric acid, and 0.01 to 5.0 percent by weight hydrofluoric acid. See, U.S. Pat. No. 7,261,835.

Another embodiment includes from about 0.5% to about 24% by weight of complexing agents with amidoxime functional groups with an method having a pH between about 1.5 and about 6 and comprising: at least about 75% by weight of a mixture of water and an organic solvent; from about 0.5% to about 10% by weight phosphoric acid; optionally one or more other acid compounds; optionally one or more fluoride-containing compounds; and at least one alkaline compound selected from the group consisting of: a trialkylammonium hydroxide and/or a tetraalkylammonium hydroxide; a hydroxylamine derivative; and one or more alkanolamines.

### Example 2

Table 1 lists other embodiments of the present invention where the formulations additionally include from about 0.5% to about 24% by weight of compounds with amidoxime functional groups in methods. Such formulations may contain additional components consistent with this application such as surfactants, alkaline components, and organic solvents.

TABLE 1
Examples of Useful Formulations with Chelating Agents for Use
with Amidoxime Compounds of the Present Invention

| H₃PO₄ (wt %) | Other Acid | wt % |
|---|---|---|
| 2 | methanesulfonic | 1.47 |
| 2 | pyrophosphoric acid (PPA) | 3.0 |
| 2 | Fluorosicilic | 0.24 |
| 2 | Oxalic | 2.0 |
| 4 | Oxalic | 2.0 |
| 6 | Glycolic | 1.0 |
| 3 | Oxalic | 2.0 |
| 3 | Lactic | 2.0 |
| 4 | Lactic | 2.0 |
| 3 | Citric | 2.0 |
| 4 | Citric | 2.0 |
| 3 | PPA | 0.5 |
| 3 | Glycolic | 2.0 |
| 6 | Glycolic | 2.0 |
| 3 | PPA | 2.0 |
| 3 | PPA | 4.0 |

### Example 3

Another embodiment is a composition for cleaning or etching a semiconductor substrate and method for using the same. The compositions include from about 0.01% to about 50%, more preferably about 0.5% to about 24% by weight of compounds with amidoxime functional groups may include a fluorine-containing compound as an active agent such as a quaternary ammonium fluoride, a quaternary phosphonium fluoride, sulfonium fluoride, more generally an -onium fluoride or “multi” quaternary-onium fluoride that includes two or more quaternary-onium groups linked together by one or more carbon-containing groups. The composition may further include a pH adjusting acid such as a mineral acid, carboxylic acid, dicarboxylic acid, sulfonic acid, or combination thereof to give a pH of about 2 to 9. The composition can be anhydrous and may further include an organic solvent such as an alcohol, amide, ether, or combination thereof, The compositions are useful for obtaining improved etch rate, etch selectivity, etch uniformity and cleaning criteria on a variety of substrates.

### Example 4

In another embodiment, the present invention can be used with methods and compositions for removing silicon-containing sacrificial layers from Micro Electro Mechanical System (HEMS) and other semiconductor substrates having such sacrificial layers is described. The etching compositions include a supercritical fluid (SCF), an etchant species, a co-solvent, chelating agent containing at least one amidoxime group, and optionally a surfactant. Such etching compositions overcome the intrinsic deficiency of SCFs as cleaning reagents, viz., the nonpolar character of SCFs and their associated inability to solubilize polar species that must be removed from the semiconductor substrate. The resultant etched substrates experience lower incidents of stiction relative to substrates etched using conventional wet etching techniques. See U.S. Pat. No. 7,160,815.

### Example 5

In another embodiment, the invention uses a supercritical fluid (SFC)-based composition, comprising at least one co-solvent, at least one etchant species, and optionally at least one surfactant, wherein said at least one etchant comprises an alkyl phosphonium difluoride and wherein said SFC-based composition is useful for etching sacrificial silicon-containing layers, said compositions containing from about 0.01% to about 50% by weight, preferably about 0.5% to about 24%, of compounds with one or more chelating group, at least one being an amidoxime functional groups. In another embodiment the surfactant comprises at least one nonionic or anionic surfactant, or a combination thereof, and the surfactant is preferably a nonionic surfactant selected from the group consisting of fluoroalkyl surfactants, polyethylene glycols, polypropylene glycols, polyethylene ethers, polypropylene glycol ethers, carboxylic acid salts, dodecylbenzenesulfonic acid; dodecylbenzenesulfonic salts, polyaciylate polymers, dinonylphenyl polyoxyethylene, silicone polymers, modified silicone polymers, acetylenic diols, modified acetylenic diols, alkylammonium salts, modified alkylammonium salts, and combinations comprising at least one of the foregoing.

### Example 6

Another embodiment of the present invention is a composition for use in semiconductor processing wherein the composition comprises water, phosphoric acid, and an organic acid; wherein the organic acid is ascorbic acid or is an organic acid having two or more carboxylic acid groups (e.g., citric acid). The said compositions containing from about 0.01% to about 50% by weight, preferably about 0.5% to about 24%, of compounds with one or more chelating groups/agents, at least one being an amidoxime functional group/compound and such compounds can be in addition to, part of, or in substitution of the organic acid. The water can be present in about 40 wt. % to about 85 wt. % of the composition, the phosphoric acid can be present in about 0.01 wt. % to about 10 wt. % of the composition, and the organic acid can be present in about 10 wt. % to about 60 wt. % of the composition. The composition can be used for cleaning various surfaces, such as, for example, patterned metal layers and vias by exposing the surfaces to the composition. See U.S. Pat. No. 7,135,444.

### Example 7

The present invention can also be used with a polishing liquid composition for polishing a surface, with one embodiment comprising an insulating layer and a metal layer, the polishing liquid composition comprising a compound having six or more carbon atoms and a structure in which each of two or more adjacent carbon atoms has a hydroxyl group in a molecule, and water, wherein the compound having a structure in which each of two or more adjacent carbon atoms has a hydroxyl group in a molecule is represented by the formula (I): R¹—X—(CH₂)_{q}—[CH(OH)]L—CH₂OH (1) wherein R¹ is a hydrocarbon group having 1 to 12 carbon atoms; X is a group represented by (CH₂)ₘ, wherein m is 1, oxygen atom, sulfur atom, COO group, OCO group, a group represented by NR² or O(R²O)P(O)O, wherein R² is hydrogen atom or a hydrocarbon group having 1 to 24 carbon atoms; q is 0 or 1; and n is an integer of 1 to 4, further comprising from about 0.01% to about 50% by weight, preferably about 0.5% to about 24%, of compounds with one or more chelating groups/agents, at least one being an amidoxime functional group/compound and such compounds can be in addition to, part of, or in substitution of an organic acid. Some embodiments include an abrasive. See U.S. Pat. No. 7,118,685.

### Example 8

Another embodiment of the present invention is a composition for use in semiconductor processing wherein the composition comprises water, phosphoric acid, and an organic acid; wherein the organic acid is ascorbic acid or is an organic acid having two or more carboxylic acid groups (e.g., citric acid), further comprising from about 0.01% to about 50% by weight, preferably about 0.5% to about 24%, of compounds with one or more chelating groups/agents, at least one being an amidoxime functional group/compound and such compounds can be in addition to part of, or in substitution of the organic acid. The water can be present in about 40 wt. % to about 85 wt. % of the composition, the phosphoric acid can be present in about 0.01 wt. % to about 10 wt. % of the composition, and the organic acid can be present in about 10 wt. % to about 60 wt. % of the composition. The composition can be used for cleaning various surfaces, such as, for example, patterned metal layers and vias by exposing the surfaces to the composition. See U.S. Pat. Nos. 7,087,561, 7,067,466, and 7,029,588.

### Example 9

In another embodiment of the present invention, from about 0.01% to about 50% by weight, preferably about 0.5% to about 24%, of compounds with one or more chelating groups/agents, at least one being an amidoxime functional group/compound can be used with an oxidizing solution and process for the in situ oxidation of contaminants, including hydrocarbon, organic, bacterial, phosphonic acid, and other contaminants, the contaminants being found in various surfaces and media, including soil, sludge, and water. In a preferred embodiment, the solution further includes a peroxygen compound, such as hydrogen peroxide, in solution with a pre-mixed solution of a carboxylic acid and a halogen salt, such as glycolic acid and sodium bromide, respectively.

### Example 10

In another embodiment of the present invention from about 0.01% to about 5% by weight, preferably about 0.01 to about 0.1% of compounds with one or more chelating groups/agents, at least one being an amidoxime functional group/compound can be used with a chemical mechanical polishing slurry that is free of heteropolyacid and consisting essentially of about 3 to about 5 percent abrasive, about 3 to about 5 percent hydrogen peroxide, about 0.05 to about 0.1 percent citric acid, about 0.05 to about 0.5 percent iminodiacetic acid, about 0.005 to about 0.02 percent ammonia, and about 85-90 percent water, wherein the abrasive consists essentially of polymethylmethacrylate. See U.S. Pat. No. 7,029,373.

### Example 11

In another embodiment, the present invention includes a non-corrosive cleaning composition for removing residues from a substrate comprising: (a) water; (b) at least one hydroxyl ammonium compound; (c) at least one basic compound, preferably selected from the group consisting of amines and quaternary ammonium hydroxides; (d) at least one organic carboxylic acid; (e) from about 0.011 to about 50% by weight, preferably about 0.5% to about 24%, of compounds with one or more chelating groups/agents, at least one being an amidoxime functional group/compound and such compounds can be in addition to, part of, or in substitution of the organic acid; and (f) optionally, a polyhydric compound. The pH of the composition is preferably between about 2 to about 6. See U.S. Pat. No. 7,001,874, which is incorporated herein by reference.

### Example 12

The present invention may also be used with a cleaning solution where the cleaning solution also contains one of polyvalent carboxylic acid and its salt, such as where the polyvalent carboxylic acid contains at least one selected from the group consisting of oxalic acid, citric acid, malic acid, maleic acid, succinic acid, tartaric acid, and malonic acid, wherein the cleaning solution contains from about 0.01% to about 50% by weight, preferably about 0.5% to about 24%, of compounds with one or more chelating groups/agents, at least one being an amidoxime functional group/compound and such compounds can be in addition to, part of or in substitution of the organic acid, which can be used in addition to, as part of, or in substitution of the polyvalent carboxylic acid. In another embodiment, the cleaning solution further contains a polyamino carboxylic acid and its salt. See U.S. Pat. No. 6,998,352.

### Example 13

A further embodiment of the present invention is to a method of chemically-mechanically polishing a substrate, which method comprises: (i) contacting a substrate comprising at least one layer of ruthenium and at least one layer of copper with a polishing pad and a chemical-mechanical polishing composition comprising: (a) an abrasive consisting of α-alumina treated with a negatively-charged polymer or copolymer, (b) hydrogen peroxide, (c) from about 0.01% to about 50% by weight, preferably about 0.5% to about 24% of compounds with one or more chelating groups/agents, at least one being an amidoxime functional group/compound; (d) at least one heterocyclic compound, wherein the at least one heterocyclic compound comprises at least one nitrogen atom, (e) a phosphonic acid, and (f) water, (ii) moving the polishing pad relative to the substrate, and (iii) abrading at least a portion of the substrate to polish the substrate, wherein the pH of the water and any components dissolved or suspended therein is about 6 to about 12, wherein the at least one layer of ruthenium and at least one layer of copper are in electrical contact and are in contact with the polishing composition, wherein the difference between the open circuit potential of copper and the open circuit potential of ruthenium in the water and any components dissolved or suspended therein is about 50 mV or less, and wherein a selectivity for polishing copper as compared to ruthenium is about 2 or less.

### Example 14

Another embodiment of the present invention is to a semiconductor wafer cleaning formulation, including 1-21% wt. fluoride source, 20-55% wt. organic amine(s), 0.5-40% wt. nitrogenous component, e.g., a nitrogen-containing carboxylic acid or an imine, 23-50% wt. water, and 0-21% wt. of compounds with one or more chelating groups/agents, at least one being an amidoxime functional group/compound. The formulations are useful to remove residue from wafers following a resist plasma ashing step, such as inorganic residue from semiconductor wafers containing delicate copper interconnecting structures. See U.S. Pat. No. 6,967,169.

### Example 15

The present invention also includes a method for chemical mechanical polishing copper, barrier material and dielectric material, the method comprises the steps of: a) providing a first chemical mechanical polishing slurry comprising (i) 1-10 wt. % silica particles, (ii) 1-12 wt. % oxidizing agent, and (iii) 0-2 wt. % corrosion inhibitor and cleaning agent, wherein said first slurry has a higher removal rate on copper relative to a lower removal rate on said barrier material; b) chemical mechanical polishing a semiconductor wafer surface with said first slurry; c) providing a second chemical mechanical polishing slurry comprising (i) 1-10 wt. % silica particles, (ii) 0.1-1.5 wt. % oxidizing agent, and (iii) 0.1-2 wt. % carboxylic acid, having a pH in a range from about 2 to about 5, wherein the amount of (ii) is not more than the amount of (iii), and wherein said second slurry has a higher removal rate on said barer material relative to a lower removal rate on said dielectric material and an intermediate removal rate on copper; and d) chemical mechanical polishing said semiconductor wafer surface with said second slurry, wherein either or both slurries contains from about 0.01% to about 50% by weight, preferably about 0.5% to about 24%, of compounds with one or more chelating groups/agents, at least one being an amidoxime functional group/compound. See U.S. Pat. No. 6,936,542.

### Example 16

The present invention further includes a method for cleaning a surface of a substrate, which comprises at least the following steps (1) and (2), wherein the step (2) is carried out after carrying out the step (1): Step (1): A cleaning step of cleaning the surface of the substrate with an alkaline cleaning agent containing a complexing agent, and Step (2): A cleaning step employing a cleaning agent having a hydrofluoric acid content C (wt %) of from 0.03 to 3 wt %, the complexing agent is from about 0.011% to about 50% by weight, preferably about 0.5% to about 24%, of compounds with one or more chelating groups/agents, at least one being an amidoxime functional group/compound, See U.S. Pat. No. 6,896,744.

### Example 17

Another embodiment of the present invention includes a cleaning gas that is obtained by vaporizing a carboxylic acid and/or a compound with one or more chelating groups/agents, at least one being an amidoxime functional group/compound which is supplied into a treatment chamber having an insulating substance adhering to the inside thereof, and the inside of the treatment chamber is evacuated. When the cleaning gas supplied into the treatment chamber comes in contact with the insulating substance adhering to an inside wall and a susceptor in the treatment chamber, the insulating substance is turned into a complex, so that the complex of the insulating substance is formed. The complex of the insulating substance is easily vaporized due to its high vapor pressure. The vaporized complex of the insulating substance is discharged out of the treatment chamber by the evacuation. See U.S. Pat. No. 6,893,964.

### Example 18

The present invention includes a method for rinsing metallized semiconductor substrates following treatment of the substrates with an etch residue removal chemistry, the method comprising the steps of: providing at least one metallized semiconductor substrate, the substrate having etch residue removal chemistry thereon, wherein the etch residue removal chemistry includes N-methylpyrrolidinone; rinsing the etch residue removal chemistry from the substrate and minimizing metal corrosion of the substrate by rinsing the substrate with an aqueous medium comprising an anti-corrosive agent including an organic acid selected from the group consisting of mono- and polycarboxylic acids in an amount effective to minimize metal corrosion; removing the aqueous medium from the process vessel; and introducing a drying vapor into the process vessel which the substrate remains substantially stationary within the process vessel, wherein the remover includes from about 0.01% to about 50% by weight, preferably about 0.5% to about 24%, of compounds with one or more chelating groups/agents, at least one being an amidoxime functional group/compound, which can be in addition to, part of, or in substitution of the organic acid. The composition may further include acetic acid. See U.S. Pat. No. 6,878,213.

### Example 19

The present invention may also be used with the compositions of U.S. Pat. No. 6,849,200 wherein the iminodiacetic acid component is supplemented by or substituted with compounds with one or more chelating groups/agents, at least one being an amidoxime functional group/compound.

### Example 20

The present invention also includes a method of cleaning a surface of a copper-containing material by exposing the surface to an acidic mixture comprising NO₃—, F—, and one or more compounds with one or more chelating groups/agents, at least one being an amidoxime functional group/compound. The mixture may also include one or more organic acids to remove at least some of the particles. See U.S. Pat. No. 6,835,668.

### Example 21

The present invention also includes a cleaning composition comprising at least one of fluoride salts and hydrogen fluoride salts; an organic solvent having a hetero atom or atoms; optionally one or more surfactants in an amount of from 0.0001 to 10.0%; water and from about 0.01% to about 50% by weight, preferably about 0.5% to about 24%, of compounds with one or more chelating groups/agents, at least one being an amidoxime functional group/compound. See U.S. Pat. No. 6,831,048.

### Example 22

The present invention further includes a glycol-free composition for cleaning a semiconductor substrate, the composition consisting essentially of: a. an acidic buffer solution having an acid selected from a carboxylic acid and a polybasic acid and an ammonium salt of the acid in a molar ratio of acid to ammonium salt ranging from 10:1 to 1:10 and wherein the acidic buffer solution is present in an amount sufficient to maintain a pH of the composition from about 3 to about 6, b. from 30% by weight to 90% by weight of an organic polar solvent that is miscible in all proportion in water, c. from 0.1% by weight to 20% by weight of fluoride, d. from 0.5% by weight to 40% by weight of water, and e. optionally up to 15% by weight of a corrosion inhibitor The composition further contains from about 0.01% to about 50% by weight, preferably about 0.5% to about 24%, of compounds with one or more chelating groups/agents, at least one being an amidoxime functional group/compound or such compounds may be used in place of the corrosion inhibitor. See U.S. Pat. No. 6,828,289.

### Example 23

The present invention further includes compositions containing AEEA and or AMEA derivatives which can be present in an amount ranging from about 1% to about 99%, though in most instances the amount ranges from about 10% to about 85%. For each AEEA range given for various compositions described herein, there is a “high-AEEA” embodiment where the amount of AEEA is in the upper half of the range, and a “low-AEEA” embodiment where AEEA is present in an amount bounded by the lower half of the range. Generally, the higher AEEA embodiments exhibit lower etch rates than the low AEEA embodiments for selected substrates, the embodiments further include from about 0.011% to about 50% by weight, preferably about 0.5% to about 24%, of compounds with one or more chelating groups/agents, at least one being an amidoxime functional group/compound. In most embodiments, these compositions also include other compounds, particularly polar organic solvents, water, alkanolamines, hydroxylamines, additional chelating agents, and/or corrosion inhibitors. See U.S. Pat. No. 6,825,156.

### Example 24

A composition for the stripping of photoresist and the cleaning of residues from substrates, and for silicon oxide etch, comprising from about 0.01 percent by weight to about 10 percent by weight of one or more fluoride compounds, from about 10 percent by weight to about 95% by weight of a sulfoxide or sulfone solvent, and from about 20 percent by weight to about 50 percent by weight water, further including from about 0.01% to about 50% by weight, preferably about 0.5% to about 24%, of compounds with one or more chelating groups/agents, at least one being an amidoxime functional group/compound. The composition may contain corrosion inhibitors, chelating agents, co-solvents, basic amine compounds, surfactants, acids and bases. See U.S. Pat. No. 6,777,380.

### Example 25

A polishing composition for polishing a semiconductor substrate has a pH of under 5.0 and comprises (a) a carboxylic acid polymer comprising polymerized unsaturated carboxylic acid monomers having a number average molecular weight of about 20,000 to 1,500,000 or blends of high and low number average molecular weight polymers of polymerized unsaturated carboxylic acid monomers, (b) 1 to 15% by weight of an oxidizing agent, (c) up to 3.0% by weight of abrasive particles, (d) 50-5,000 ppm (parts per million) of an inhibitor, (e) up to 3.0% by weight of a complexing agent, such as, malic acid, and (f) 0.1 to 5.0% by weight of a surfactant, from about 0.01% to about 50% by weight, preferably about 0.5% to about 24%, of compounds with one or more chelating groups/agents, at least one being an amidoxime functional group/compound. See U.S. Pat. No. 6,679,928.

### Example 26

Particulate and metal ion contamination is removed from a surface, such as a semiconductor wafer containing copper damascene or dual damascene features, employing aqueous composition comprising a fluoride containing compound; a dicarboxylic acid and/or salt thereof; and a hydroxycarboxylic acid and/or salt thereof, the composition contains from about 0.01% to about 50% by weight, preferably about 0.5% to about 24%, of compounds with one or more chelating groups/agents, at least one being an amidoxime functional group/compound. See U.S. Pat. No. 6,673,757.

### Example 27

A semiconductor wafer cleaning formulation, including 2-98% wt. organic amine, 0-50% wt. water, 0.1-60% wt. 1,3-dicarbonyl compound chelating agent, 0-25% wt. of additional different chelating agent(s), 0.5-40% wt. nitrogen-containing carboxylic acid or an imine, and 2-98% wt polar organic solvent. The formulations are useful to remove residue from wafers following a resist plasma ashing step, such as inorganic residue from semiconductor wafers containing delicate copper interconnecting structures.

### Example 28

Another embodiment of the present invention relates to a method useful in removing etch residue from etcher equipment parts. The compositions used are aqueous, acidic compositions containing flouride and polar, organic solvents. The compositions are free of glycols and hydroxylamine and have a low surface tension and viscosity and further include from about 0.01% to about 50% by weight, preferably about 0.5% to about 24%, of compounds with one or more chelating groups/agents, at least one being an amidoxime functional group/compound. See U.S. Pat. No. 6,656,894.

### Example 29

The invention includes a method of cleaning a surface of a copper-containing material by exposing the surface to an acidic mixture comprising NO₃—, F— and from about 0.01% to about 50% by weight, preferably about 0.5% to about 24%, of compounds with one or more chelating groups/agents, at least one being an amidoxime functional group/compound and/or one or more organic acid anions having carboxylate groups. The invention also includes an improved semiconductor processing method of forming an opening to a copper-containing material. A mass is formed over a copper-containing material within an opening in a substrate. The mass contains at least one of an oxide barrier material and a dielectric material. A second opening is etched through the mass into the copper-containing material to form a base surface of the copper-containing material that is at least partially covered by particles comprising at least one of a copper oxide, a silicon oxide or a copper fluoride. The base surface is cleaned with a solution comprising nitric acid, hydrofluoric acid and one or more organic acids to remove at least some of the particles.

One or more organic acids may be used in the composition of this example. An exemplary composition includes an acetic acid solution (99.8%, by weight in water), an HF solution (49%, by weight in water), an HNO₃ solution (70.4%, by weight in water), and H₂O the resulting cleaning mixture being: from about 3% to about 20% compounds with one or more chelating groups/agents, at least one being an amidoxime functional group/compound, by weight; from about 0.1% to about 2.0% HNO₃ by weight; and from about 0.05% to about 3.0% HF, by weight. See U.S. Pat. No. 6,589,882.

### Example 30

Another embodiment of the present invention is a composition for selective etching of oxides over a metal. The composition contains water, hydroxylammonium salt, one or more compounds with one or more chelating groups/agents, at least one being an amidoxime functional group/compound, a fluorine containing compound, and optionally, a base. The pH of the composition is about 2 to 6. See U.S. Pat. No. 6,589,439.

### Example 31

Another embodiment of the present invention is an etching treatment comprising a combination including hydrofluoric acid of 15 percent by weight to 19 percent by weight, one or more compounds with one or more chelating groups/agents, at least one being an amidoxime functional group/compound of 0.5 percent by weight to 24 percent by weight and ammonium fluoride of 12 percent by weight to 42 percent by weight, said combination having a hydrogen ion concentration of 10⁻⁶ mol/L to 101.8, further comprising a surfactant of 0.001 percent by weight to 1 percent by weight. See U.S. Pat. No. 6,585,910.

### Example 32

Another embodiment of the present invention includes a semiconductor wafer cleaning formulation, including 2-98% wt. organic amine, 0-50% wt. water, 0.1-60% wt. one or more compounds with one or more chelating groups/agents, at least one being an amidoxime functional group/compound, 0-25% wt. of additional different chelating agent(s), 0.140% wt. nitrogen-containing carboxylic acid or an imine, optionally 1,3-dicarbonyl compound chelating agent, and 2-98% wt polar organic solvent. The formulations are useful to remove residue from wafers following a resist plasma ashing step, such as inorganic residue from semiconductor wafers containing delicate copper interconnecting structures. See U.S. Pat. No. 6,566,315.

### Example 33

An alternative embodiment of the present invention is a method for removing organometallic and organosilicate residues remaining after a dry etch process from semiconductor substrates. The substrate is exposed to a conditioning solution of a fluorine source, a non-aqueous solvent, a complementary acid, and a surface passivation agent. The fluorine source is typically hydrofluoric acid. The non-aqueous solvent is typically a polyhydric alcohol such as propylene glycol. The complementary acid is typically either phosphoric acid or hydrochloric acid. The surface passivation agent is one or more compounds with one or more chelating groups/agents, at least one being an amidoxime functional group/compound, and may optionally include a carboxylic acid such as citric acid. Exposing the substrate to the conditioning solution removes the remaining dry etch residues while minimizing removal of material from desired substrate features. See U.S. Pat. No. 6,562,726.

### Example 34

Another embodiment of the present invention is a stripping and cleaning composition for the removal of residue from metal and dielectric surfaces in the manufacture of semi-conductors and microcircuits. The composition is an aqueous system including organic polar solvents including corrosive inhibitor component from one or more compounds with one or more chelating groups/agents, at least one being an amidoxime functional group/compound and optionally a select group of aromatic carboxylic acids used in effective inhibiting amounts. A method in accordance with this invention for the removal of residues from metal and dielectric surfaces comprises the steps of contacting the metal or dielectric surface with the above inhibited compositions for a time sufficient to remove the residues. See U.S. Pat. No. 6,558,879.

### Example 35

Another embodiment of the present invention is a homogeneous non-aqueous composition containing a fluorinated solvent, ozone, one or more compounds with one or more chelating groups/agents, at least one being an amidoxime functional group/compound, and optionally a co-solvent and the use of these compositions for cleaning and oxidizing substrates is described. See U.S. Pat. No. 6,537,380.

### Example 36

The present invention also includes a chemical mechanical polishing slurry and method for using the slurry for polishing copper, barrier material and dielectric material that comprises a first and second slurry. The first slurry has a high removal rate on copper and a low removal rate on barrier material. The second slurry has a high removal rate on barrier material and a low removal rate on copper and dielectric material. The first and second slurries at least comprise silica particles, an oxidizing agent, one or more compounds with one or more chelating groups/agents, at least one being an amidoxime functional group/compound, optionally a corrosion inhibitor, and a cleaning agent. See, U.S. Pat. No. 6,527,819.

### Example 37

Another embodiment of the present invention also includes a method for removing organometallic and organosilicate residues remaining after a dry etch process from semiconductor substrates. The substrate is exposed to a conditioning solution of phosphoric acid, hydrofluoric acid, and one or more compounds with one or more chelating groups/agents, at least one being an amidoxime functional group/compound, and optionally a carboxylic acid, such as acetic acid, which removes the remaining dry etch residues while minimizing removal of material from desired substrate features. The approximate proportions of the conditioning solution are typically 80 to 95 percent by weight one or more compounds with one or more chelating groups/agents, at least one being an amidoxime functional group/compound and carboxylic acid, 1 to 15 percent by weight phosphoric acid, and 0.01 to 5.0 percent by weight hydrofluoric acid. U.S. Pat. No. 6,517,738.

### Example 38

Another embodiment of the present invention is a composition for use in semiconductor processing wherein the composition comprises water, phosphoric acid, and one or more compounds with one or more chelating groups/agents, at least one being an amidoxime functional group/compound, and optionally an organic acid; wherein the organic acid is ascorbic acid or is an organic acid having two or more carboxylic acid groups (e.g., citric acid). The water can be present in about 40 wt. % to about 85 wt. % of the composition, the phosphoric acid can be present in about 0.01 wt. % to about 10 wt. % of the composition, and the one or more compounds with one or more chelating groups/agents, at least one being an amidoxime functional group/compound and organic acid can be present in about 10 wt. % to about 60 wt. % of the composition. The composition can be used for cleaning various surfaces, such as, for example, patterned metal layers and vias by exposing the surfaces to the composition. See U.S. Pat. No. 6,486,108.

### Example 39

Another embodiment of the present invention is a method for removing organometallic and organosilicate residues remaining after a dry etch process from semiconductor substrates. The substrate is exposed to a conditioning solution of phosphoric acid, hydrofluoric acid, and one or more compounds with one or more chelating groups/agents, at least one being an amidoxime functional group/compound, and optionally a carboxylic acid, such as acetic acid, which removes the remaining dry etch residues while minimizing removal of material from desired substrate features. The approximate proportions of the conditioning solution are typically 80 to 95 percent by weight one or more compounds with one or more chelating groups/agents, at least one being an amidoxime functional group/compound and acetic acid, 1 to 15 percent by weight phosphoric acid, and 0.01 to 5.0 percent by weight hydrofluoric acid. See U.S. Pat. No. 6,453,914.

### Example 40

Another example of the present invention is show in cleaning a substrate which has a metal material and a semiconductor material both exposed at the surface and which has been subjected to a chemical mechanical polishing treatment, the substrate is first cleaned with a first cleaning solution containing ammonia water, etc. and then with a second cleaning solution containing (a) a first complexing agent capable of easily forming a complex with the oxide of said metal material, etc. and (b) an anionic or cationic surfactant. See U.S. Pat. No. 6,444,583.

### Example 41

The present invention is also exemplified by a cleaning agent for semiconductor parts, which can decrease a load on the environment and has a high cleaning effect on CMP (chemical mechanical polishing) abrasive particles, metallic impurities and other impurities left on the semiconductor parts such as semiconductor substrates after the CMP, comprising a (co)polymer having one or more compounds with one or more chelating groups/agents, at least one being an amidoxime functional group/compound, and optionally at least one kind of group selected from the group consisting of sulfonic acid (salt) groups and carboxylic acid (salt) groups, the cleaning agent further containing a phosphonic acid (salt) group-containing (co)polymer, a phosphonic acid compound or a surfactant as needed; and a method for cleaning semiconductor parts with the above cleaning agent. See U.S. Pat. No. 6,440,856.

### Example 42

The present invention also includes a non-corrosive cleaning composition for removing residues from a substrate. The composition comprises: (a) water; (b) at least one hydroxylammonium compound; (c) at least one basic compound, preferably selected from the group consisting of amines and quaternary ammonium hydroxides; (d) one or more compounds with one or more chelating groups/agents, at least one being an amidoxime functional group/compound, (e) optionally at least one organic carboxylic acid; and (f) optionally, a polyhydric compound. The pH of the composition is preferably between about 2 to about 6. See U.S. Pat. No. 6,413,923.

### Example 43

Another embodiment of the present invention is a composition comprising a slurry having an acidic pH and a corrosion inhibitor with one or more compounds with one or more chelating groups/agents, at least one being an amidoxime functional group/compound, and optionally a carboxylic acid corrosion inhibitor, wherein said carboxylic acid is selected from the group consisting of: glycine, oxalic acid, malonic acid, succinic acid and nitrilotriacetic acid. U.S. Pat. No. 6,409,781.

### Example 44

An alternative embodiment of the present invention is a chemical formulation consisting of a chelating agent, wherein said chelating agent is one or more compounds with one or more chelating groups/agents, at least one being an amidoxime functional group/compound, and optionally one or more additional chelating agents selected from the group consisting of iminodiacetic, malonic, oxalic, succinic, boric and malic acids and 2,4 pentanedione; a fluoride; and a glycol solvent, wherein said chelating agents consist of approximately 0.1-10% by weight of the formulation; and wherein said fluoride consists of a compound selected from the group consisting of ammonium fluoride, an organic derivative of ammonium fluoride, and a organic derivative of a polyammonium fluoride, and wherein said fluoride consists of approximately 1.65-7% by weight of the formulation; and wherein said glycol solvent consists of approximately 73-98.25% by weight of said formulation, further comprising: an amine, wherein said amine consists of approximately 0.1-10% by weight of said formulation. The chelating agents generally contain one or more compounds with one or more chelating groups/agents, at least one being an amidoxime functional group/compound, and optionally contain two carboxylic acid groups or two hydroxyl groups or two carbonyl groups such that the two groups in the chelating agent are in close proximity to each other, Other chelating agents which are also weakly to moderately acidic and are structurally similar to those claimed are also expected to be suitable. See U.S. Pat. No. 6,383,410.

### Example 45

Another embodiment of the present invention is a cleaning composition comprising a partially fluorinated solvent, a co-solvent, one or more compounds with one or more chelating groups/agents, at least one being an amidoxime functional group/compound, and ozone, wherein said fluorinated solvent comprises hydrofluoroethers, wherein said co-solvent is selected from the group consisting of ethers, esters, teriary alcohols, carboxylic acids, ketones and aliphatic hydrocarbons. See U.S. Pat. No. 6,372,700.

### Example 46

Yet another embodiment of the present invention is a combination of one or more compounds with one or more chelating groups/agents, at least one being an amidoxime functional group/compound and optionally a carboxylic acid corrosion inhibitor. The combination of corrosion inhibitors can effectively inhibit metal corrosion of aluminum, copper, and their alloys. Suitable carboxylic acids include monocarboxylic and polycarboxylic acids. For example, the carboxylic acid may be, but is not limited to, formic acid, acetic acid, propionic acid, valeric acid, isovaleric acid, oxalic acid, malonic acid, succinic acid, glutaric acid, maleic acid, filmaric acid, phthalic acid, 1,2,3-benzenetricarboxylic acid, glycolic acid, lactic acid, citric acid, salicylic acid, tartaric acid, gluconic acid, and mixtures thereof. The preferred carboxylic acid is citric acid.

### Example 47

Another example of the present invention is a composition for selective etching of oxides over a metal comprising; (a) water; (b) hydroxylammonium salt in an amount about 0.1 wt. % to about 0.5 wt. % of said composition; (c) one or more compounds with one or more chelating groups/agents, at least one being an amidoxime functional group/compound; (d) optionally a carboxylic acid selected from the group consisting of: formic acid, acetic acid, propionic acid, valeric acid, isovaleric acid, oxalic acid, malonic acid, succinic acid, glutaric acid, maleic acid, fumaric acid, phthalic acid, 1,2,3-benzenetricarboxylic acid, glycolic acid, lactic acid, citric acid, salicylic acid, tartaric acid, gluconic acid, and mixtures thereof; (e) a fluorine-containing compound; and (e) optionally, base. See U.S. Pat. No. 6,361,712.

### Example 48

In a further aspect, the invention relates to a semiconductor wafer cleaning formulation for use in post plasma ashing semiconductor fabrication, comprising the following components in the percentage by weight (based on the total weight of the formulation) ranges shown:

| | | |
|---|---|---|
| Organic amine(s) | 2-98% | by weight |
| Water | 0-50% | by weight |
| amidoxime chelating agent | 0.1-60% | by weight |
| Complexing agent | 0-25% | by weight |
| Nitrogen-containing carboxylic acid or imine | 0.5-40% | by weight |
| polar organic solvent | 2-98% | by weight. |

### Example 49

Another example of the present invention includes an essentially anhydrous cleaning composition comprising 88 weight percent or more of a fluorinated solvent, from 0.005 to 2 weight percent of hydrogen fluoride or complex thereof, and from 0.01 to 5 weight percent of a co-solvent, wherein said co-solvent is selected from one or more compounds with one or more chelating groups/agents, at least one being an amidoxime functional group/compound, ethers, polyethers, carboxylic acids, primary and secondary alcohols, phenolic alcohols, ketones, aliphatic hydrocarbons and aromatic hydrocarbons. See U.S. Pat. No. 6,310,018.

### Example 50

| | | | |
|---|---|---|---|
| A. | Amidoxime compound | 2.5% | by weight |
| | Tetramethylammonium fluoride | 4.5% | by weight |
| | Ethylene glycol | 93% | by weight |
| B. | Amidoxime compound | 1.3% | by weight |
| | Pentamethyldiethylenetriammonium trifluoride | 4.6% | by weight |
| | Ethylene glycol | 94.1% | by weight |
| C. | Amidoxime compound | 1.25% | by weight |
| | Triethanolammonium fluoride | 5% | by weight |
| | Ethylene glycol | 93.75% | by weight |
| D. | Amidoxime compound | 2.8% | by weight |
| | Tetramethylammonium fluoride | 5.1% | by weight |
| | Ethylene glycol | 92.1% | by weight |
| E. | Amidoxime compound | 2% | by weight |
| | Ammonium fluoride | 7% | by weight |
| | Ethylene glycol | 91% | by weight |
| F. | Amidoxime compound | 2.8% | by weight |
| | Ammonium fluoride | 5% | by weight |
| | Ethylene glycol | 92.2% | by weight |

### Example 51

Another embodiment of the present invention includes a chelating agent, a fluoride salt, and a glycol solvent, wherein said chelating agent is weakly to moderately acidic, and consists of approximately 0.1-10% by weight of the formulation; and wherein said fluoride salt consists of a compound selected from the group consisting of ammonium fluoride, an organic derivative of ammonium fluoride, and a organic derivative of a polyammonium fluoride; and wherein said fluoride salt consists of approximately 1.65-7% by weight of the formulation; and wherein said glycol solvent consists of 73-98.25% by weight of said formulation; and further including an amine, wherein said amine consists of approximately 0.1-10% by weight of said formulation; and wherein said chelating agent is an amidoxime or hydroxamic acid. See U.S. Pat. No. 6,280,651.

### Example 52

Another example of the present invention is a cleaning agent for use in producing semiconductor devices, which consists essentially of an aqueous solution containing (A) 0.1 to 15% by weight based on the total amount of the cleaning agent of at least one fluorine-containing compound selected from the group consisting of hydrofluoric acid, ammonium fluoride, ammonium hydrogen fluoride, acidic ammonium fluoride, methylamine salt of hydrogen fluoride, ethylamine salt of hydrogen fluoride, propylamine salt of hydrogen fluoride and tetramethylammonium fluoride, (B) 0.1 to 15% by weight based on the total amount of the cleaning agent of a salt of boric acid and (C) 0.5 to 50% by weight of one or more compounds with one or more chelating groups/agents, at least one being an amidoxime functional group/compound; and (d) 5 to 80% by weight based on the total amount of the cleaning agent of a water-soluble organic solvent, and optionally further containing at least one of a quaternary ammonium salt, an ammonium salt of an organic carboxylic acid, an amine salt of an organic carboxylic acid and a surfactant. See U.S. Pat. No. 6,265,309.

### Example 53

Another embodiment of the present invention includes a cleaning liquid in the form of an aqueous solution for cleaning a semiconductor device during production of a semiconductor device, which comprises (A) a fluorine-containing compound; (B) a water-soluble or water-miscible organic solvent; (C) one or more compounds with one or more chelating groups/agents, at least one being an amidoxime functional group/compound; (D) optionally, an organic acid; and (E) a quaternary ammonium salt. In some embodiments the cleaning solution also contains a surfactant. The organic acid is typically selected from the group consisting of formic acid, acetic acid, propionic acid, butyric acid, isobutyric acid, valeric acid, isovaleric acid, heptanoic acid, lauric acid, palmitic acid, stearic acid, acrylic acid, crotonic acid, methacrylic acid, oxalic acid, malonic acid, maleic acid, succinic acid, adipic acid, azelaic acid, sebacic acid, benzoic acid, toluic acid, phthalic acid, trimellitic acid, pyromellitic acid, benzenesulfonic acid, toluenesulfonic acid, salicylic acid and phthalic anhydride, See U.S. Pat. No. 5,972,862.

### Example 54

Another embodiment is a method for semiconductor processing comprising etching of oxide layers, especially etching thick SiO₂ layers and/or last step in the cleaning process wherein the oxide layers are etched in the gas phase with a mixture of hydrogen fluoride, one or more compounds with one or more chelating groups/agents, at least one being an amidoxime functional group/compound, and optionally one or more carboxylic acids, eventually in admixture with water. See U.S. Pat. No. 5,922,624.

### Example 55

The complexing agents of the present invention may also be added to the rinse containing a peroxide of U.S. Pat. No. 5,911,836.

### Example 56

Another example of the present invention is a method and apparatus for increasing the deposition of ions onto a surface, such as the adsorption of uranium ions on the detecting surface of a radionuclide detector. The method includes the step of exposing the surface to one or more compounds with one or more chelating groups/agents, at least one being an amidoxime functional group/compound, and optionally, a phosphate ion solution, which has an affinity for the dissolved species to be deposited on the surface. This provides, for example, enhanced sensitivity of the radionuclide detector. See U.S. Pat. No. 5,652,013.

### Example 57

Another embodiment of the present invention is a stripping and cleaning agent for removing dry-etching photoresist residues, and a method for forming an aluminum based line pattern using the stripping and cleaning agent. The stripping and cleaning agent contains (a) from 5 to 50% by weight of one or more compounds with one or more chelating groups/agents, at least one being an amidoxime functional group/compound; (b) from 0.5 to 15% by weight of a fluorine compound; and (c) a solvent, including water The inventive method is advantageously applied to treating a dry-etched semiconductor substrate with the stripping and cleaning agent. The semiconductor substrate comprises a semiconductor wafer having thereon a conductive layer containing aluminum. The conductive layer is dry-etched through a patterned photoresist mask to form a wiring body having etched side walls. The dry etching forms a side wall protection film on the side walls. In accordance with the inventive method, the side wail protection film and other resist residues are completely released without corroding the wiring body. See, U.S. Pat. No. 5,630,904.

### Example 58

U.S. Pat. No. 6,927,176 describes the effectiveness of chelating compound due to their binding sites as illustrated below. It highlights that there are 6 binding sites for ethylenediaminetetraacetic acid (EDTA).

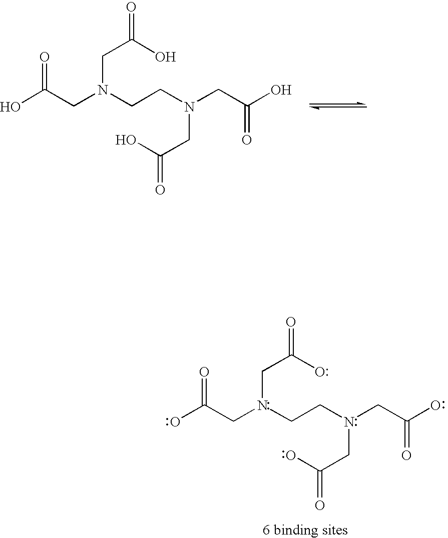

The same principal applying to an amidoxime from the conversion of a cyanoethylation compound of ethylenediamine, results in a total of 14 binding sites, as depicted in the following:

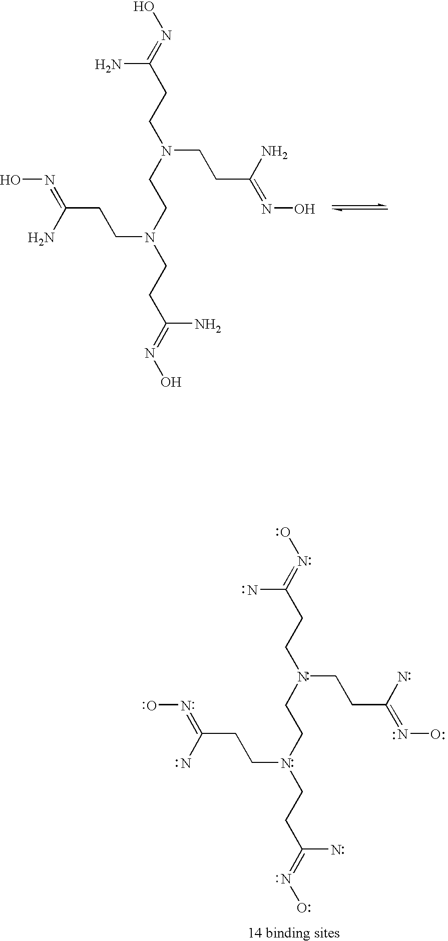

(1,2,3,4,5,6(hexa-(2-amidoximo)ethoxy)hexane Hexitol

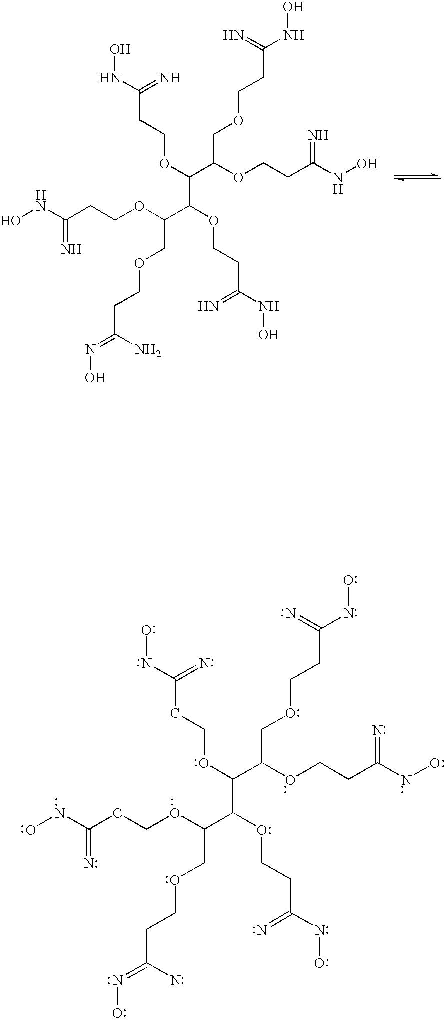

The above compound has a total of 18 binding sites and is more effective in binding metal ions from the etching residues.

The claimed amidoxime chelating agent can substitute in similar applications to replace polyacrylates, carbonates, phosphonates, and gluconates, ethylenediaminetetraacetic acid (DTA), N,N′-bis(2-hydroxyphenyl)ethylenediiminodiacetic acid (APED), triethylenetetranitrilohexaacetic acid (TTHA), desferriferrioxamin B,N,N′,N″-tris[2-(N-hydroxycarbonyl)ethyl]-1,3,5-benzenetncarboxamide (BAMTPH), and ethylenediaminediorthohydroxyphenylacetic acid (EDDHA).

### Example 59

### Associated Methods

The associated methods of this invention entail use of the aforementioned composition (as disclosed supra) for chemical mechanical planarization of substrates comprised of metals, barrier layer materials, and dielectric materials. In the methods, a substrate (e.g., a wafer) is placed face-down on a polishing pad which is fixedly attached to a rotatable platen of a CMP polisher. In this manner, the substrate to be polished and planarized is placed in direct contact with the polishing pad. A wafer carrier system or polishing head is used to hold the substrate in place and to apply a downward pressure against the backside of the substrate during CARP processing while the platen and the substrate are rotated. The polishing composition (slurry) is applied (usually continuously) on the pad during CMP processing to effect the removal of material to planarize the substrate. Since the associated methods of this invention employ the compositions described herein, the ranges (e.g., pH, component levels) described for composition embodiments also apply to corresponding method embodiments.

The composition and associated methods of this invention are effective for CMP of a wide variety of substrates, including substrates having dielectric portions that comprise materials having dielectric constants less than 3.3 (low-k materials). Suitable low-k films in substrates include, but are not limited to, organic polymers, carbon-doped oxides, fluorinated silicon glass (FSG), inorganic porous oxide-like materials, and hybrid organic-inorganic materials. Representative low-k materials and deposition methods for these materials are summarized below.

| | | Deposit | |
|---|---|---|---|
| Vendor | Tradename | Method | Material |
| Air Product and | Messo ELK ® | Spin-On | Hybrid organic- |
| Chemicals | | | inorganic |
| Applied Materials | Black Diamond ® | CVD | Carbon-doped |
| | | | oxide |
| Dow Chemical | SiLK ™, Porous | Spin-On | Organic polymer |
| | SiLK ™ | | |
| Honeywell | NANOGLASS ® E | Spin-On | Inorganic oxide-like |
| Electronic Materials | | | |
| Novellus Systems | CORAL ® | PECVD | Carbon-doped oxide |

PECVD = Plasama enhanced chemical vapor deposition
CVD = chemical vapor deposition

Similarly, the composition and associated methods of this invention are effective for CMP of substrates comprised of various metals, including, but not limited to, tantalum, titanium, tungsten, copper, and noble metals. The composition and associated methods of this invention are particularly useful and preferred in copper CMP processing (e.g., step 2 copper CMP), and afford tunability for the selective removal of barrier layer materials, copper, low-k dielectric layer materials, and PETEOS dielectric layer materials; and high removal rates for metal (e.g., copper), barrier layer material (e.g., tantalum nitride), and low-k dielectric layer materials (e.g., Black Diamond®), in relation to PETEOS dielectric materials (as illustrated in the examples). A combination of (i) abrasive concentration, (ii) abrasive type selected between an unmodified versus a surface-modified abrasive, and (iii) the synergistic combination of hydrogen peroxide concentration with the various concentrations of amidoxime compounds, offers considerable flexibility and provides tunability for the selective removal of barrier layer materials, copper, low-k dielectric materials, and PETEOS dielectric layer materials, during CMP processing by varying tantalum nitride:Black Diamond®.\removal rate selectivity between values of 0.7 to 2.0, tantalum nitride:copper removal rate selectivity between values of 0.7 to 3.5, tantalum nitride:PETEOS removal rate selectivity between values of 1.8 to greater than 16, copper:Black Diamond® removal rate selectivity between values of 0.2 to 2.2, and copper:PETEOS removal rate selectivity between values of 1.9 to greater than 19.

While not being bound by any particular theory, the inventors believes that the following considerations may explain why a polishing composition comprising a) an abrasive, b) a amidoxime compound, c) water, and d) an per-compound oxidizing agent exhibits enhanced tantalum nitride, copper, and low-k dielectric removal rates in CMP processing. Typically when a slurry composition is exposed to copper and tantalum nitride with a commonly used oxidizer such as hydrogen peroxide under basic conditions during CMP processing, both copper and tantalum nitride undergo corrosion to form copper and tantalum ions, which forms passive hard copper oxide and tantalum oxide films. This phenomenon is well understood, and described in Pourbaix diagrams of copper (pages 385-392) and tantalum (pages 251-255) in Atlas of Electrochemical Equilibria in Aqueous Solutions (2.sup.nd Edition), by M. J. N. Pourbaix, published by National Association of Corrosion Engineers, Houston, Tex. (1974). Thus copper and tantalum nitride removal rates are very low. As described in this invention, the addition of a amidoxime compound to a slurry results in complexation with copper and tantalum ions under basic pH polishing conditions. This complexation assists in maintaining copper and tantalum ions in solution as amidoxime complexes, resulting in high copper and tantalum nitride removal rates, high selectivity for removal of copper in relation to PETEOS at low abrasive concentration, and high selectivity for removal of tantalum nitride in relation to PETEOS at low abrasive concentration. Unlike hydrogen peroxide, amidoxime compounds serve not only as an oxidant but also complex the copper ions and tantalum ions. These dual roles result in high copper and tantalum nitride removal rates. Interestingly, the inventive slurry also facilitates high removal rates of Black Diamond® low-k dielectric material.

The present invention is further demonstrated by the examples below.

A) Exemplary Components (and Equivalents Thereof)

| | Nitrile (N) | Amidoxime (AO) |
|---|---|---|
| 3 | 3-hydroxypropionitrile | N′,3-dihydroxypropanimidamide |
| 4 | Acetonitrile | NN′-hydroxyacetimidamide |
| 5 | 3- | N′-hydroxy-3- |
| | methylaminopropionitrile | (methylamino)propanimidamide |
| 6 | Benzonitrile | N′-hydroxybenzimidamide |
| 8 | 3,3′ iminodipropionitrile | 3,3′-azanediylbis(N′- |
| | | hydroxypropanimidamide) |
| 9 | octanonitrile | N′-hydroxyoctanimidamide |
| 10 | 3-phenylpropionitrile | N′-hydroxy-3-phenylpropanimidamide |
| 11 | ethyl 2-cyanoacetate | 3-amino-N-hydroxy-3- |
| | | (hydroxyimino)propanamide |
| 12 | 2-cyanoacetic acid | 3-amino-3-(hydroxyimino)propanoic acid |
| 13 | 2-cyanoacetamide | 3-amino-3-(hydroxyimino)propanamide |
| 15 | adiponitrile | N′1,N′6-dihydroxyadipimidamide |
| 16 | sebaconitrile | N′1,N′10-dihydroxydecanebis(imidamide) |
| 17 | 4-pyridinecarbonitrile | N′-hydroxyisonicotinimidamide |
| 18 | m-tolunitrile | N′-hydroxy-3-methylbenzimidamide |
| 19 | phthalonitrile | isoindoline-1,3-dione dioxime |
| 20 | glycolonitrile | N′,2-dihydroxyacetimidamide |
| 21 | chloroacetonitrile | 2-chloro-N′-hydroxyacetimidamide |
| 22 | benzyl cyanide | product N′-hydroxy-2- |
| | | phenylacetimidamide |
| 24 | Anthranilonitrile | 2-amino-N′-hydroxybenzimidamide |
| 25 | 3,3′ iminodiacetonitrile | 2,2′-azanediylbis(N′- |
| | | hydroxyacetimidamide) |
| 26 | 5-cyanophthalide | N′-hydroxy-1-oxo-1,3- |
| | | dihydroisobenzofuran-5-carboximidamide |
| 27 | 2- | 3-aminoisoquinolin-1(4H)-one oxime or |
| | cyanophenylacetonitrile | 3-(hydroxyamino)-3,4- |
| | | dihydroisoquinolin-1-amine |
| 29 | cinnamonitrile | N′-hydroxycinnamimidamide |
| 30 | 5-hexynenitrile | 4-cyano-N′-hydroxybutanimidamide |
| 31 | 4-chlorobenzonitrile | 4-chloro-N′-hydroxybenzimidamide |

For example, N3 represents 3-hydroxypropionitrile and AO3 is N′,3-dihydroxypropanimidamide from reacting 3-hydroxypropionitrile with hydroxylamine to form its corresponding amidoxime. Summary of preferred amidoxime compounds from nitrites by cyanoethylation of nucleophilic compounds include but are not limited to the list below:

| | Nucleophilic | Cyanoethylated Compounds | Amidoxime from cyanoethylated |
|---|---|---|---|
| ID | compounds | (CE) | compounds (AO) |
| 01 | Sorbitol | 1,2,3,4,5,6-hexakis-O-(2- | 1,2,3,4,5,6-hexakis-O-[3-(hydroxyamino)-3- |
| | | kyanoetyl)hexitol | iminopropyl Hexitol, |
| 07 | ethylenediamine | 3,3′,3″,3′′′-(ethane-1,2- | 3,3′,3″,3′′′-(ethane-1,2- |
| | | diylbis(azanetriyl))tetrapropanenitrile | diylbis(azanetriyl))tetrakis(N′- |
| | | | hydroxypropanimidamide) |
| 28 | ethylene glycol | 3,3′-(ethane-1,2- | 3,3′-(ethane-1,2-diylbis(oxy))bis(N′- |
| | | diylbis(oxy))dipropanenitrile | hydroxypropanimidamide) |
| 34 | diethylamine | 3-(diethylamino)propane nitrile | 3-(diethylamino)-N′- |
| | | | hydroxypropanimidamide |
| 35 | piperazine | 3,3′-(piperazine-1,4- | 3,3′-(piperazine-1,4-diyl)bis(N′- |
| | | diyl)dipropanenitrile | hydroxypropanimidamide) |
| 36 | 2-ethoxyethanol | 3-(2-ethoxyethoxy) | 3-(2-ethoxyethoxy)-N′- |
| | | propanenitrile | hydroxypropanimidamide |
| 37 | 2-(2- | 3-(2-(2-(dimethylamino) | 3-(2-(2-(dimethylamino)ethoxy)ethoxy)-N′- |
| | dimethylamino | ethoxy)ethoxy) propanenitrile | hydroxypropanimidamide |
| | ethoxy)ethanol | | |
| 38 | isobutyraldehyde | 4,4-dimethyl-5-oxo | N′-hydroxy-4,4-dimethyl-5- |
| | | pentanenitrile | oxopentanimidamide |
| 39 | diethyl malonate | diethyl 2,2-bis(2-cyanoethyl) | 2,2-bis(3-amino-3- |
| | | malonate | (hydroxyimino)propyl)malonic acid |
| 40 | aniline | 3-(phenylamino) propanenitrile | N′-hydroxy-3-(phenylamino) |
| | | | propanimidamide |
| 41 | ammonia | 3,3′,3″-nitrilotri propanenitrile | 3,3′,3″-nitrilotris(N′- |
| | | | hydroxypropanimidamide) |
| 42 | diethyl malonate | 2,2-bis(2-cyanoethyl) malonic | 2,2-bis(3-amino-3- |
| | | acid | (hydroxyimino)propyl)malonic acid |
| 43 | Glycine (Mono | 2-(2-cyanoethylamino)acetic | 2-(3-amino-3- |
| | cyanoethylated) | acid | (hydroxyimino)propylamino)acetic acid |
| 44 | Glycine | 2-(bis(2-cyanoethyl)amino) | 2-(bis(3-amino-3- |
| | (Dicyanothylated) | acetic acid | (hydroxyimino)propyl)amino)acetic acid |
| 45 | malononitrile | propane-1,1,3-tricarbonitrile | N1,N′1,N′3-trihydroxypropane-1,1,3- |
| | | | tris(carboximidamide) |
| 46 | cyanoacetamide | 2,4-dicyano-2-(2- | 5-amino-2-(3-amino-3- |
| | | cyanoethyl)butanamide | (hydroxyimino)propyl)-2-(N′- |
| | | | hydroxycarbamimidoyl)-5- |
| | | | (hydroxyimino)pentanamide |
| 47 | Pentaerythritol | 3,3′-(2,2-bis((2-cyanoethoxy) | 3,3′-(2,2-bis((3-(hydroxyamino)-3- |
| | | methyl) propane-1,3- | iminopropoxy)methyl)propane-1,3- |
| | | diyl)bis(oxy) dipropanenitrile | diyl)bis(oxy)bis(N- |
| | | | hydroxypropanimidamide) |
| 48 | N-methyl | 3,3′-(2,2′-(methylazanediyl) | 3,3′-(2,2′-(methylazanediyl)bis(ethane-2,1- |
| | diethanol amine | bis(ethane-2,1-diyl) | diyl)bis(oxy))bis(N′- |
| | | bis(oxy)dipropanenitrile | hydroxypropanimidamide) |
| 49 | glycine anhydride | 3,3′-(2,5-dioxopiperazine-1,4- | 3,3′-(2,5-dioxopiperazine-1,4-diyl)bis(N′- |
| | | diyl)dipropanenitrile | hydroxypropanimidamide) |
| 50 | acetamide | N,N-bis(2-cyanoethyl)acetamide | N,N-bis(3-amino-3- |
| | | | (hydroxyimino)propyl)acetamide |
| 51 | anthranilonitrile | 3,3′-(2-cyanophenylazanediyl) | 3,3′-(2-N′- |
| | | dipropanenitrile | hydroxycarbamimidoyl)phenylazanediyl)bis |
| | | | (N′-hydroxypropanimidamide) |
| 52 | diethanolamine | 3,3′-(2,2′-(2- | 3,3′-(2,2′-(3-amino-3- |
| | | cyanoethylazanediyl)bis(ethane- | (hydroxyimino)propylazanediyl)bis(ethane- |
| | | 2,1-diyl)bis(oxy))dipropane | 2,1-diyl))bis(oxy)bis(N′- |
| | | nitrile | hydroxypropanimidamide) |

For example, CE36 represents cyanoethylated product of ethylene glycol and AO36 is from reacting 3-(2-ethoxyethoxy) propanenitrile with hydroxylamine to form its corresponding amidoxime

B) Other Co-Additives with Amidoxime Compounds in the Polishing Compositions:

Other Additives Used in the Polishing Formulations is Summarized Below:
1) Hydrogen Peroxide: a 30 weight % solution, Air Products and Chemicals, Inc., 7201 Hamilton Blvd., Allentown, Pa. 18195.
2) Potassium Hydroxide: Aldich Chemical Company, Inc, 1001 West St. Paul, Milwaukee, Wis. 53233.
3) Potassium-stabilized Colloidal Silica: DuPont Air Products NanoMaterials L.L.C., 2507 West Erie Drive, Tempe, Ariz. 85282 (an approximately 30 weight % potassium-stabilized dispersion in water with a particle size of 50-60 nanometers as measured by Capillary Hydro-Dynamic Flow using a Matec Applied Sciences model number CHDF 2000 instrument.)

C) General

| | |
|---|---|
| Black | Applied Producer ® Black Diamond ® chemical vapor |
| Diamond ® | deposition (CVD) film, a low-k dielectric layer. |
| PETEOS | Plasma enhanced deposition of tetraethoxy silane; a |
| | dielectric oxide layer. |
| Blanket | Blanket wafers are those that have typically one type of |
| Wafers: | surface prepared for polishing experiments. |

Parameters.

| | |
|---|---|
| ANG.: | angstrom(s)-a unit of length |
| CMP: | chemical mechanical planarization, or chemical |
| | mechanical polishing |
| min: | minute(s) |
| ml: | milliliter(s) |
| psi: | pounds per square inch |
| rpm: | revolution(s) per minute |

| | |
|---|---|
| TaN:BD1 | Sel Tantalum nitride:Black Diamond ® Selectivity - the ratio of the |
| | amount of tantalum nitride removed to the amount of Black |
| | Diamond ® removed during CMP experiments using blanket wafers |
| | under identical conditions. |
| TaN:Cu Sel | Tantalum nitride:Copper Selectivity - the ratio of the amount of |
| | tantalum nitride removed to the amount of copper removed during |
| | CMP experiments using blanket wafers under identical conditions. |
| TaN:PETEOS | Sel Tantalum nitride:PETEOS Selectivity - the ratio of the amount |
| | of tantalum nitride removed to the amount of PETEOS removed |
| | during CMP experiments using blanket wafers under identical |
| | conditions. |
| Cu:BD1 | Sel Copper:Black Diamond ® Selectivity - the ratio of the amount |
| | of copper removed to the amount of Black Diamond ® removed |
| | during CMP experiments using blanket wafers under identical |
| | conditions. |
| Cu:PETEOS Sel | Copper:PETEOS Selectivity - The ratio of the amount of copper |
| | removed to the amount of PETEOS (dielectric material) removed |
| | during CMP experiments using blanket wafers under identical |
| | conditions. |

All percentages are weight percentages and all temperatures are degrees Celsius unless otherwise indicated.

Chemical Mechanical Planarization (CMP) Methodology

In the examples presented below, CMP experiments were run using the procedures and experimental conditions given below.

Metrology

PETEOS and Black Diamond® thickness was measured with a Nanometrics, model, #9200, manufactured by Nanometrics Inc, 1550 Buckeye, Milpitas, Calif. 95035. The metal films were measured with a ResMap CDE, model 168, manufactured by Creative Design Engineering, Inc, 20565 Alves Dr, Cupertino, Calif., 95014. This tool is a four-point probe sheet resistance tool. Twenty-five and forty nine-point polar scans were taken with the respective tools at 3-mm edge exclusion.

CMP Tool

The CMP tool that was used is a Mirra®, manufactured by Applied Materials, 3050 Boweres Avenue, Santa Clara, Calif., 95054. A Politex® embossed pad, supplied by Rohm and Haas Electronic Materials, 3804 East Watkins Street, Phoenix, Ariz., 85034, was used on the platen for the blanket wafer polishing studies.

In blanket wafers studies, polish time was 60 seconds per wafer. The Mirra® tool mid-point conditions for polishing blanket wafers were: platen (or table) speed 90 rpm; head speed 84 rpm; retaining ring pressure 3.0 psi; inter-tube pressure 3.0 psi; membrane pressure 2.0 psi; slurry flow 200 ml/min.

Blanket Wafers

Blanket wafer polishing experiments were conducted using Black Diamond®, PETEOS, CVD tantalum nitride, and electrochemically deposited copper wafers. The Black Diamond® wafers were purchased from Advanced Technology Development Facility (ATDF), 2706 Montopolis Drive, Austin, Tex. 78741. The Cu, PETEOS, and tantalum nitride blanket wafers were purchased from Silicon Valley Microelectronics, 1150 Campbell Ave, Calif. 95126. The blanket wafer film thickness specifications are summarized below: Black Diamond®: 10,000 angstroms on silicon Copper: 10,000 angstroms electroplated copper/1,000 angstroms copper seed/250 angstroms tantalum on silicon PETEOS: 15,000 angstroms on silicon Tantalum nitride: 3000 angstroms on 3,000 angstroms thermal oxide (on silicon)

A copper blanket wafer is immersed in the following solutions at room temperature for 15 and 30 minutes to observe the copper thickness changes.

| | | H₂O₂ | H₂O₂/AO | AO |
|---|---|---|---|---|
| Hydrogen Peroxide | | 3% | 3% | 0 |
| 1,2,3,4,5,6-hexakis-O-[3- | | 0 | 1% | 1% |
| (hydroxyamino)-3-iminopropyl Hexitol | | | | |
| Water | | Balance | Balance | Balance |
| Copper Thickness Lost | 15 minutes | 97 | 16 | 22 |
| | 30 minutes | 120 | 13 | 48 |

Hydrogen peroxide attacks the copper surface which is converted to copper oxide, resulting in the reduction of copper thickness. It resulted in a loss of 120 Å in 30 minutes of immersion. Amidoxime etches copper slightly in 30 minutes to remove about 50 Å. It is unexpected to see the mixture of the two components inhibit the oxidation of the copper surface.

Dishing Improvement with Amidoxime:

A slurry system is prepared according to manufacturing recommended procedures with the following.

| | |
|---|---|
| Potassium-stabilized Colloidal Silica from DuPont | 3% |
| Air Products NanoMaterials* | |
| Potassium hydroxide | 0.11% |
| 1,2,3,4,5,6-hexakis-O-[3-(hydroxyamino)-3- | 3000 ppm |
| iminopropyl Hexitol | |
| Hydrogen Peroxide (weight %) | 1% |
| Deionized Water | Balance |
| pH | 10.6 |

The result shows an improvement on copper dishing by 25-35% over comparative standard recipe without amidoxime.

Amidoxime Prevents Erosion.

Wafer samples with copper/low k structures are immersed in the cleaning solutions at 60° C. for 1 and 4 hours. The samples are then inspected using Hitachi S-5200 Scanning Electron Microscope. The results from the SEM pictures show that approximately 25 nm of copper have been eroded when exposed to the amidoxime solution of the invention compared to 130 nm lost in PCMP EKC5510 from EKC Technology, Inc.

While not being bound by any particular theory, the inventors believe that the following considerations may explain why a polishing composition comprising a) an abrasive, b) a amidoxime compound, c) water, and d) an per-compound oxidizing agent exhibits enhanced tantalum nitride, copper, and low-k dielectric removal rates in CMP processing. Typically, when a slurry composition is exposed to copper and tantalum nitride with a commonly used oxidizer such as hydrogen peroxide under basic conditions during CMP processing, both copper and tantalum nitride undergo corrosion to form copper and tantalum ions, which forms passive hard copper oxide and tantalum oxide films. This phenomenon is well understood, and described in Pourbaix diagrams of copper (pages 385-392) and tantalum (pages 251-255) in Atlas of Electrochemical Equilibria in Aqueous Solutions (2nd Edition), by M. J. N. Pourbaix, published by National Association of Corrosion Engineers, Houston, Tex. (1974). Thus, copper and tantalum nitride removal rates are very low. As described in this invention, the addition of an amidoxime compound to a slurry results in complexation with copper and tantalum ions under basic pH polishing conditions. This complexation assists in maintaining copper and tantalum ions in solution as amidoxime complexes, resulting in high copper and tantalum nitride removal rates, high selectivity for removal of copper in relation to PETEOS at low abrasive concentration, and high selectivity for removal of tantalum nitride in relation to PETEOS at low abrasive concentration. Unlike hydrogen peroxide, amidoxime compounds serve not only as an oxidant but also to complex with the copper ions and tantalum ions. These dual roles result in high copper and tantalum nitride removal rates. Interestingly, the inventive slurry also facilitates high removal rates of Black Diamond® low-k dielectric material.

Cleaning solutions of the present application include compositions comprising:

A) An organic compound with one or more amidoxime functional groups

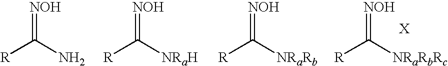

or tautomers thereof, wherein X is a counterion and R, Rₐ, R_{b} and R_{c} are independently selected from alkyl, heteroalkyl, aryl and heteroaryl, and wherein the alkyl, heteroalkyl, aryl and heteroaryl are optionally substituted.

The above solution can further comprise components selected from one or more of the following groups:

B) Water

Within the scope of this invention, water may be introduced into the composition essentially only in chemically and/or physically bound form or as a constituent of the raw materials or compounds.

C) Solvent—From about 1% to 99% by weight.

The compositions of the present invention also include 0% to about 99% by weight and more typically about 1% to about 80% by weight of a water miscible organic solvent where the solvent(s) is/are preferably chosen from the group of water miscible organic solvents.

Examples of water miscible organic solvents include, but are not limited to, dimethylacetamide (DMAC), N-methylpyrrolidinone (NMP), N-Ethyl pyrrolidone (NEP), N-Hydroxyethyl Pyrrolidone (BEP), N-Cyclohexyl Pyrrolidone (CHP) dimethylsulfoxide (DMSO), Sulfolane, dimethylformamide DMF), N-methylformamide (NMF), formamide, Monoethanol amine (MEA), Diglycolamine, dimethyl-2-piperidone (DMPD), morpholine, N-morpholine-N-Oxide (NMNO), tetrahydrofurfuryl alcohol, cyclohexanol, cyclohexanone, polyethylene glycols and polypropylene glycols, glycerol, glycerol carbonate, triacetin, ethylene glycol, propylene glycol, propylene carbonate, hexylene glycol, ethanol and n-propanol and/or isopropanol, diglycol, propyl or butyl diglycol, hexylene glycol, ethylene glycol methyl ether, ethylene glycol ethyl ether, ethylene glycol propyl ether, ethylene glycol mono-n-butyl ether, diethylene glycol methyl ether, diethylene glycol ethyl ether, propylene glycol methyl, ethyl or propyl ether, dipropylene glycol methyl or ethyl ether, methoxy, ethoxy or butoxy triglycol, I-butoxyethoxy-2-propanol, 3-methyl-3-methoxybutanol, propylene glycol t-butyl ether, and other amides, alcohols or pyrrolidones, ketones, sulfoxides, or multifunctional compounds, such as hydroxyamides or aminoalcohols, and mixtures of these solvents thereof. The preferred solvents, when employed, are dimethyl acetamide and dimethyl-2-piperidone, dimethylsufoxide and N-methylpyrrolidinone, diglycolamine, and monoethanolamine.

D) Acids—From About 0.001% to 15% by Weight

Possible acids are either inorganic acids or organic acids provided these are compatible with the other ingredients.

Inorganic acids include hydrochloric acid, hydrofluoric acid, sulfuric acid, phosphoric acid, phosphorous acid, hypophosphorous acid, phosphonic acid, nitric acid, and the like.

Organic acids include monomeric and/or polymeric organic acids from the groups of unbranched saturated or unsaturated monocarboxylic acids, of branched saturated or unsaturated monocarboxylic acids, of saturated and unsaturated dicarboxylic acids, of aromatic mono-, di- and tricarboxylic acids, of sugar acids, of hydroxy acids, of oxo acids, of amino acids and/or of polymeric carboxylic acids are preferred. These groups are provided below:

From the group of unbranched saturated or unsaturated monocarboxylic acids: methanoic acid (formic acid), ethanoic acid (acetic acid), propanoic acid (propionic acid), pentanoic acid (valeric acid), hexanoic acid (caproic acid), heptanoic acid (enanthic acid), octanoic acid (caprylic acid), nonanoic acid (pelargonic acid), decanoic acid (capric acid), undecanoic acid, dodecanoic acid (lauric acid), tridecanoic acid, tetradecanoic acid (myristic acid), pentadecanoic acid, hexadecanoic acid (palmitic acid), heptadecanoic acid (margaric acid), octadecanoic acid (stearic acid), eicosanoic acid (arachidic acid), docosanoic acid (behenic acid), tetracosanoic acid (lignoceric acid), hexacosanoic acid (cerotic acid), triacontanoic acid (melissic acid), 9c-hexadecenoic acid (paimitoleic acid), 6c-octadecenoic acid (petroselic acid), 6t-octadecenoic acid (petroselaidic acid), 9c-octadecenoic acid (oleic acid), 9t-octadecenoic acid (elaidic acid), 9c,12c-octadecadienoic acid (linoleic acid), 9t,12t-octadecadienoic acid (linolaidic acid) and 9c,12c,15c-octadecatrienoic acid (linolenic acid).

From the group of branched saturated or unsaturated monocarboxylic acids: 2-methylpentanoic acid, 2-ethylhexanoic acid, 2-propylheptanoic acid, 2-butyloctanoic acid, 2-pentylnonanoic acid, 2-hexyldecanoic acid, 2-heptylundecanoic acid, 2-octyldodecanoic acid, 2-nonyltridecanoic acid, 2-decyltetradecanoic acid, 2-undecylpentadecanoic acid, 2-dodecylhexadecanoic acid, 2-tridecylheptadecanoic acid, 2-tetradecyloctadecanoic acid, 2-pentadecylnonadecanoic acid, 2-hexadecyleicosanoic acid, 2-heptadecylheneicosanoic acid.

From the group of unbranched saturated or unsaturated di- or tricarboxylic acids: propanedioic acid (malonic acid), butanedioic acid (succinic acid), pentanedioic acid (glutaric acid), hexanedioic acid (adipic acid), heptanedioic acid (pimelic acid), octanedioic acid (suberic acid), nonanedioic acid (azelaic acid), decanedioic acid (sebacic acid), 2c-butenedioic acid (maleic acid), 2t-butenedioic acid (fumatic acid), 2-butynedicarboxylic acid (acetylenedicarboxylic acid).

From the group of aromatic mono-, di- and tricarboxylic acids: benzoic acid, 2-carboxybenzoic acid (phthalic acid), 3-carboxyhenzoic acid (isophthalic acid), 4-carboxybenzoic acid (terephthalic acid), 3,4-dicarhoxybenzoic acid (trimellitic acid), and 3,5-dicarboxybenzoic acid (trimesionic acid).

From the group of sugar acids: galactonic acid, mannonic acid, fructonic acid, arabinonic acid, xylonic acid, ribonic acid, 2-deoxyribonic acid, alginic acid. From the group of hydroxy acids: hydroxyphenylacetic acid (mandelic acid), 2-hydroxypropionic acid (lactic acid), hydroxysuccinic acid (malic acid), 2,3-dihydroxybutanedioic acid (tartaric acid), 2-hydroxy-1,2,3-propanetricarboxylic acid (citric acid), ascorbic acid, 2-hydroxybenzoic acid (salicylic acid), and 3,4,5-trihydroxybenzoic acid (gallic acid).

From the group of oxo acids: 2-oxopropionic acid (pyruvic acid) and 4-oxopentanoic acid (levulinic acid).

From the group of amino acids: alanine, valine, leucine, isoleucine, proline, tryptophan, phenylalanine, methionine, glycine, serine, tyrosine, threonine, cysteine, asparagine, glutamine, aspartic acid, glutamic acid, lysine, arginine, and histidine.

E) Bases—from About 1% to 45% by Weight

Possible bases are either inorganic bases or organic bases, provided these are compatible with the other ingredients.

Inorganic bases include sodium hydroxide, lithium hydroxide, potassium hydroxide, ammonium hydroxide and the like.

Organic bases including organic amines, and quaternary alkylammonium hydroxide which may include, but are not limited to, tetramethylammonium hydroxide (TMAH), TMAH pentahydrate, benzyltetramethylammonium hydroxide (BTMAH), TBAH, choline, and Tris(2-hydroxyethyl)methylammonium hydroxide (TEMAH).

F) Activator—from about 0.001% to 25% by Weight

According to the present invention, the cleaning compositions comprise one or more substances from the group of activators, in particular from the groups of polyacylated alkylenediamines, in particular tetraacetylethylenediamine (TAED), N-acylimides, in particular N-nonanoylsuccinimide (NOSI), acylated phenolsulfonates, in particular n-nonanoyl- or isononanoyloxybenzenesulfonate (n- or iso-NOBS) and n-methylmorpholiniumacetonitriie, methylsulfate (MMA), and “nitrile quaternary” compound in amounts of from 0.1 to 20% by weight, preferably from 0.5 to 15% by weight and in particular from 1 to 10% by weight, in each case based on the total composition to enhance the oxidation/reduction performance of the cleaning solutions. The “nitrile quats”, cationic nitrites has the formula,

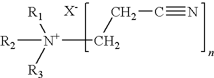

G) Compounds Having Oxidation and Reduction Potential—from about 0.001% to 25% by Weight.

These compounds include hydroxylamine and its salts, such as hydroxylamine chloride, hydroxylamine nitrate, hydroxylamine sulfate, hydroxylamine phosphate or its derivatives, such as N,N-diethylhydroxylamine, N-Phenylhydroxylamine Hydrazine and its derivatives; hydrogen peroxide; persulfate salts of ammonium, potassium and sodium, permanganate salt of potassium, sodium; and other sources of peroxide are selected from the group consisting of: perborate monohydrate, perborate tetrahydrate, percarbonate, salts thereof and combinations thereof. For environmental reasons, hydroxylamine phosphate is not preferred.

Other compounds which may be used as ingredients within the scope of the present invention are the diacyl peroxides, such as, for example, dibenzoyl peroxide. Further typical organic compounds which have oxidation/reduction potentials are the peroxy acids, particular examples being the alkyl peroxy acids and the aryl peroxy acids. Preferred representatives are (a) peroxybenzoic acid and its ring substituted derivatives, such as alkylperoxybenzoic acids, but also peroxy-a-naphthoic acid and magnesium monoperphthalate, (b) the aliphatic or substituted aliphatic peroxy acids, such as peroxylauric acid, peroxystearic acid, c-phthalimidoperoxycaproic acid [phthaloiminoperoxyhexanoic acid (PAP)], o-carboxybenzamidoperoxycaproic acid, N-nonenylamidoperadipic acid and N-nonenylamidopersuccinate, and (c) aliphatic and araliphatic peroxydicarboxylic acids, such as 1,2-diperoxycarboxylic acid, 1,9-diperoxyazelaic acid, diperoxysebacic acid, diperoxybrassylic acid, the diperoxyphthalic acids, 2-decyldiperoxybutane-1,4-dioic acid, N,N-terephthaloyidi(6-aminopercaproic acid) may be used.

H) Other Chelating Agents—Preferably, the Cleaning Composition Comprises (by Weight of the Composition) from 0.0% to 15% of Additional One or More Chelant.

A further possible group of ingredients are the chelate complexing agents. Chelate complexing agents are substances which form cyclic compounds with metal ions, where a single ligand occupies more than one coordination site on a central atom, i.e., it is at least “bidentatec” In this case, stretched compounds are thus normally closed by complex formation via an ion to give rings. The number of bonded ligands depends on the coordination number of the central ion.

Complexing groups (ligands) of customary complex forming polymers include iminodiacetic acid, hydroxyquinoline, thiourea, guanidine, dithiocarbamate, hydroxamic acid, amidoxime, aminophosphoric acid, (cycl) polyamino, mercapto, 1,3-dicarbonyl and crown ether radicals, some of which have very specific activities toward ions of different metals.

For the purposes of the present invention, it is possible to use complexing agents of the prior art. These may belong to different chemical groups. Preferred chelating/complexing agents include the following, individually, or in a mixture with one another:

1) polycarboxylic acids in which the sum of the carboxyl and optionally hydroxyl groups is at least 5, such as gluconic acid,
2) nitrogen-containing mono- or polycarboxylic acids, such as ethylenediaminetetraacetic acid (EDTA), N-hydroxyethylethylenediaminetriacetic acid, diethylenetriaminepentaacetic acid, hydroxy-ethyliminodiacetic acid, nitridodiacetic acid-3-propionic acid, isoserinediacetic acid, N,N-di(O-hydroxyethyl)glycine, N-(1,2-dicarboxy-2-hydroxyethyl)glycine, N-(1,2-dicarboxy-2-hydroxyethyl)-aspartic acid or nitrilotriacetic acid (NTA),
3) geminal diphosphonic acids, such as 1-hydroxyethane-1,1-diphosphonic acid (HEDP), higher homologs thereof having up to 8 carbon atoms, and hydroxy or amino group-containing derivatives thereof and 1-aminoethane-1,1-diphosphonic acid, higher homologs thereof having up to 8 carbon atoms, and hydroxy or amino group-containing derivatives thereof,
4) aminophosphonic acids, such as ethylenediamine-tetra(methylenephosphonic acid), diethylenetriaminepenta(methylenephosphonic acid) or nitrilotri(methylenephosphonic acid),
5) phosphonopolycarboxylic acids, such as 2-phosphonobutane-1,2,4-tricarboxylic acid, and
f) cyclodextrins.

Surfactants—Surfactants can be present in the compositions of the present invention in a range from about 10 ppm to 5%.

The compositions according to the invention may thus also comprise anionic, cationic, and/or amphoteric surfactants as surfactant components.

Source of fluoride ions—The source of fluoride ions can be present in a range from an amount about 0.001% to 10%.

Sources of fluoride ions include, but are not limited to, ammonium bifluoride, ammonium fluoride, hydrofluoric acid, sodium hexafluorosilicate, fluorosilicie acid and tetrafluoroboric acid.

The components of the claimed compositions can be metered and mixed in situ just prior dispensing to the substrate surface for treatment. Furthermore, analytical devices can be installed to monitor the composition and chemical ingredients can be re-constituted to mixture to the specification to deliver the cleaning performance. Critical paramenters that can be monitored include physical and chemical properties of the composition, such as pH, water concentration, oxidation/reduction potential and solvent components.

The composition claims a range at point of use and also as mixtures which can be diluted to meet the specific cleaning requirements.

While the invention has been described and illustrated herein by references to various specific materials, procedures and examples, it is understood that the invention is not restricted to the particular combinations of materials and procedures selected for that purpose. Numerous variations of such details can be implied as will be appreciated by those skilled in the art. It is intended that the specification and examples be considered as exemplary, only, with the true scope and spirit of the invention being indicated by the following claims. All references, patents, and patent applications referred to in this application are herein incorporated by reference in their entirety.

What is claimed is:

1. A chemical-mechanical planarization composition comprising: a) at least one amidoxime compound; b) water; and c) an abrasive.

2. A method of chemical-mechanical planarization of a substrate comprising a metal surface, at least one dielectric material and at least one barrier material, said method comprising the steps of.
A) contacting the substrate with a polishing pad and with the chemical-mechanical planarization composition of claim 1; and
B) polishing the substrate.

3. A chemical-mechanical planarization composition comprising:
(a) an abrasive;
(b) water; and
(c) an amidoxime compound having the structure. 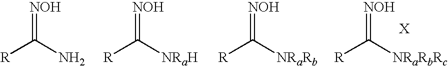
or tautomers thereof, wherein X is a counterion and R, Rₐ, R_{b} and R_{c} are independently selected from alkyl, heteroalkyl, aryl and heteroaryl.

4. The composition of claim 3, wherein the abrasive is a colloidal abrasive.

5. The composition of claim 3, wherein the abrasive is silica or surface-modified silica.

6. The composition of claim 3, wherein the amidoxime compound is present at a weight percent level in the composition ranging from 0.1 weight % to 25 weight %.

7. The composition of claim 3 further comprising a compound with oxidation and reduction potential.

8. The composition of claim 7, wherein the compound with oxidation and reduction potential is hydrogen peroxide.

9. The composition of claim 8, wherein hydrogen peroxide is present at a level ranging from 0.05 weight % to 7.5 weight % of the total weight of the composition.

10. The composition of claim 3, wherein the composition has a pH ranging from 5 to 11.

11. The composition of claim 3 further comprising a surfactant.

12. The composition of claim 11, wherein the surfactant is a nonionic surfactant.

13. The composition of claim 3 further comprising a chelating agent and/or corrosion inhibitor.

14. The composition of claim 3, wherein the amidoxime compound is selected from the group consisting of: 1,2,3,4,5,6-hexakis-O-[3-(hydroxyamino)-3-iminopropyl Hexitol, 3,3′,3′,3′″-(ethane-1,2-diylbis(azanetriyl))tetrakis(N′-hydroxypropanimidamide), 3,3′-(ethane-1,2-diylbis(oxy))bis(N′-hydroxypropanimidamide), 3-(diethylamino)-N′-hydroxypropanimidamide, 3,3′-(piperazine-1,4-diyl)bis(N′-hydroxypropanimidamide), 3-(2-ethoxyethoxy)-N′-hydroxypropanimidamide, 3-(2-(2-(dimethylamino)ethoxy)ethoxy)-N′-hydroxypropanimidamide, N′-hydroxy-3-(phenylamino)propanimidamide, 3,3′,3″-nitrilotris(N′-hydroxypropanimidamide), 3,3′-(2,2-bis((3-(hydroxyamino)-3-iminopropoxy)methyl)propane-1,3-diyl)bis(oxy)bis(N-hydroxypropanimidamide), 3,3′-(2,2′-(methylazanediyl)bis(ethane-2,1-diyl)bis(oxy))bis(N′-hydroxypropanimidamide), N,N-bis(3-amino-3 (hydroxyimino)propyl)acetamide, 3,3′-(2-(N′-hydroxycarbamimidoyl)phenylazanediyl)bis(N′-hydroxypropanimidamide), 3,3′-(2,2′-(3-amino-3-(hydroxyimino)propylazanediyl)bis(ethane-2,1-diyl))bis(oxy)bis(N′-hydroxypropanimidamide), N′,3-dihydroxypropanimidamide, NN′-hydroxyacetimidamide, N′-hydroxy-3-(methylamino)propanimidamide, N′-hydroxybenzimidamide, 3,3′-azanediylbis(N′-hydroxypropanimidamide), N′-hydroxyoctanimidamide, N′-hydroxy-3-phenylpropanimidamide, 3-amino-N-hydroxy-3-(hydroxyimino)propanamide, 3-amino-3-(hydroxyimino)propanoic acid, 3-amino-3-(hydroxyimino)propanamide, N′1,N′6-dihydroxyadipimidamide, N′1,N′10-dihydroxydecanebis(imidamide), N′-hydroxyisonicotinimidamide, N′-hydroxy-3-methylbenzimidamide, isoindoline-1,3-dione dioxime, N′,2-dihydroxyacetimidamide, 2-chloro-N′-hydroxyacetimidamide, product N′-hydroxy-2-phenylacetimidamide, 2-amino-N′-hydroxybenzimidamide, 2,2′-azanediylbis(N′-hydroxyacetimidamide)₇ N′-hydroxy-1-oxo-1,3-dihydroisobenzofuran-5-carboximidamide, 3-aminoisoquinolin-1(4H)-one oxime or 3-(hydroxyamino)-3,4-dihydroisoquinolin-1-amine, N′-hydroxycinnamimidamide, 4-cyano-N′-hydroxybutanimidamide, 4-chloro-N′-hydroxybenzimidamide and salts thereof.

15. A method of metal chemical-mechanical planarization, said method comprising the steps of:
A) placing a substrate comprising a metal, at least one dielectric material and at least one barrier material in contact with a polishing pad;
B) delivering to the substrate a chemical-mechanical planarization composition comprising
a) an abrasive,
b) water, and
c) an amidoxime compound having the structure: 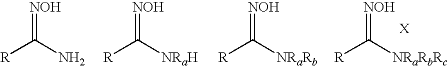
or tautomers thereof, wherein X is a counterion and R, Rₐ, R_{b} and R_{c} are independently selected from alkyl, heteroalkyl, aryl and heteroaryl, and
C) polishing the substrate with the chemical-mechanical planarization composition.

16. The method of claim 15, wherein the abrasive is a colloidal abrasive.

17. The method of claim 15, wherein the abrasive is silica or surface-modified silica.

18. The method of claim 15, wherein the amidoxime compound is present at a weight percent level in the composition ranging from 0.1 weight % to 25 weight %.

19. The method of claim 15, wherein the composition further comprises a compound with oxidation and reduction potential.

20. The method of claim 15, wherein the compound with oxidation and reduction potential is hydrogen peroxide or hydroxylamine and its salts.

21. The method of claim 20, wherein hydrogen peroxide is present at a level ranging from 0.05 weight % to 7.5 weight % of the total weight of the composition.

22. The method of claim 15, wherein the composition has a pH ranging from 5 to 11.

23. The method of claim 15, wherein the composition further comprises a surfactant.

24. The method of claim 23, wherein the surfactant is a nonionic surfactant.

25. The method of claim 15, wherein the composition further comprises a chelating agent and/or corrosion inhibitor.

26. A method of metal chemical-mechanical planarization, said method comprising the steps of:
A) placing a substrate comprising a metal, at least one dielectric material and at least one barrier material in contact with a polishing pad;
B) delivering to the substrate a chemical-mechanical planarization composition comprising
a) an abrasive;
b) an amidoxime compound having the structure: 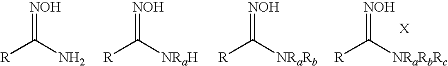
c) or tautomers thereof, wherein X is a counterion and R, Rₐ, R_{b} and R_{c} are independently selected from alkyl, heteroalkyl, aryl and heteroaryl,
d) water; and
e) a compound with oxidation and reduction potential; and
C) polishing the substrate with the metal chemical-mechanical planarization composition.

27. The method of claim 26, wherein the metal is copper, aluminum, or tungsten.

28. The method of claim 26, wherein the substrate further comprises at least one dielectric material and at least one barrier material.

29. The method of claim 28, wherein the dielectric material is silicon oxide, carbon doped silicon oxide or an organic low k dielectric material.

30. The method of claim 28, wherein the composition further comprises one or more basic compounds.

31. The method of claim 28, wherein the composition further comprises one or more acid compounds.

32. The method of claim 28, wherein the composition further comprises a corrosion inhibitor.

33. The method of claim 28, wherein R is an alkyl group.

34. The method of claim 28, wherein R is a heteroalkyl group.

35. The method of claim 32, wherein the R group contains 10 or more carbon atoms.

36. The composition of claim 1, wherein the amidoxime has the following structure: 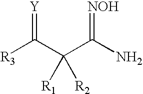
wherein R₁, R₂ and R₃ are independently selected from hydrogen, heteteroatoms, heterogroups, alkyl, heteroalkyl, aryl and heteroaryl, and Y is O, NH or NOH.

37. The composition of claim 1, wherein the amidoxime has the following structure: 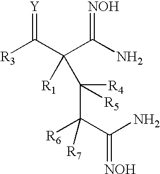
wherein R₄, R₅, R₆ and R₇ are independently selected from hydrogen, heteteroatoms, heterogroups, alkyl, heteroalkyl, aryl and heteroaryl.

38. The composition of claim 1, wherein the amidoxime is selected from the group consisting of 1,2,3,4,5,6-hexakis-O-[3-(hydroxyamino)-3-iminopropyl Hexitol, 3,3′,3″,3′″-(ethane-1,2-diylbis(azanetriyl))tetrakis(N′-hydroxypropanimidamide), 3,3′-(ethane-1,2-diylbis(oxy))bis(N′-hydroxypropanimidamide), 3-(diethylamino)-N′-hydroxypropanimidamide, 3,3′-(piperazine-1,4-diyl)bis(N′-hydroxypropanimidamide), 3-(2-ethoxyethoxy)-N′-hydroxypropanimidamide, 3-(2-(2-(dimethylamino)ethoxy)ethoxy)-N′-hydroxypropanimidamide, N′-hydroxy-3-(phenylamino)propamidamide, 3,3′,3′-nitrilotris(N′-hydroxypropanimidamide), 3,3′-(2,2-bis((3-(hydroxyamino)-3-iminopropoxy)methyl)propane-1,3-diyl)bis(oxy)bis(N-hydroxypropanimidamide), 3,3′-(2,2′-(methylazanediyl)bis(ethane-2,1-diyl)bis(oxy))bis(N′-hydroxypropanimidamide), N,N-bis(3-amino-3-(hydroxyimino)propyl)acetamide, 3,3′-(2-(N′-hydroxycarbamimidoyl)phenylazanediyl)bis(N′-hydroxypropanimidamide), 3,3′-(2,2′-(3-amino-3-(hydroxyimino)propylazanediyl)bis(ethane-2,1-diyl))bis(oxy)bis(N′-hydroxypropanimidamide), N′,3-dihydroxypropanimidamide, NN′-hydroxyacetimidamide, N′-hydroxy-3-(methylamino)propanimidamide, N′-hydroxybenzimidamide, 3,3′-azanediylbis(N′-hydroxypropanimidamide), N′-hydroxyoctanimidamide, N′-hydroxy-3-phenylpropanimidamide, 3-amino-N-hydroxy-3-(hydroxyimino)propanamide, 3-amino-3-(hydroxyimino)propanoic acid, 3-amino-3-(hydroxyimino)propanamide, N′1,N′6-dihydroxyadipimidamide, N′1,N′10-dihydroxydecanebis(imidamide), N′-hydroxyisonicotinimidamide, N′-hydroxy-3-methylbenzimidamide, isoindoline-1,3-dione dioxime, N′,2-dihydroxyacetimidamide, 2-chloro-N′-hydroxyacetimidamide, product N′-hydroxy-2-phenylacetimidamide, 2-amino-N′-hydroxybenzimidamide, 2,2′-azanediylbis(N′-hydroxyacetimidamide), N′-hydroxy-1-oxo-1,3-dihydroisobenzofuran-5-carboximidamide, 3-aminoisoquinolin-1(4H)-one oxime or 3-(hydroxyamino)-3,4-dihydroisoquinolin-1-amine, N′-hydroxycinnamimidamide, 4-cyano-N′-hydroxybutanimidamide, 4-chloro-N′-hydroxybenzimidamide and salts thereof.

39. A method for the chemical mechanical planarization of a semiconductor work-piece, the method comprising the steps of:
A) providing a semiconductor work-piece, wherein said semiconductor workpiece comprises:
a) a metal line, wherein said metal line comprises copper or aluminum;
b) a barrier material, wherein said barrier material comprises materials selected from the group consisting of: a) Tantalum (Ta), b) Tantalum nitride (TaN), c) Titanium (Ti), d) Titanium nitride (TiN), e) Tungsten (W), and f) Tungsten nitride (WN); and
c) a dielectric, and
B) contacting said semiconductor work-piece with a polishing composition comprising a cleaning agent, wherein said cleaning agent comprises:
a) water; and
b) one or more amidoxime compounds.

40. The method of claim 39, wherein the one or more amidoxime compounds is present in the polishing composition in an amount of from about 0.001 percent by weight to about 25 percent by weight.

41. The method of claim 40, wherein the polishing composition is a slurry comprising from about 0.1 to about 10 percent by weight of one or more abrasive particles selected from the group consisting of silica, alumina, titanium oxide, zirconium oxide, cerium oxide, and combinations thereof.

42. The method of claim 41, wherein the polishing composition further comprises one or more compounds with oxidation and reduction potential selected from the group consisting of: ammonium peroxydisulfate, peracetic acid, urea hydroperoxide, sodium percarbonate, sodium perborate, hydrogen peroxide; hydroxylamine, hydroxylamine salts, peracetic acid, perchloric acid, periodic acid, ammonium persulfate, sodium persulfate, potassium persulfate, Na₂O₂, Ba₂O₂ and (C₆H₅C)₂O₂; hypochlorous acid, ketoneperoxides, diacylperoxides, hydroperoxides, alkylperoxides, peroxyketals, alkylperesters peroxycarbonates, hydroxylammonium salts and mixtures thereof.

43. The method of claim 42, wherein the one or more compounds with oxidation and reduction potential are present in an amount of about 0.01 percent by weight to about 10 percent by weight.

44. The method of claim 43, wherein the polishing composition further comprises a corrosion inhibitor selected from the group consisting of dithiocarbamate, thiosulfate, benzotriazole, 1-hydroxybenzotriazole, 4-hydroxybenzotriazole, 2,3-dicarboxybenzotriazole, 2,3-dicarboxypropylbenzotriazole, 4-carboxyl-1H-benzotriazole, 4-methoxycarbonyl-1H-benzotriazole, 4-butoxycarbonyl-1H-benzotriazole and methyl-1H-benzotriazole in an amount from about 0.001 percent by weight to about 1.0 percent by weight.

45. The method of claim 39 wherein the semiconductor workpiece has at least one feature thereon comprising copper, wherein the polishing composition further comprises a hydroxylamine compound in an amount sufficient for chemical etching of the at least one feature comprising copper, wherein the polishing composition further comprises an abrasive, and wherein the pH of the composition is in a range of from approximately 2.0 to approximately 12.0.

46. The method of claim 45, wherein the hydroxylamine compound is hydroxylamine freebase, hydroxylamine sulfate, hydroxylamine nitrate or hydroxylamine phosphate.

47. The method of claim 45, wherein the amount of hydroxylamine compound is from approximately 0.3 to approximately 10 percent by weight.
